(19) United States
(12) Patent Application Publication
(10) Pub. No.: US 2016/0048045 A1
(43) Pub. Date: Feb. 18, 2016

(54) DISPLAY COMPONENT, DISPLAY DEVICE, AND METHOD OF PRODUCING DISPLAY COMPONENT

(71) Applicant: SHARP KABUSHIKI KAISHA, Osaka-shi, Osaka (JP)

(72) Inventors: Akihiro IMAI, Osaka-shi (JP); Makoto KANBE, Osaka-shi (JP); Motoaki FUKAYAMA, Osaka-shi (JP); Ryoh UEDA, Osaka-shi (JP); Taichi OBATA, Osaka-shi (JP); Shigeki TANAKA, Osaka-shi (JP)

(73) Assignee: Sharp Kabushiki Kaisha, Osaka-shi, Osaka (JP)

(21) Appl. No.: 14/655,406

(22) PCT Filed: Dec. 20, 2013
(86) PCT No.: PCT/JP2013/084230

§ 371 Date: Jun. 25, 2015

(30) Foreign Application Priority Data
Dec. 27, 2012 (JP) 2012-285308
Feb. 8, 2013 (JP) 2013-023564

(51) Int. Cl. G02F 1/1337; G03F 7/20; G02F 1/1343; H01L 27/12; G02F 1/1362; G02F 1/1333

(52) U.S. Cl. CPC G02F 1/1337; G02F 1/136227; G02F 1/133345; G02F 1/1343; H01L 27/127; G03F 7/20

(57) ABSTRACT

An array board 1311b includes a first conductive film, a second conductive film, an insulator, an alignment film 1311e, and at least two inclined portions 48, 49. The second conductive film is disposed above the first conductive film and at least a portion of the second conductive film overlap the first conductive film in a plan view. The insulator is disposed between the first conductive film and the second conductive film. The insulator includes a contact hole formed at a position overlapping the first conductive film and the second conductive film in a plan view and connects the second conductive film to the first conductive film. The alignment film 1311e is disposed above the second conductive film. The alignment film 1311e includes a portion that overlaps the contact hole in a plan view and a portion that does not overlap the contact hole in a plan view. The inclined portions 48, 49 are formed at an edge of the contact hole in the insulator. The inclined portions 48, 49 have inclined shapes in a cross-sectional view and inclination angles different from each other.

### TECHNICAL FIELD

The present invention relates to a display component, a display device, and a method of producing the display component.

### BACKGROUND ART

A liquid crystal panel used for a liquid crystal display device includes liquid crystals held between a pair of boards. One of the boards is an array board including TFTs that are active components for controlling the operation of pixels. The array board has a number of gate lines and source lines formed in a matrix within a display area thereof, and has the TFT disposed at each intersection of the gate line and the source line. A pixel electrode is disposed in a region surrounded by the gate lines and the source lines. The region including the pixel electrode corresponds to a unit display region, that is, a pixel. A drain electrode included in the TFT is connected to a drain line. A contact hole is formed at a position overlapping both the drain line and the pixel electrode. The contact hole runs through an insulator that insulates the drain line from the pixel electrode. The drain line is connected to the pixel electrode via the contact hole. Alignment films for controlling the alignment of liquid crystal molecules are formed on inner surfaces of the boards that are in contact with the liquid crystals.

To form the alignment film on the array board, an inkjet device may be used. An example of the device is disclosed in Patent Document 1. According to Patent Document 1, the contact holes of the pixels are in irregular arrangement within the surface of the array board. This is to reduce moire resulting from a depressed portion that may be formed in the alignment film when droplets of the solution discharged from an inkjet head for forming the alignment film enter the contact hole.

### RELATED ART DOCUMENT

### Patent Document

Patent Document 1: Japanese Unexamined Patent Application Publication No. 2010-66397

### Problem to be Solved by the Invention

According to Patent Document 1, when the droplets of the solution for forming the alignment film enter the contact hole, the depressed portion may be formed in a portion of the alignment film corresponding to the contact hole and the moire may occur due to the depressed portion. However, the droplets of the solution for forming the alignment film actually do not enter the contact hole. This results in defects in the film. The moire occurs due to the defects in the film. Thus, it is difficult to reduce the moire without reducing the defects in the alignment film. In addition, even though the contact holes of the pixels are arranged irregularly as disclosed in Patent Document 1, each contact hole cannot be arranged beyond an area of the pixel that includes the contact hole. Namely, a distance between the adjacent contact holes cannot be larger than a certain distance.

Accordingly, moire reducing effect is limited.

### DISCLOSURE OF THE PRESENT INVENTION

The present invention was made in view of the foregoing circumstances. An object of the present invention is to reduce or suppress moire.

### Means for Solving the Problem

A first display component according to the present invention includes a first conductive film, a second conductive film, an insulator, and an alignment film. The second conductive film is disposed above the first conductive film and at least a portion of the second conductive film overlaps the first conducive film in a plan view. The insulator is held between the first conductive film and the second conductive film. The insulator includes a contact hole for connecting the second conductive film to the first conductive film. The contact hole is at a position overlapping the first conductive film and the second conductive film in a plan view. The alignment film is disposed above the second conductive film. The alignment film includes a portion overlapping the contact hole in a plan view and a portion not overlapping the contact hole in a plan view. The contact hole includes an edge, at least a portion of which defines a bending portion of the insulator which bends toward an inner side of the contact hole such that an outer angle of the bending portion is a reflex angle in a plan view.

Thus, the second conductive film formed after the formation of the first conductive film and the insulator is connected to the first conductive film on the lower side via the contact hole of the insulator. When the solution for forming the alignment film is supplied locally to the surface of the second conductive film or the like in the formation of the alignment film above the first conductive film, the solution spreads to the outside and inside of the contact hole, thereby forming the alignment film having a portion overlapping the contact hole in a plan view and a portion not overlapping the contact hole in a plan view. Here, in the case where the solution for forming the alignment film supplied to the outside of the contact hole spreads into the contact hole, when the solution reaches the bending portion that bends toward the inner side of the contact hole such that the outer angle of the bending portion is a reflex angle in a plan view, the solution is drawn into the contact hole because of the bending portion. It is considered that the solution is drawn because the reach of the solution to the bending portion with the reflex angle in a plan view produces the force to spread the solution in a wide angle. It is easier to arrange the alignment film in the contact hole and defects are less likely to be developed in the alignment film. Accordingly, the moire is properly reduced or suppressed.

Preferable embodiments may include the following configurations.

(1) In the insulator, the contact hole may include a contact hole main portion overlapping at least a portion of the first conductive film and the second conductive film in a plan view, and an expanded hole portion formed by expanding a portion of the contact hole main portion. The bending portion may be defined by edges of the contact hole main portion and the expanded hole portion that are communicated with each other, and the expanded hole portion may have a smaller opening width than the main body of the contact hole main portion. The opening widths of the expanded hole portion and the contact hole main portion are each defined by the distance between a pair of edges opposite to each other. Here, in the case where the solution for forming the alignment film reaches both the pair of edges opposite to each other at the expanded hole portion included in the contact hole in the formation of the alignment film, the solution reaching the edges is easily connected as compared to the contact hole main portion side. When the solution is connected, the solution flows to have a smaller surface area due to the surface tension, thereby making it easier for the solution to flow into the contact hole. In addition, the edge of the expanded hole portion communicated with the edge of the contact hole main portion forms the bending portion. Therefore, in combination with the easy flow of the solution for forming the alignment film into the contact hole due to the bending portion, the solution for forming the alignment film can flow into the contact hole more easily. This allows the alignment film to be formed more easily in the portion overlapping the contact hole in a plan view and the defects are less likely to be developed in the alignment film.

(2) The second conductive film may form the pixel electrode formed of a transparent electrode material, and in the insulator, the expanded hole portion may be formed by extending a portion of the contact hole main portion that is relatively far from the center of the pixel electrode in a plan view. The portion of the alignment film that overlaps the contact hole has a depressed shape relative to the non-overlapped portion. Therefore, the aligning function cannot be exhibited sufficiently in some cases and this tends to be remarkably observed in the expanded hole portion formed by extending the contact hole main portion. In this regard, the expanded hole portion is formed by extending a portion of the contact hole main portion that is relatively far from the center of the pixel electrode in a plan view. Therefore, the defective alignment that may be caused by the expanded hole portion affects the display of the pixel electrode less easily. For this reason, the deterioration in display quality due to the expanded hole portion is suppressed.

(3) In the insulator, the expanded hole portion may be formed by extending a corner of the contact hole main portion. This allows the expanded hole portion to be disposed as far from the pixel electrode as possible in the contact hole. Thus, the defective alignment caused by the expanded hole portion affects the display of the pixel electrode less easily.

(4) The second conductive film may form the pixel electrode formed of a transparent electrode material, and in the insulator, the expanded hole portion may be disposed not overlapping the pixel electrode in a plan view. The portion of the alignment film that overlaps the contact hole in a plan view has a depressed shape relative to the non-overlapped portion. Thus, the aligning function cannot be exhibited sufficiently in some cases, and in particular, this tends to be remarkably observed in the expanded hole portion formed by extending the contact hole main portion. In this regard, the expanded hole portion is disposed not overlapping the pixel electrode in a plan view. Therefore, the defective alignment that may be caused by the expanded hole portion affects the pixel electrode less easily. Thus, the deterioration in display quality due to the expanded hole portion is suppressed. When the pixel electrode is formed of a transparent electrode material, the fluidity of the solution for forming the alignment film on the pixel electrode may be low. However, when the expanded hole portion with the bending portion for enabling the easy flow of the solution for forming the contact hole into the contact hole is formed not overlapping the pixel electrode in a plan view, the fluidity of the solution toward the expanded hole portion is maintained high. This makes the solution for forming the alignment film flow to the contact hole more easily.

(5) In the insulator, the expanded hole portion may be disposed not overlapping the first conductive film in a plan view. Thus, as compared to the contact hole main portion, the opening depth, i.e., the gap from the surface of the second conductive film and the like to which the solution for forming the alignment film is supplied is large in the expanded hole portion because the expanded hole portion does not overlap the first conductive film in a plan view. Therefore, the solution for forming the alignment film flows into the expanded hole portion more easily.

(6) The display component may further include a third conductive film disposed below the first conductive film, at least a portion of the third conductive film overlapping the first conductive film in a plan view. In the insulator, at least a portion of the contact hole main portion may be disposed overlapping the third conductive film in a plan view and the expanded hole portion may be disposed not overlapping the third conductive film in a plan view. Thus, as compared to the contact hole main portion, the opening depth, i.e., the gap from the surface of the second conductive film to which the solution for forming the alignment film is supplied is large in the expanded hole portion because the expanded hole portion does not overlap the third conductive film in a plan view. Therefore, the solution for forming the alignment film flows into the expanded hole portion more easily.

(7) In contrast to the first conductive film that may form at least the source electrode and the drain electrode, the third conductive film may form a gate electrode that overlaps at least the source electrode and the drain electrode in a plan view and an auxiliary capacitor line disposed apart from the gate electrode in a plan view. In the insulator, at least a portion of the contact hole main portion may overlap the drain electrode and the gate electrode in a plan view and the expanded hole portion may be held between the gate electrode and the auxiliary capacitor line in a plan view. Since the expanded hole portion is held between the gate electrode and the auxiliary capacitor line in a plan view, the valley is formed on the surface of the second conductive film and the like to which the solution for forming the alignment film is supplied. Therefore, the solution for forming the alignment flows more easily from the portion overlapping the gate electrode and the auxiliary capacitor line in a plan view to the expanded hole portion on the surface of the second conductive film and the like.

(8) The insulator may include at least an organic insulator formed of an organic resin material. At least the bending portion of the edge of the contact hole may have the sectional shape gradually rising, and include a first inclined portion that is disposed on the relatively lower side and has a larger inclination angle, and a second inclined portion that is disposed on the relatively upper side and has a smaller inclination angle. If the bending portion is entirely formed of the first inclined portion, the inclination is sharp so that it is difficult for the solution for forming the alignment film to move toward the first inclined portion. In contrast, when the second inclined portion that is less sharp is disposed above the first inclined portion, the solution for forming the alignment film is moved smoothly. Therefore, when the solution for forming the alignment film has reached the bending portion of the edge of the contact hole in the formation of the alignment film, the solution is induced to flow into the contact hole by the second inclined portion that is disposed on the relatively upper side and has a smaller inclination angle. As a result, the solution enters the contact hole smoothly through the first inclined portion. The above case is suitable when the contact hole is small, as compared to the case where the bending portion is entirely formed of the second inclined portion and the edge of the contact hole tends to have a larger width.

(9) The display component may further include: a third conductive film provided below the first conductive film, at least a portion of the third conductive film overlapping the first conductive film in a plan view; and a semiconductor film interposed between the third conductive film and the first conductive film. The first conductive film may form at least the source electrode and the drain electrode. The third conductive film may form the gate electrode that overlaps at least the source electrode and the drain electrode in a plan view. The semiconductor film may include an oxide semiconductor and forma channel that is connected to the source electrode and the drain electrode. Thus, upon the application of voltage to the gate electrode, current flows between the source electrode and the drain electrode through the channel formed of the oxide semiconductor film. Since this oxide semiconductor film has higher electron mobility than an amorphous silicon thin film or the like, sufficient current can be supplied between the source electrode and the drain electrode even though the channel has a smaller width. If the channel has a smaller width, the source electrode, the drain electrode, and the gate electrode have smaller size, which is preferable in achieving the higher definition of the display component. When the display component has the higher definition, the number of contact holes tends to increase. According to the configuration, defects are more likely to be developed in the alignment film. In this regard, when the bending portion that is curved to form a reflex angle on the inside in a plan view at the edge of the contact hole of the insulator is included, the solution for forming the alignment film easily enters the contact hole, which is preferable because defects are less likely to be developed in the alignment film.

A second display component according to the present invention includes a first conductive film, a second conductive film, an insulator, an alignment film, and at least two inclined portions. The second conductive film is disposed above the first conductive film and includes a portion overlapping the first conductive film in a plan view. The insulator is held between the first conductive film and the second conductive film and includes a contact hole for connecting the second conductive film to the first conductive film. The contact hole is at a position overlapping the first conductive film and the second conductive film in a plan view. The alignment film is disposed above the second conductive film and includes a portion overlapping the contact hole in a plan view and a portion not overlapping the contact hole in a plan view. The inclined portions are formed at an edge of the contact hole in the insulator and have inclined shapes in a cross-sectional view with inclination angles different from each other.

According to the configuration, the second conductive film formed after the first conductive film and the insulator are formed is connected to the first conductive film in a lower layer via the contact hole in the insulator. During the formation of the alignment film in a layer above the first conductive film, a solution for forming the alignment film is fed a portion of the surface of the second conductive film. The solution spreads outside and inside of the contact hole and the alignment film is formed. The alignment film includes the portion overlapping the contact hole in a plan view and the portion not overlapping the contact hole in a plan view. When the solution for forming the alignment film fed to the outside of the contact hole spreads toward the inside of the contact hole and reaches the edge of the contact hole, flow of the solution into the contact hole is promoted by the inclined portion having a smaller inclination angle, that is, having a gentle slope, among the inclined portions having the inclination angles different from each other at the edge of the contact hole. At a portion of the edge of the contact hole at a boundary between the inclined portions having the inclination angles different from each other, flowability of the solution for forming the alignment film is improved because of the difference in inclination angle. Therefore, the solution is more likely to flow into the contact hole. Namely, it is easier to form the alignment film inside the contact hole and defects are less likely to be developed in the alignment film. According to the configuration, the moire is properly suppressed or reduced.

Preferable embodiments of the second display component may include the following configurations.

(1) The at least two inclined portions may be formed such that a difference between the inclination angles thereof is in a range from 10° to 50°. If the difference between the inclination angles of the inclined portions is smaller than 10°, the difference is so small that the flowability of the solution for forming the alignment film at a boundary between the inclined portions having different inclination angles is not sufficient. Namely, a sufficient level of promotion of flow of the solution is not achieved. If the difference between the inclination angles of the inclined portions is larger than 50°, the slope of the inclined portion having the smaller inclination angle is so gentle that a creepage distance thereof tends to become large. Therefore, an area of a portion that is not used for display increases and display performance may decrease. As described above, the difference between the inclination angles θ1 of the inclined portions is within the range from 10° to 50°. Therefore, the flow of the solution for forming the alignment film is sufficiently promoted. Furthermore, the creepage distance of the inclined portion having the smaller inclination angle is sufficiently small. Therefore, the display component can exert the sufficient level of the display performance.

(2) The insulator may be formed such that the contact hole includes a long edge and a short edge in a plan view. One of the inclined portions having the smaller inclination angle is formed at the short edge of the contact hole. In comparison to a configuration in which the inclined portion having the smaller inclination angle is formed at the long edge of the contact hole, the solution for forming the alignment film, the flow of which into the contact hole is promoted by the inclined portion having the smaller inclination angle, is more likely to reach the boundary between the inclined portions of the edges of the contact hole having different inclination angles. Because the inclination angles at the boundary are different, the flowability of the solution for forming the alignment film increases and thus the solution is more likely to flow into the contact hole.

(3) The inclined portion having the smaller inclination angle may have a dimension along the short edge equal to 8 μm or smaller. In comparison to a configuration in which the dimension is equal to 8 μm or larger, the solution for forming the alignment film, the flow of which into the contact hole is promoted by the inclined portion having the smaller inclination angle is more likely to reach the boundary between the inclined portions having the different inclination angles, respectively, at the edge of the contact hole. Therefore, the flow of the solution into the contact hole is further promoted and thus the defects are further less likely to be developed in the alignment film.

(4) The insulator may be formed such that the contact hole has a polygonal shape in a plan view. The inclined portion having the smaller inclination angle and the inclined portion having a larger inclination angle of the inclined portions are formed at portions of at least one edge of the contact hole. According to the configuration, when the solution for forming the alignment film reaches at least one edge of the contact hole having the polygonal shape in a plan view during the formation of the alignment film, the flow of the solution into the contact hole is promoted by the inclined portion formed at a portion of at least one edge of the contact hole and having the smaller inclination angle. Furthermore, the flowability of the solution is increased at the boundary between the inclined portions formed at a portion of at least edge of the contact hole and having the larger inclination angle. According to the configuration, the flowability of the solution for forming the alignment film into the contact hole is further promoted and thus defects are further less likely to be developed in the alignment film.

(5) The insulator may be formed such that the contact hole has a rectangular shape in a plan view. The inclined portion having the smaller inclination angle and the inclined portion having the larger inclination angle of the inclined portions may be formed at portions of at least a long edge of the contact hole. According to the configuration, that is, the inclined portion having the smaller inclination angle and the inclined portion having the larger inclination angle are formed at the portions of long edge of the contact hole, flowability of a solution for forming an alignment film is increased at a boundary between the inclined portions having different inclination angles during the formation of the alignment film. This configuration is especially preferable when there is not sufficient space for forming the inclined portion having the smaller inclination angle at the short edge of the lower contact hole.

(6) The insulator may be formed such that the contact hole has around shape or an oval shape in a plan view. The contact hole having the round shape or the oval shape in a plan view does not have edges that cross each other. When a solution for forming an alignment film reaches the edge of the contact hole during the formation of the alignment film, droplets of the solution are less likely to merge and thus the solution is less likely to flow into the contact hole. By forming at least two inclined portions having different inclination angles at the edge of the contact hole, a sufficient level of flowability of the solution for forming the alignment film into the contact hole is achieved.

(7) The insulator may be formed such that the contact hole has an opening area in a range from 10 μm² to 150 μm². If the opening area of the contact hole is smaller than 10 μm², a connecting area between the first conductive film and the second conductive film is so small that reliability of the connection may decrease and it may be difficult to form the contact hole. If the opening area of the contact hole is larger than 150 μm², the solution that has reached the edge of the contact hole is less likely to merge with the solution that has reached from a different way. Therefore, the solution for forming the alignment film is less likely to flow into the lower contact hole. According to the configuration in which the opening area of the contact hole is within the range from 10 μm² to 150 μm², the connecting area between the first conductive film and the second conductive film has a sufficient size and thus the reliability of the connection is ensured. Furthermore, the contact hole is easily formed and the solution for forming the alignment film is more likely to flow into the lower contact hole.

A display device according to the present invention includes the display component described above, an opposite board, and liquid crystals. The opposite board is disposed opposite to the display component. The liquid crystals disposed between the display component and the opposite board. In the display device, the defects are less likely to be developed in the alignment film of the display component and the moire is properly reduced or suppressed. Therefore, the alignment of liquid crystals is properly performed and high display quality is achieved.

A method of producing the first display component according to the present invention includes a first film forming process and a second film forming process. The first film forming process is for forming the first conductive film, the insulator, and the second conductive film in this sequence on a substrate. The first film forming process includes forming the contact hole at a position overlapping the first conductive film and the second conductive film in a plan view for connecting the second conductive film to the first conductive film. The first film forming process further includes forming a bending portion at a portion of an edge of the contact hole such that the bending portion bends toward the inner side of the contact hole and has a reflex outer angle in a plan view. The second film forming process is for forming the alignment film including the portion that overlaps the contact hole and the portion that does not overlap the contact hole in a plan view.

According to the method, when the second conductive film is formed after the first conductive film and the insulator are formed on the substrate in the first film forming process, the second conductive film is connected to the first conductive film in the lower layer via the contact hole formed in the insulator. In the second film forming process performed after the first film forming process, when the solution for forming the alignment film is fed to a portion of the surface of the second conductive film for forming the alignment film in a layer above the first conductive film and the solution spreads outside and inside the contact hole, the alignment film is formed. The alignment film includes the portion overlapping the contact hole and the portion not overlapping the contact hole in a plan view. When the solution for forming the alignment film fed to the outside of the contact hole spreads toward the inside of the contact hole and reaches the bending portion that bends toward the inside with the reflex angle in a plan view at the edge of the contact hole, the solution is drawn to the inside of the contact hole by the bending portion. The reason why the solution is drawn as such is that a force may be exerted on the solution by the bending portion having the reflex angle on the inside in a plan view to spread in a wide angle when the solution reaches the bending portion. According to the configuration, the alignment film is easily formed inside the contact hole. Therefore, the defects are less likely to be developed in the alignment film and the moire is properly reduced or suppressed.

Preferable embodiments of the method of producing the first display component may include the following.

(1) In the second film forming process, an inkjet device is used and the solution for forming the alignment film is discharged out of a plurality of nozzles in the inkjet device onto the second conductive film. Thus, in the second film forming process, the solution for forming the alignment film discharged out of the nozzles of the inkjet device reaches the upper side of the second conductive film and then spreads over the surface. The arrangement of the nozzles of the inkjet device may interfere with the arrangement of the contact holes, in which case the solution for forming the alignment film discharged out of the nozzles may not spread sufficiently. This may result in the moire. According the configuration described above, the bending portion is included in the edge of the contact hole. The solution for forming the alignment film is drawn to the contact holes by the bending portions. Therefore, the alignment film is easily formed in the contact hole and the moire is properly reduced or suppressed.

(2) In the second film forming process, a stencil printing device is used. While the solution for forming the alignment film is supplied onto the mesh stencil included in the stencil printing device, the squeegee is moved on the stencil. Thus, the solution for forming the alignment film is printed onto the upper side of the second conductive film through the holes of the stencil. Thus, the solution for forming the alignment film supplied onto the mesh stencil included in the stencil printing device in the second film forming process is printed onto the second conductive film through the holes of the stencil by the squeegee moving on the stencil and spreads over the surface. The stencil of the stencil printing device has the holes and has a mesh shape. An arrangement of the holes and the arrangement of the contact holes may overlap each other. If the solution for forming the alignment film does not sufficiently spread after passed through the holes, the moire may occur. In this embodiment, the bending portions are included in the edges of the respective contact holes as described above, the solution for forming the alignment film is drawn into the contact holes by the bending portions. Therefore, the alignment film is easily formed in the contact holes and the moire is properly reduced or suppressed.

(3) In the first film forming process, at least the organic insulator formed of a photosensitive organic material is provided as the insulator and the organic insulator is exposed to light using a halftone mask including a semitransmissive film or a gray tone mask including a semitransmissive area by a slit as a photomask. Thus, at least the bending portion in the edge of the contact hole is formed to have the sectional shape gradually rising and the edge has the first inclined portion disposed on the relatively lower side and having a larger inclination angle, and the second inclined portion disposed on the relatively upper side and having a smaller inclination angle. Thus, the organic insulator formed of the photosensitive organic material provided in the first film forming process is exposed to light using the halftone mask including the semitransmissive film or the gray tone mask including the semitransmissive area by the slit. Therefore, the bending portion is formed to have the sectional shape gradually rising and the bending portion has the first inclined portion disposed on the relatively lower side and having a larger inclination angle, and the second inclined portion disposed on the relatively upper side and having a smaller inclination angle. If the bending portion is formed entirely from the first inclined portion, the solution for forming the alignment film is moved toward the first inclined portion less easily because the inclination is sharp. As compared to this, the solution for forming the alignment film is moved smoothly when the second inclined portion with a less sharp inclination is disposed above the first inclined portion. Therefore, when the solution for forming the alignment film has reached the bending portion in the edge of the contact hole in the formation of the alignment film, the solution is induced to flow into the contact hole by the second inclined portion disposed on the relatively upper side and having the smaller inclination angle. Thus, the solution enters the contact hole smoothly through the first inclined portion. The above case is suitable when the contact hole is small, as compared to the case where the bending portion is entirely formed of the second inclined portion because the edge of the contact hole tends to have a larger width.

A method of producing the second display component according to the present invention includes a first film forming process and a second film forming process. The first film forming process is for forming the first conductive film, the insulator, and the second conductive film in this sequence of a substrate. The first film forming process includes forming the contact hole at a portion overlapping the first conductive film and the second conductive film in a plan view for connecting the second conductive film to the first conductive film. The first film forming process further includes forming at least two inclined portions at an edge of the contact hole such that the inclined portions have inclined shapes in a cross-sectional view and inclination angles different from each other. The second film forming process is for forming the alignment film including a portion overlapping the contact hole and a portion not overlapping the contact hole.

According to the method, when the second conductive film is formed after the first conductive film and the insulator are formed on the substrate in the first film forming process, the second conductive film is connected to the first conductive film in the lower layer via the contact hole formed in the insulator. In the second film forming process performed after the first film forming process, when the solution for forming the alignment film is fed to a portion of the surface of the second conductive film for forming the alignment film in a layer above the first conductive film and the solution spreads outside and inside the contact hole, the alignment film is formed. The alignment film includes the portion overlapping the contact hole and the portion not overlapping the contact hole in a plan view. When the solution for forming the alignment film fed to the outside of the contact hole spreads toward the inside of the contact hole and reaches the edge of the contact hole, the flow of the solution to the inside of the contact hole is promoted by the inclined portion having the smaller inclination angle and a gentle slope among the inclined portions having the different inclination angles. Furthermore, flowability of the solution for forming the alignment film is increased at a boundary between the inclined portions having different inclination angles at the edge of the contact hole and thus the solution is more likely to flow into the contact hole. According to the configuration, the alignment film is easily formed inside the contact hole. Therefore, the defects are less likely to be developed in the alignment film and the moire is properly reduced or suppressed.

Preferable embodiments of the method of producing the second display component may include the following.

(1) The first film forming process may include forming at least an organic insulator from photosensitive organic resin material as the insulator. The first film forming process may include exposing the organic insulator using a halftone mask including a semitransmissive film or a gray-tone mask including a semitransmissive area with a slit as a photomask. The first film forming process may include forming one of the inclined portions having the smaller inclination angle at the edge of the contact hole with light transmitted through the semitransmissive film of the halftone mask or the semitransmissive area of the gray-tone mask.

(2) The first film forming process may include forming at least an organic insulator from photosensitive organic resin material as the insulator. The first film forming process may include exposing the organic insulator using a halftone mask including a light blocking film and a semitransmissive film including holes, respectively, as a photomask. The halftone mask may include a semitransmissive area in which the hole in the light blocking film overlaps the semitransmissive film in a plan view. The semitransmissive area has a width in a range from 0.5 μm to 5 μm. The first film forming process may include forming one of the inclined portions having the smaller inclination angle at the edge of the contact hole with light transmitted through the semitransmissive area. According to the method, the contact hole is formed in the organic insulator made of photosensitive organic resin material formed in the first film forming process by exposing the organic insulator using the halftone mask. At the edge of the contact hole, the inclined portion having the smaller inclination angle of the inclined portions is formed with the light transmitted through the semitransmissive area that is an area in which the hole in the light blocking film overlaps the semitransmissive film in a plan view. If the width of the semitransmissive area is smaller than 0.5 μm, the amount of light transmitted through the semitransmissive area may be so small that underexposure may occur. As a result, the inclined portion having the smaller inclination angle may not be formed in the organic insulator. If the width of the semitransmissive area is larger than 5 μm, holes different from the contact hole may be formed in the organic insulator. As a result, the inclined portion having the smaller inclination angle may not be formed in the organic insulator. By setting the width of the semitransmissive area of the halftone mask in the range from 0.5 μm to 5 μm as described earlier, the organic insulator is properly exposed and the inclined portion having the smaller inclination angle is properly formed at the edge of the contact hole.

(3) The halftone mask used in the first film forming process may be configured according to photosensitivity of the photosensitive organic resin material of the organic insulator. When the photosensitive organic resin material of the organic insulator is a positive type, the organic insulator is exposed to light using the halftone mask including a transmissive area in which the hole in the light blocking film and the hole in the semitransmissive film overlap each other in a plan view and a distance between the transmissive area and the semitransmissive area is in a range from 0.5 μm to 5 μm. When the photosensitive organic resin material of the organic insulator is a negative type, the organic insulator is exposed to light using the halftone mask including a light blocking area that overlaps the light blocking film in a plan view and a distance between the light blocking area and the semitransmissive area is in a range from 0.5 μm to 5 μm. If the distance between the transmissive area and the semitransmissive area or the distance between the light blocking area and the semitransmissive area is smaller than 0.5 μm, the semitransmissive area is so close to the transmissive area or the light blocking area that it may be difficult to form the inclined portion having the smaller inclination angle. If the distance between the transmissive area and the semitransmissive area or the distance between the light blocking area and the semitransmissive area is larger than 5 μm, holes different from the contact hole may be formed in the organic insulator. Therefore, the inclined portions having the smaller inclination angle may not be formed in the organic insulator. By setting the distance between the transmissive area and the semitransmissive area or the distance between the light blocking area and the semitransmissive area of the halftone mask in the range from 0.5 μm to 5 μm, the organic insulator is properly exposed and the inclined portion having the smaller inclination angle is properly formed to the edge of the contact hole.

(4) The first film forming process may include forming at least an organic film from photosensitive organic resin material as the insulator. The first film forming process may include exposing the organic insulator using a gray-tone mask as a photomask. The gray-tone mask may include a light blocking film and a width of the semitransmissive area including the slit is in a range from 0.5 μm to 5 μm. The first film forming process may include forming one of the inclined portions having the smaller inclination angle at the edge of the contact hole with light transmitted through the semitransmissive area. According to the method, the contact hole is formed in the organic insulator made of photosensitive organic resin material formed in the first film forming process by exposing the organic insulator using the gray-tone mask. At the edge of the contact hole, the inclined portion having the smaller inclination angle of the at least two inclined portions is formed with the light transmitted through the semitransmissive area that is the area of the gray-tone mask including the slit in the light blocking film. If the width of the semitransmissive area is smaller than 0.5 μm, the amount of light transmitted through the semitransmissive area may be so small that underexposure may occur. As a result, the inclined portion having the smaller inclination angle may not be formed in the organic insulator. If the width of the semitransmissive area is larger than 5 μm, multiple steps may be formed at the edge of the contact hole. As a result, the inclined portion having the smaller inclination angle may not be formed in the organic insulator. By setting the width of the semitransmissive area of the gray-tone mask in the range from 0.5 μm to 5 μm as described earlier, the organic insulator is properly exposed and the inclined portion having the smaller inclination angle is properly formed at the edge of the contact hole.

### Advantageous Effect of the Invention

According to the present invention, the moire is suppressed or reduced.

### BRIEF DESCRIPTION OF THE DRAWINGS

FIG. 1 is a schematic plan view of a liquid crystal panel on which a driver is mounted, a flexible printed circuit board, and a control circuit board according to a first embodiment of the present invention illustrating connection among those.

FIG. 2 is a schematic cross-sectional view of a liquid crystal display device illustrating a cross-sectional configuration along a long-side direction thereof.

FIG. 3 is a schematic cross-sectional view illustrating a cross-sectional configuration of the liquid crystal panel.

FIG. 4 is a plan view schematically illustrating a wiring configuration on an array board in the liquid crystal panel.

FIG. 5 is a plan view illustrating wiring between a row control circuit and a gate line in a non-display area on the array board.

FIG. 6 is a cross-sectional view along line vi-vi in FIG. 5.

FIG. 7 is a plan view illustrating a plane configuration of pixels in a display area on the array board.

FIG. 8 is a plan view illustrating a TFT and its vicinity in FIG. 7 in an enlarged manner.

FIG. 9 is a cross-sectional view along line ix-ix in FIG. 8.

FIG. 10 is a cross-sectional view along line x-x in FIG. 8.

FIG. 11 is a cross-sectional view along line xi-xi in FIG. 8.

FIG. 12 is a perspective view illustrating a schematic configuration of an inkjet device for applying an alignment film.

FIG. 13 is a schematic plan view representing the behavior of a solution for forming the alignment film in a bending portion.

FIG. 14 is a schematic plan view representing the behavior of a solution for forming the alignment film in an expanded hole portion.

FIG. 15 is a cross-sectional view of a TFT in a display area on an array board according to a second embodiment of the present invention, which is taken along an X-axis direction.

FIG. 16 is a cross-sectional view of the TFT in the display area on the array board, which is taken along a Y-axis direction.

FIG. 17 is a cross-sectional view illustrating a process of exposing an organic insulator to light using a gray tone mask, which is the same as FIG. 15.

FIG. 18 is a cross-sectional view illustrating the process of exposing the organic insulator to light using the gray tone mask, which is the same as FIG. 16.

FIG. 19 is a cross-sectional view illustrating a state before an alignment film is applied using a screen printing device according to a third embodiment of the present invention.

FIG. 20 is a plan view illustrating a TFT and its vicinity in a display area on an array board according to a fourth embodiment of the present invention in an enlarged manner.

FIG. 21 is a plan view illustrating a TFT and its vicinity in a display area on an array board according to a fifth embodiment of the present invention in an enlarged manner.

FIG. 22 is a plan view schematically illustrating the planar shape of a lower contact hole according to a sixth embodiment of the present invention.

FIG. 23 is a plan view schematically illustrating the planar shape of a lower contact hole according to a seventh embodiment of the present invention.

FIG. 24 is a plan view schematically illustrating the planar shape of a lower contact hole according to an eighth embodiment of the present invention.

FIG. 25 is a plan view schematically illustrating the planar shape of a lower contact hole according to a ninth embodiment of the present invention.

FIG. 26 is a plan view schematically illustrating the planar shape of a lower contact hole according to a tenth embodiment of the present invention.

FIG. 27 is a plan view schematically illustrating the planar shape of a lower contact hole according to an eleventh embodiment of the present invention.

FIG. 28 is a plan view schematically illustrating the planar shape of a lower contact hole according to a twelfth embodiment of the present invention.

FIG. 29 is a plan view schematically illustrating the planar shape of a lower contact hole according to a thirteenth embodiment of the present invention.

FIG. 30 is a plan view illustrating a TFT and its vicinity in a display area on an array board according to a fourteenth embodiment of the present invention in an enlarged manner.

FIG. 31 is a cross-sectional view along line xxxi-xxxi in FIG. 30.

FIG. 32 is a cross-sectional view along line xxxii-xxxii in FIG. 30.

FIG. 33 is a cross-sectional view illustrating a process of exposing an organic insulator to light using a gray tone mask, which is the same as FIG. 31.

FIG. 34 is a cross-sectional view illustrating the process of exposing the organic insulator to light using the gray tone mask, which is the same as FIG. 32.

FIG. 35 is a magnified plan view of a portion of a display area of an array board around a TFT according to a fifteenth embodiment of the present invention.

FIG. 36 is a cross-sectional view along line xxxvi-xxxvi in FIG. 35.

FIG. 37 is a cross-sectional view along line xxxvii-xxxvii in FIG. 35.

FIG. 38 is a graph illustrating results of comparative experiments including a relationship difference in angle between a first inclined portion and a second inclined portion and yield of the array board.

FIG. 39 is a magnified plan view of a halftone mask according to a sixteenth embodiment of the present invention.

FIG. 40 is a cross-sectional view illustrating a step of exposing a positive organic insulator to light using a halftone mask.

FIG. 41 is a magnified plan view of the organic insulator developed after exposed to the light using the halftone mask.

FIG. 42 is a magnified plan view of a halftone mask according to a seventeenth embodiment of the present invention.

FIG. 43 is a cross-sectional view illustrating a step of exposing a negative organic insulator to light using a halftone mask.

FIG. 44 is a magnified plan view of a halftone mask according to an eighteenth embodiment of the present invention.

FIG. 45 is a cross-sectional view illustrating a step of exposing a positive organic insulator to light using a gray-tone mask.

FIG. 46 is a magnified plan view of a halftone mask according to a nineteenth embodiment of the present invention.

FIG. 47 is a magnified plan view of the organic insulator developed after exposed to the light using the halftone mask.

FIG. 48 is a magnified plan view of a halftone mask according to a twentieth embodiment of the present invention.

FIG. 49 is a magnified plan view of the organic insulator developed after exposed to the light using the halftone mask.

FIG. 50 is a magnified plan view of a halftone mask according to a twenty-first embodiment of the present invention.

FIG. 51 is a magnified plan view of the organic insulator developed after exposed to the light using the halftone mask.

FIG. 52 is a magnified plan view of a halftone mask according to a twenty-second embodiment of the present invention.

FIG. 53 is a magnified plan view of the organic insulator developed after exposed to the light using the halftone mask.

FIG. 54 is a magnified plan view of a halftone mask according to a twenty-third embodiment of the present invention.

FIG. 55 is a magnified plan view of the organic insulator developed after exposed to the light using the halftone mask.

FIG. 56 is a magnified plan view of a halftone mask according to a twenty-fourth embodiment of the present invention.

FIG. 57 is a magnified plan view of the organic insulator developed after exposed to the light using the halftone mask

FIG. 58 is a magnified plan view of the organic insulator developed after exposed to the light using the halftone mask according to a twenty-fifth embodiment of the present invention.

FIG. 59 is a magnified plan view of the organic insulator developed after exposed to the light using the halftone mask according to a twenty-sixth embodiment of the present invention.

FIG. 60 is a magnified plan view of the organic insulator developed after exposed to the light using the halftone mask according to a twenty-seventh embodiment of the present invention.

FIG. 61 is a magnified plan view of the organic insulator developed after exposed to the light using the halftone mask according to a twenty-eighth embodiment of the present invention.

FIG. 62 is a magnified plan view of the organic insulator developed after exposed to the light using the halftone mask according to a twenty-ninth embodiment of the present invention.

FIG. 63 is a magnified plan view of the organic insulator developed after exposed to the light using the halftone mask according to a thirtieth embodiment of the present invention.

FIG. 64 is a magnified plan view of the organic insulator developed after exposed to the light using the halftone mask according to a thirty-first embodiment of the present invention.

FIG. 65 is a magnified plan view of the organic insulator developed after exposed to the light using the halftone mask according to a thirty-second embodiment of the present invention.

### MODE FOR CARRYING OUT THE INVENTION

### First Embodiment

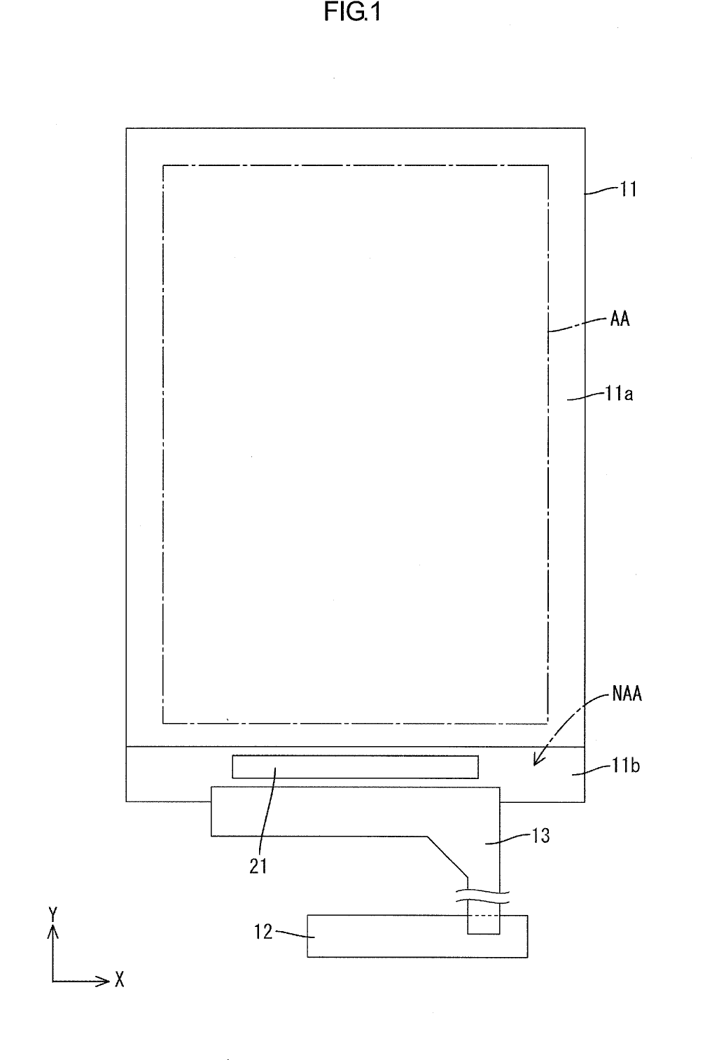

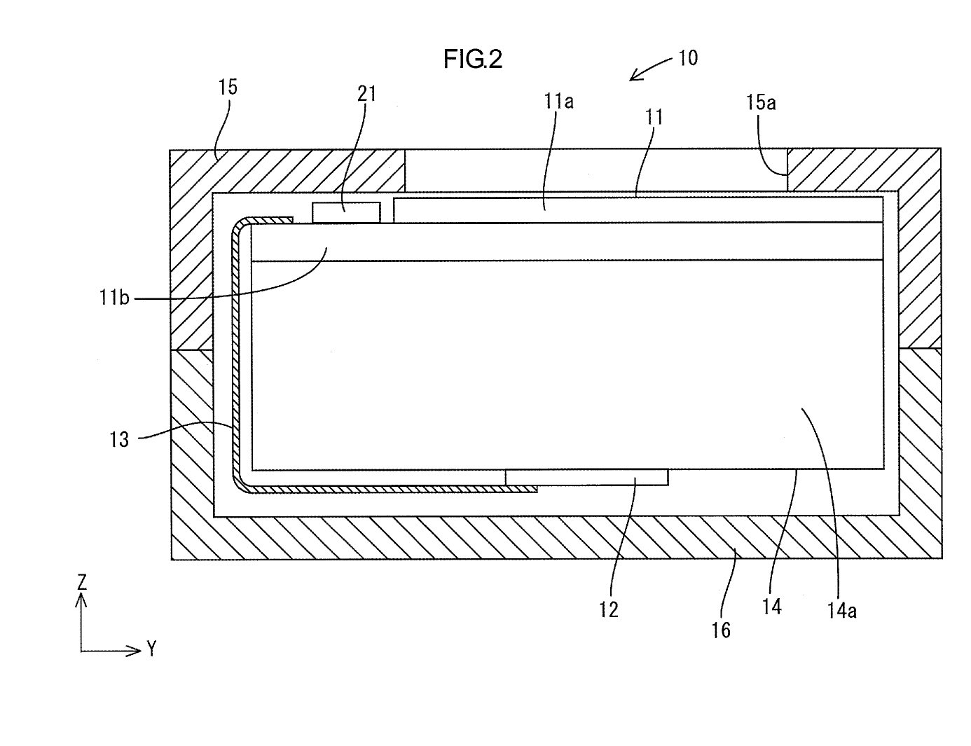

A first embodiment of the present invention will be described with reference to FIGS. 1 to 14. A liquid crystal display device 10 will be described as an example. X-axis, the Y-axis and the Z-axis may be present in the drawings. The axes in each drawing correspond to the respective axes in other drawings. The vertical direction is defined based on FIG. 2. An upper side and a lower side in FIG. 2 correspond to a front side and the back side of the liquid crystal display device 10, respectively.

As illustrated in FIGS. 1 and 2, a liquid crystal display device 10 includes a liquid crystal panel (display device) 11, a driver (panel driver) 21, a control circuit board (external signal source) 12, a flexible board (external connecting component) 13, and a backlight unit (illumination device) 14. The liquid crystal panel 11 includes a display area AA configured to display an image and a non-display area NAA outside the display area AA. The driver 21 is configured to drive the liquid crystal panel 11. The control circuit board 12 is configured to supply various input signals from the outside to the driver 21. The flexible board 13 electrically connects the liquid crystal panel 11 to the external control circuit board 12. The backlight unit 14 is an external light source configured to supply light to the liquid crystal panel 11. The liquid crystal display device 10 further includes a pair of exterior components 15 and 16 that are front and rear components used in a pair to hold the liquid crystal panel 11 and the backlight unit 14 that are attached together. The exterior component 15 on the front side has an opening 15a through which images displayed in the display area AA of the liquid crystal panel 11 are viewed from the outside. The liquid crystal display device 10 according to this embodiment may be used in various kinds of electronic devices (not illustrated) such as mobile phones (including smartphones), laptop computers (including tablet computers), handheld terminals (including electronic books and PDAs), digital photo frames, portable video game players, and electronic-ink papers. The liquid crystal panel 11 in the liquid crystal display device 10 is in a range between some inches to ten and some inches. Namely, the liquid crystal panel 11 is in a size that is classified as a small or a small-to-medium.

The backlight unit 14 will be briefly described. As illustrated in FIG. 2, the backlight unit 14 includes a chassis 14a, light sources (e.g., cold cathode fluorescent tubes, LEDs, organic ELs), and an optical member. The chassis 14a has a box-like shape with an opening on the front side (opening toward the liquid crystal panel 11). The light sources, which are not illustrated, are disposed inside the chassis 14a. The optical member, which is not illustrated, is disposed to cover the opening of the chassis 14a. The optical member has a function to convert light from the light sources into planar light.

Next, the liquid crystal panel 11 will be described. As illustrated in FIG. 1, the liquid crystal panel 11 has a vertically-long rectangular overall shape (rectangular shape). The liquid crystal panel 11 includes the display area (active area) AA that is off centered toward one of ends of a long dimension thereof (the upper side in FIG. 1). The driver 21 and the flexible board 13 are mounted to a portion of the liquid crystal panel 11 closer to the other end of the long dimension of the liquid crystal panel 11 (the lower side in FIG. 1). An area of the liquid crystal panel 11 outside the display area AA is a non-display area (non-active area) NAA in which images are not displayed. The non-display area NAA includes a frame-shaped area around the display area AA (a frame portion of a CF board 11a, which will be described later) and an area provided at the other end of the long dimension (an exposed area of an array board 11b which does not overlap the CF board 11a and exposed, which will be described later). The area provided at the other end of the long dimension of the liquid crystal panel 11 includes a mounting area (an attachment area) to which the driver 21 and the flexible printed circuit board 13 are mounted. The short dimension of the liquid crystal panel 11 coincides with the X-axis direction of each drawing and the long dimension thereof coincides with the Y-axis direction of each drawing. In FIG. 1, a chain line box slightly smaller than the CF board 11a indicates a boundary of the display area AA. An area outside the solid line is the non-display area NAA.

Next, the components connected to the liquid crystal panel 11 will be described. As illustrated in FIGS. 1 and 2, the control circuit board 12 is mounted to the back surface of the chassis 14a (an outer surface on a side opposite from the liquid crystal panel 11) of the backlight unit 14 with screws. The control circuit board 12 includes a substrate and electronic components. The substrate is made of paper phenol or glass epoxy resin. The electronic components are mounted on the substrate and configured to supply various input signals to the driver 21. Traces (electrically conductive paths) which are not illustrated are formed in predetermined patterns. An end (end side) of the flexible printed circuit board 13 is electrically and mechanically connected to the control circuit board 12 via an anisotropic conductive film (ACF), which is not illustrated.

The flexible board (FPC board) 13 includes a base member made of synthetic resin having insulating property and flexibility (e.g., polyimide resin) as illustrated in FIG. 2. A number of traces are formed on the base member (not illustrated). The end of the long dimension of the flexible board 13 is connected to the control circuit board 12 disposed on the back surface of the chassis 14a as described above, while the other end of the long dimension of the flexible board 13 is connected to the array board 11b in the liquid crystal panel 11. The flexible printed circuit board 13 is therefore bent or folded back inside the liquid crystal display device 10 such that a cross-sectional shape thereof forms a U-like shape. At the ends of the long dimension of the flexible board 13, the wiring patterns are exposed to the outside and configured as terminals (not illustrated). The terminals are electrically connected to the control circuit board 12 and the liquid crystal panel 11. With this configuration, input signals supplied by the control circuit board 12 are transmitted to the liquid crystal panel 11.

As illustrated in FIG. 1, the driver 21 is provided by an LSI chip including drive circuits. The driver 21 is configured to operate according to signals supplied by the control circuit board 12 serving as a signal source, to process the input signal supplied by the control circuit board 12 to generate output signals, and to output the output signals to the display area AA in the liquid crystal panel 11. The driver 21 has a horizontally-long rectangular shape (an elongated shape that extends along the short side of the liquid crystal panel 11) in a plan view. The driver 21 is directly mounted to the non-display area NAA of the liquid crystal panel 11 (or the array board 11b, which will be described later), that is, mounted by the chip-on-glass (COG) mounting method. The long dimension and the short dimension of the driver 21 correspond to the X-axis direction (the short dimension of the liquid crystal panel 11) and the Y-axis direction (the long dimension of the liquid crystal panel 11), respectively.

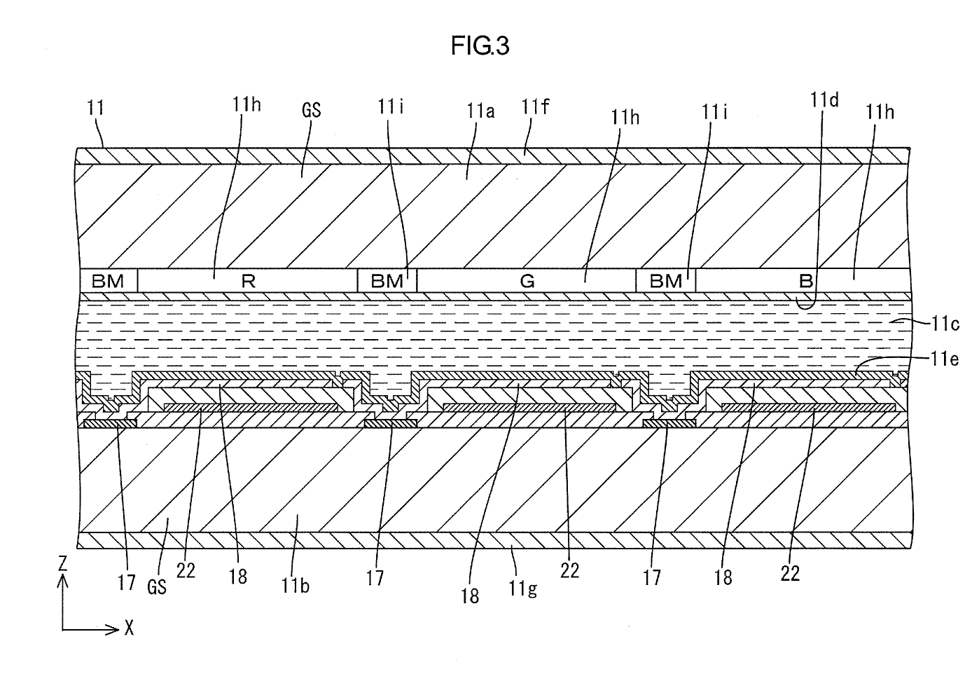

The liquid crystal panel 11 will be described in more detail. As illustrated in FIG. 3, the liquid crystal panel 11 includes a pair of substrates 11a and 11b, and a liquid crystal layer (liquid crystal) 11c. The liquid crystal layer 11c is interposed between the substrates 11a and 11b, and includes liquid crystal molecules having optical characteristics that change according to application of the electric field. The substrates 11a and 11b are bonded by a sealing agent (not illustrated) while a gap corresponding to the thickness of the liquid crystal layer 11c is maintained. The liquid crystal panel 11 according to this embodiment operates in a fringe field switching (FFS) mode that is a mode improved from an in-plane switching (IPS) mode. Of the pair of substrates 11a and 11b, the array board 11b is provided with pixel electrodes (second transparent electrodes) 18 and common electrodes (first transparent electrodes) 22, which will be described later. The electrodes 18 and the common electrodes 22 are provided in the different layers. Of the pair of substrates 11a and 11b, the substrate on the front side is the CF board (opposite substrate) 11a and the substrate on the back side (rear side) is the array board (display component) 11b. The CF board 11a and the array board 11b each include a glass substrate GS that is substantially transparent (i.e., having high light transmissivity). Various films are formed in layers on each glass substrate GS. As illustrated in FIGS. 1 and 2, the CF board 11a has a short dimension substantially equal to that of the array board 11b and a long dimension smaller than that of the array board 11b. The CF board 11a is bonded to the array board 11b with one of ends of the long dimension (the upper end in FIG. 1) aligned with a corresponding edge of the array board 11b. A predetermined area of the other end of the long dimension of the array board 11b (the lower end in FIG. 1) does not overlap the CF board 11a and front and back plate surfaces of the area are exposed to the outside. The mounting area in which the driver 21 and the flexible printed circuit board 13 are mounted is provided in this area. Alignment films 11d and 11e are formed on inner surfaces of the substrates 11a and 11b, respectively, for alignment of the liquid crystal molecules included in the liquid crystal layer 11c. The alignment films 11d and 11e are formed of, for example, polyimide, and are in solid patterns formed in a substantially whole area along the plate surfaces of the substrates 11a and 11b. The alignment films 11d and 11e are configured to align, by irradiation with light having a particular wavelength (for example, ultraviolet ray), the liquid crystal molecules in the irradiation direction of the light. Polarizing plates 11f and 11g are attached to the outer surfaces of the substrates 11a and 11b.

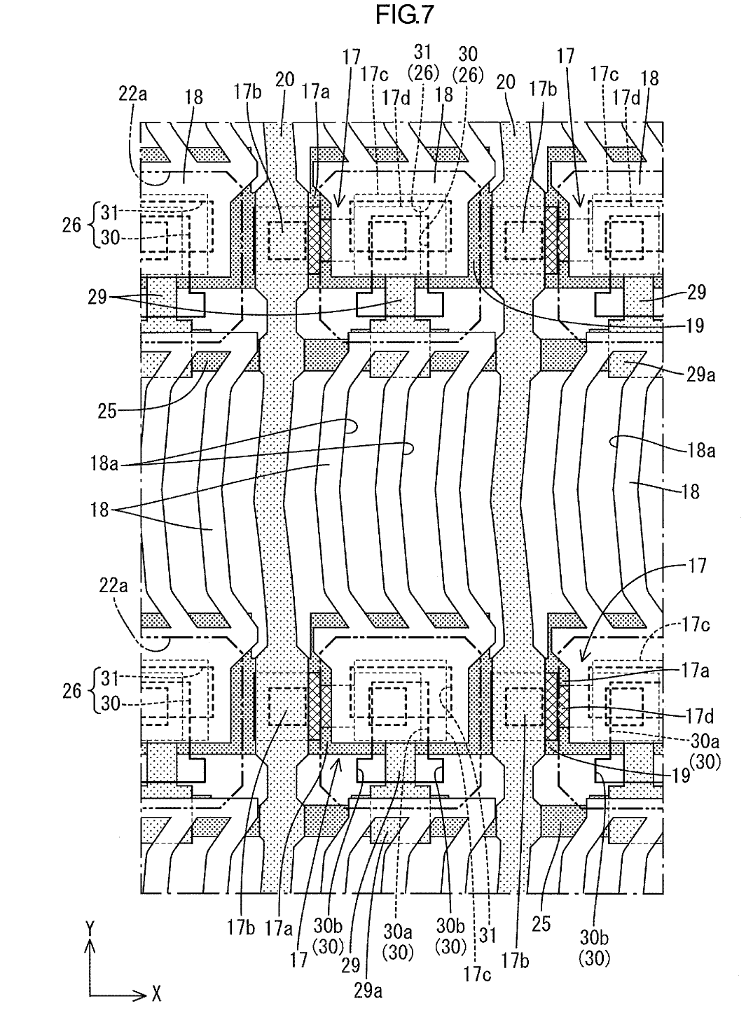

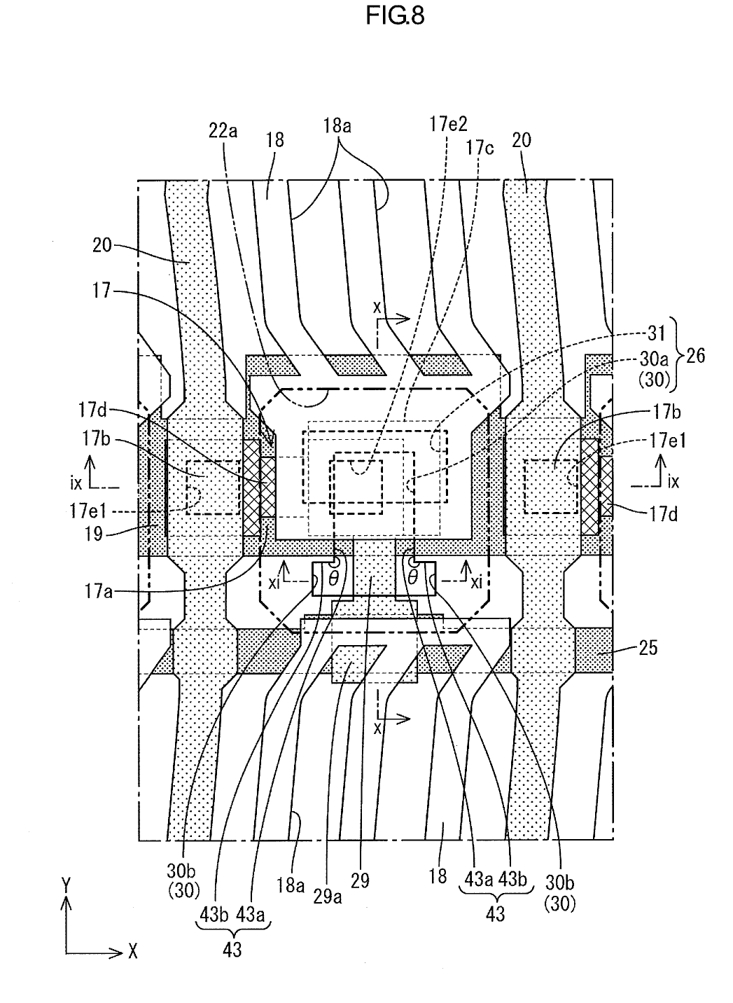

The films formed in layers on the inner surface of the array board 11b (on the liquid crystal layer 11c side, a surface opposite to the CF board 11a) by a known photolithography method will be described. As illustrated in FIG. 7, on the array board 11b, the following films are formed in the following sequence from the lowest layer (the grass substrate GS): a first metal film (first conductive film, gate metal film) 34, agate insulator (insulator, first insulator) 35, a semiconductor film 36, a protection film (insulator, etching stopper film) 37, a second metal film (first conductive film, source metal film) 38, a first interlayer insulator (insulator, second insulator) 39, an organic insulator (insulator) 40, a first transparent electrode film 23, a second interlayer insulator (third insulator) 41, and a second transparent electrode film (second conductive film) 24. In FIGS. 7 and 8, the first metal film 34, the semiconductor film 36, and the second metal film 38 are hatched.

The first metal film 34 is a multilayer film of titanium (Ti) and copper (Cu). The gate insulator 35 is formed at least above the first metal film 34 and is made of, for example, silicon oxide (SiO₂). The semiconductor film 36 is formed of an oxide thin film containing indium (In), gallium (Ga), and zinc (Zn), which are a kind of oxide semiconductors. The oxide semiconductor film that contains indium (In), gallium (Ga), and zinc (Zn), that is, the oxide semiconductor film 36 is amorphous or crystalline. The protection film 37 is made of silicon oxide (SiO₂). The second metal film 38 is a multilayer film that includes titanium (Ti) and copper (Cu). The first interlayer insulator 39 is made of silicon oxide (SiO₂). The organic insulator 40 is made of acrylic resin (e.g., polymethyl methacrylate (PMMA)), which is an organic material, and functions as a planarization film. The first transparent electrode film 23 and the second transparent electrode film. 24 are made of a transparent electrode material such as indium tin oxide (ITO) or zinc oxide (ZnO). The second interlayer insulator 41 is made of silicon nitride (SiNₓ). The first transparent electrode film 23 and the second transparent electrode film 24 among these films are formed only in the display area AA of the array board 11b, and are not formed in the non-display area NAA. The insulators made of the insulating materials, such as the gate insulator 35, the protection film 37, the first interlayer insulator 39, the organic insulator 40, and the second interlayer insulator 41, are formed in solid patterns disposed in a substantially whole area of the surface of the array board 11b (although holes are formed in some areas). The first metal film 34, the oxide semiconductor film 36, and the second metal film 38 are formed in predetermined patterns in the display area AA and the non-display area NAA of the array board 11b.

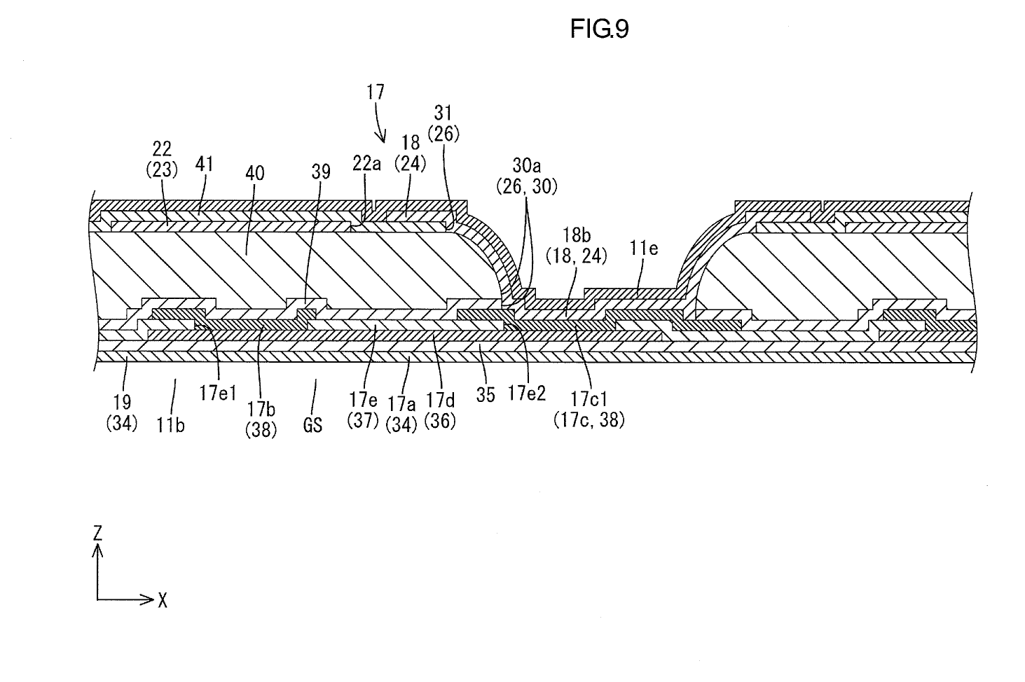

Next, configurations of components in the display area AA of the array board 11b will be described in sequence. As illustrated in FIGS. 7 and 8, in the display area AA of the array board 11b, a number of TFTs (transistors) 17, which are switching components, and a number of pixel electrodes 18 are disposed in a matrix. Gate lines (scanning lines, row control lines) 19 and source lines (column control lines, data lines) 20 are routed in a matrix such that each pair of display area TFT 17 and the pixel electrode 18 is in a cell defined by the gate lines 19 and the source lines 20. Namely, the TFTs 17 and the pixel electrodes 18 are disposed in parallel to be arranged in a matrix at respective corners defined by the gate lines 19 and the source lines 20 that are formed in a matrix. The gate lines 19 are formed from the first metal film 34 and the source lines 20 are formed from the second metal film 38. The gate insulator 35 and the protection film 37 are interposed between the gate line 19 and the source line 20 at an intersection thereof. The gate lines 19 and the source lines 20 are connected to gate electrodes 17a and source electrodes 17b of the TFTs 17, respectively. The pixel electrodes 18 are connected to drain electrodes 17c of TFTs 17 (FIG. 9). The gate line 19 is disposed overlapping one end (the lower end in FIG. 7) of the pixel electrode 18 in a plan view (viewed from the normal line direction relative to the plate surface of the array board 11b). In addition, the array board 11b is provided with an auxiliary capacitor line (storage capacitor line, Cs line) 25 that is in parallel to the gate line 19 and overlaps a portion of the pixel electrode 18 in a plan view. The auxiliary capacitor line 25 is made of the same metal film 34 as the gate line 19, and is provided overlapping the other end (the upper end in FIG. 7) in the pixel electrode 18 in a plan view, i.e., on the opposite side with the center of the pixel electrode 18 interposed between the auxiliary capacitor line 25 and the gate line 19 in the Y-axis direction. In other words, the auxiliary capacitor line 25 is provided adjacent to the gate line 19 while a predetermined gap is maintained therebetween in the Y-axis direction. The gate line 19 is connected to the pixel electrode 18 adjacent to the pixel electrode 18 on the upper side overlapping the auxiliary capacitor line 25 via the TFT 17 as illustrated in FIG. 7. The auxiliary capacitor lines 25 and the gate lines 19 are alternately disposed in the Y-axis direction.

As illustrated in FIG. 8, the TFT 17 is mounted on the gate line 19, i.e., disposed entirely overlapping the gate line 19 in a plan view. A portion of the gate line 19 constitutes the gate electrode 17a of the TFT 17, and the portion of the source line 20 that overlaps the gate line 19 in a plan view constitutes the source electrode 17b of the TFT 17. The TFT 17 includes the drain electrode 17c, which has an island shape by being disposed opposite to the source electrode 17b with a predetermined gap therebetween in the X-axis direction. The drain electrode 17c is formed from the second metal film 38, which is the same as the source electrode 17b (source line 20), and is disposed overlapping one end of the pixel electrode 18 (portion where a later-described slit 18a is not formed) in a plan view. The drain electrode 17c has a drain line 29 formed from the same second metal film 38 connected thereto. The drain line 29 is extended from the connected drain electrode 17c in the Y-axis direction toward the lower side in FIG. 8, i.e., toward the auxiliary capacitor line 25, and an extension end thereof is provided with a capacitance formation portion 29a forming capacitance by overlapping the auxiliary capacitor line 25 and the next pixel electrode 18 (specifically, the pixel electrode 18 adjacent to and below the pixel electrode 18 connected to the drain electrode 17c in FIG. 8) in a plan view. The portion of the gate line 19 not overlapping the source line 20 in a plan view is formed to have a larger line width than the portion overlapping the source line 20 in a plan view, while the portion of the source line 20 overlapping the gate line 19 and the auxiliary capacitor line 25 in a plan view is formed to have a larger line width than the portion not overlapping the gate line 19 and the auxiliary capacitor line 25 in a plan view.

As illustrated in FIG. 9, the TFT 17 includes the gate electrode 17a formed from the first metal film 34, a channel 17d formed from the semiconductor film 36 and disposed so as to overlap the gate electrode 17a in a plan view, a protection portion 17e formed from the protection film 37 and including two openings 17e1 and 17e2 that penetrate at positions overlapping the channel 17d in a plan view, the source electrode 17b formed from the second metal film 38 and connected to the channel 17d via one of the openings 17e1 and 17e2, specifically the opening 17e1, and the drain electrode 17c formed from the second metal film 38 and connected to the channel 17d via the other one of the openings 17e1 and 17e2, specifically the opening 17e2. The gate electrode 17a includes a portion of the gate line 19 overlapping at least the source electrode 17b, the drain electrode 17c, and the channel 17d in a plan view. The channel 17d extends along the X-axis direction and bridges between the source electrode 17b and the drain electrode 17c to allow a flow of electrons between the electrodes 17b and 17c. The semiconductor film 36 that forms the channel 17d is an oxide thin film containing indium (In), gallium (Ga), and zinc (Zn). The oxide thin film containing indium (In), gallium (Ga), and zinc (Zn) has electron mobility higher than that of an amorphous silicon thin film, for example, 20 to 50 times higher. Therefore, the TFTs 17 can be easily downsized and the amount of transmitted light through each pixel electrode 18 can be increased to the maximum level. This configuration is preferable for enhancement of image resolution and reduction of power consumption. Each TFT 17 including the oxide thin film containing indium (In), gallium (Ga), and zinc (Zn) is an inverted-staggered type having a configuration in which the gate electrode 17a is disposed at the bottom and the channel 17d is disposed thereon with the gate insulator 35 interposed therebetween. A stacking structure of the TFT 17 is similar to that of a commonly-used TFT including an amorphous silicon thin film.

Each pixel electrode 18 is formed from the second transparent electrode film 24 as illustrated in FIGS. 8 and 9. The pixel electrode 18 has a vertically-long rectangular overall shape (approximately rectangular shape) in a plan view and disposed in an area defined by the gate lines 19 and the source lines 20. One end of the pixel electrode 18 overlaps the gate line 19 in a plan view and the portion excluding the overlapping portion does not overlap the gate line 19 in a plan view. The non-overlapping portion includes a plurality of longitudinal slits 18a (two in FIG. 8), with which a comb-shaped portion is formed. This slit 18a extends to the portion of the pixel electrode 18 that overlaps the gate line 19 in a plan view. The lower end of the pixel electrode 18 in FIG. 8 is positioned between the lowest end position of the gate line 19 and the lowest end position of the drain electrode 17c, specifically closer to the lower end position of the drain electrode 17c. The pixel electrode 18 is formed on the second interlayer insulator 41 and the second interlayer insulator 41 exists between the pixel electrode 18 and the common electrode 22, which will be described below. Under the pixel electrode 18, the first interlayer insulator 39, the organic insulator 40, and the second interlayer insulator 41 are disposed. Portions of them overlapping the drain electrode 17c and the pixel electrode 18 in a plan view include display area side contact holes (contact holes, first contact holes) 26 that penetrate from the top to the bottom. The pixel electrode 18 is connected to the drain electrode 17c via the display area side contact holes 26. Thus, when current is supplied to the gate electrode 17a of the TFT 17, current flows between the source electrode 17b and the drain electrode 17c through the channel 17d and a predetermined potential is applied to the pixel electrode 18. The display area side contact hole 26 includes a lower contact hole 30 formed penetrating the first interlayer insulator 39 and the organic insulator 40, and an upper contact hole 31 formed penetrating the second interlayer insulator 41 and overlapping partially the lower contact hole 30 in a plan view. As described below in detail, the contact holes 30 and 31 have different planar shapes. A portion of the pixel electrode 18 that is formed inside the lower contact hole 30 and the upper contact hole 31 serves as a pixel electrode side connector 18b to be connected to the drain electrode 17c. On the other hand, a portion of the drain electrode 17c that faces the front side through the lower contact hole 30 and the upper contact hole 31 serves as a drain electrode side connector 17c1 to be connected to the pixel electrode side connector 18b of the pixel electrode 18.

The common electrode 22 is formed from the first transparent electrode film 23 as illustrated in FIGS. 8 and 9. The common electrode 22 is a solid electrode disposed in a substantially whole area of the display area AA of the array board 11b. The common electrode 22 is sandwiched between the organic insulator 40 and the second interlayer insulator 41. A common potential (a reference potential) is applied to the common electrode 22 through a common line, which is not illustrated. By controlling the potential to be applied to the pixel electrode 18 by the TFT 17 as described above, a predetermined potential difference is generated between the electrodes 18 and 22. When the potential difference is generated between the electrodes 18 and 22, a fringe field (an oblique field) including a component in a direction normal to a plate surface of the array board 11b is applied to the liquid crystal layer 11c in addition to a component in a direction along the plate surface of the array board 11b because of the slit 18a of the pixel electrode 18. Therefore, not only alignment of the liquid crystal molecules in the slit 18a in the liquid crystal layer 11c but also alignment of the liquid crystal molecules on the pixel electrode 18 is properly switchable. With this configuration, the aperture ratio of the liquid crystal panel 11 increases and a sufficient amount of transmitted light is obtained. Furthermore, high view-angle performance is achieved. The common electrode 22 is provided with an opening 22a in a portion overlapping with a portion of the TFT 17 in a plan view (specifically, in the range of an approximately rectangular shape surrounded by a two-dot chain line in FIG. 8).

Next, configurations of components in the display area AA of the CF board 11a will be described in detail. As illustrated in FIG. 3, the CF board 11a includes a color filter 11h including red (R), green (G), and blue (B) color portions arranged in a matrix so as to overlap the pixel electrodes 18 on the array board 11b side in a plan view. A light blocking layer (a black matrix) 11i is formed in a grid for preventing colors from mixing. Each line of the grid is located between the adjacent color portions of the color filters 11h. The light blocking layer 11i is disposed to overlap the gate lines 19 and the source lines 20 in a plan view. An alignment film 11d is formed on the surfaces of the color filters 11h and the light blocking layer 11i. Each display pixel of the liquid crystal panel 11, which constitutes a display unit, includes a set of three color portions, that is, R (red), G (green) and B (blue) color portions and three pixel electrodes 18 opposite to the color portions. The display pixel includes a red pixel including the R color portion, a green pixel including the G color portion, and a blue pixel including the B color portion. The pixels are arranged on the plate surface of the liquid crystal panel 11 in repeated sequence along the row direction (the X-axis direction) and form groups of pixels. The groups of pixels are arranged in the column direction (the Y-axis direction).

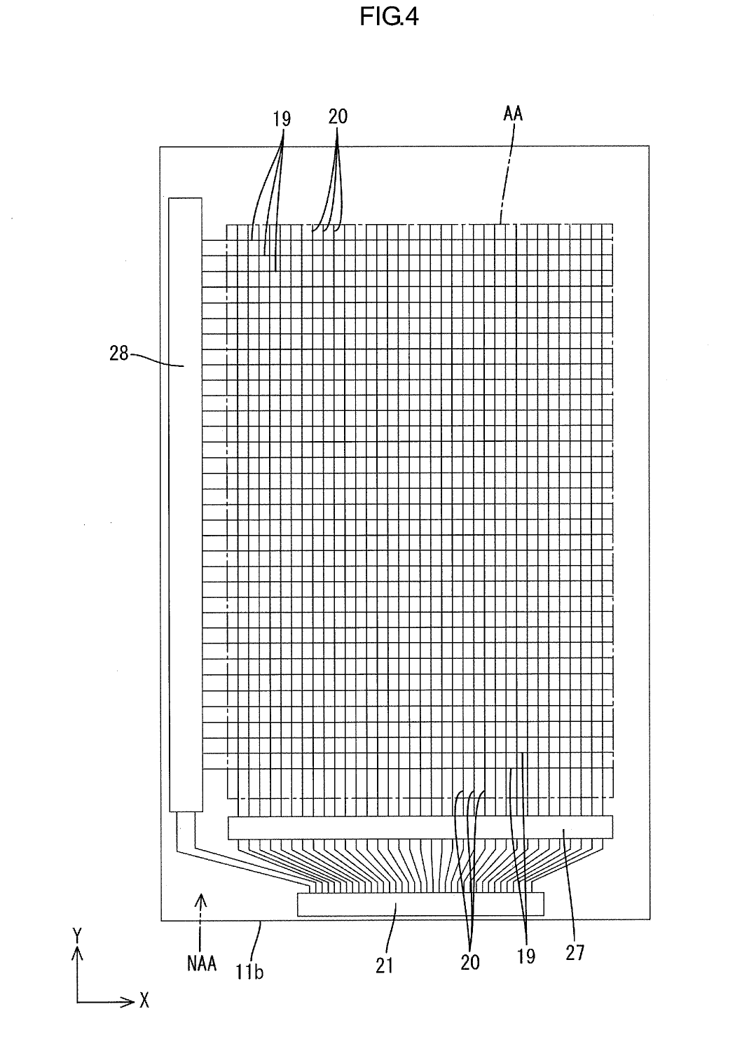

Next, configurations of components in the non-display area NAA of the array board 11b will be described in detail. As illustrated in FIG. 4, a column control circuit 27 is disposed in a portion of the non-display area NAA of the array board 11b adjacent to the short edge of the display area AA. A row control circuit 28 is disposed in a portion of the non-display area NAA adjacent to the long edge of the display area AA. The column control circuit 27 and the row control circuit 28 are configured to perform control for supplying output signals from the driver 21 to the TFTs 17. The column control circuit 27 and the row control circuit 28 are monolithically fabricated on the array board 11b with the oxide thin film (semiconductor film 36) containing indium (In), gallium (Ga), and zinc (Zn) as a base, which is similar to the TFT 17. The column control circuit 27 and the row control circuit 28 include control circuits configured to perform control for supplying the output signals to the TFTs 17. The column control circuit 27 and the row control circuit 28 are formed on the array board 11b by patterning using a known photolithography method during patterning of the TFTs 17 in the fabrication process of the array board 11b.

As illustrated in FIG. 4, the column control circuit 27 is disposed adjacent to the short edge of the display area AA located at the lower side in FIG. 4. Namely, the column control circuit 27 is disposed in a horizontally-long rectangular area along the X-axis direction (direction where the source lines 20 are arranged) between the display area AA and the driver 21 with respect to the Y-axis direction. The column control circuit 27 is connected to the source lines 20 in the display area AA. The column control circuit 27 includes a switching circuit (RGB switching circuit) configured to sort image signals in the output signals from the driver 21 to the respective source lines 20. The source lines 20 are disposed in the display area AA of the array board 11b along the X-axis direction and parallel to each other. The source lines 20 are connected to the TFTs 17 that form R (red), G (green) and B (blue) pixels. The column control circuit 27 sorts the image signals from the driver 21 using the switching circuit and supplies the sorted signals to the respective R, G, B source lines 20. The column control circuit 27 may include ancillary circuits such as a level-shifter circuit and ESD protection circuit.

As illustrated in FIG. 4, the row control circuit 28 is disposed adjacent to the long edge of the display area AA on the left in FIG. 4 within a vertically-long area that extends in the Y-axis direction (direction where the gate lines 19 are arranged). The row control circuit 28 is connected to the gate lines 19 in the display area AA. The row control circuit 28 includes a scanning circuit configured to supply scan signals included in the output signals from the driver 21 to the gate lines 19 at the predetermined timing to scan the gate lines 19 in sequence. The gate lines 19 are disposed in the display area AA of the array board 11b along the Y-axis direction and parallel to each other. The row control circuit 28 supplies control signals (scan signals) from the driver 21 using the scanning circuit to the gate lines 19 in sequence from the one at the top in FIG. 4 to the one at the bottom to scan the gate lines 19. The scanning circuit included in the row control circuit 28 includes a buffer circuit for amplifying the scan signal. The row control circuit 28 may include ancillary circuits such as a level-shifter circuit and an ESD protection circuit. The column control circuit 27 and the row control circuit 28 are connected to the driver 21 via connection lines formed on the array board 11b.

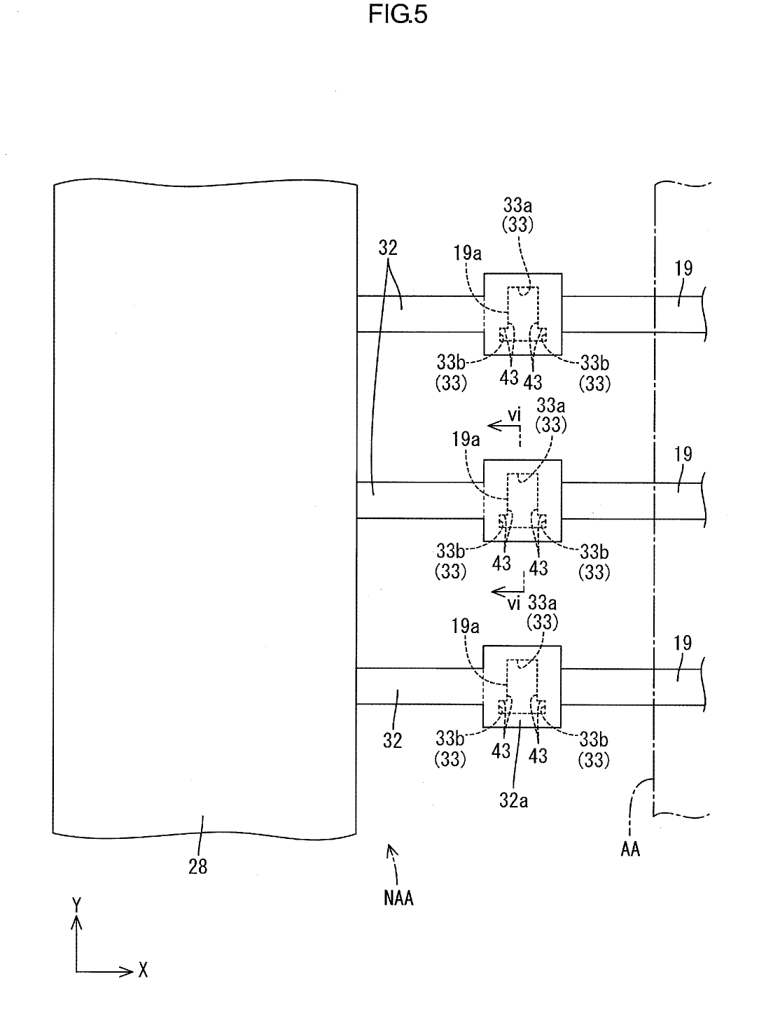

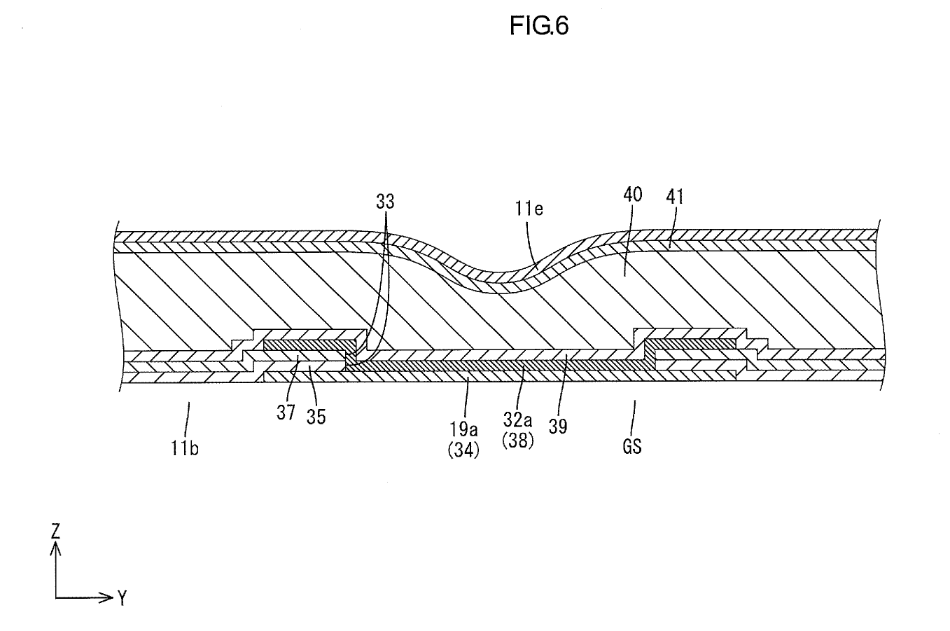

As illustrated in FIG. 5, connection lines 32 to be connected to the gate lines 19 are led out to the display area AA from the row control circuit 28. The connection lines 32 are made of the same second metal film 38 as the source lines 20. The connection lines 32 extend from the row control circuit 28 toward the display area AA along the X-axis direction (direction where the gate lines 19 extend), and have their extension ends serving as connection line side connectors 32a to be connected to the gate lines 19 in the non-display area NAA. The gate line 19 is led out from the display area AA to the non-display area NAA, and an end thereof overlaps the connection line side connector 32a in a plan view and serves as a gate line side connector 19a to be connected to the connection line side connector 32a. As illustrated in FIGS. 5 and 6, at a position where the gate insulator 35 and the protection film 37 disposed below the connection line 32 overlap the connection line side connector 32a and the gate line side connector 19a in a plan view, a non-display area side contact hole (contact hole, second contact hole) 33 is formed penetrating vertically, and through the non-display area side contact hole 33, the connection line side connector 32a is connected to the gate line side connector 19a. The non-display area side contact hole 33 is positioned between the display area AA and the row control circuit 28 in the X-axis direction in the non-display area NAA. A number of (the same number of gate lines 19 arranged in parallel) contact holes 33 are intermittently arranged in parallel along the Y-axis direction, i.e., the direction where the row control circuit 28 extends.

Each of the insulators 35, 37, 39, 40, and 41 provided for the array board 11b as above has the display area side contact hole 26 (lower contact hole 30) and the non-display area side contact hole 33. Therefore, at the portion where the contact holes 26 and 33 are formed, the alignment film 11e disposed at the uppermost layer position is formed to have a depressed shape as illustrated in FIGS. 6 and 9. The alignment film 11e is formed in a manner that the solution for forming the alignment film 11e is applied locally to the inner surface of the array board 11b using, for example, a later-described inkjet device 42, and the applied solution spreads along the surface of the array board 11b, thereby forming the alignment film 11e in the solid pattern. In this film forming process, it is difficult for the solution for forming the alignment film 11e to enter the portion where each of the contact holes 26 and 33 is formed to have the depressed shape in the array board 11b, resulting in that the film-deficient portion is easily formed in the alignment film 11e. The planar arrangement of the film-deficient portion substantially coincides with the contact holes 26 and 33 and has regularity. Accordingly, moire may be caused. In particular, the liquid crystal panel 11 with the definition enhanced by the use of the oxide semiconductor as the semiconductor film 36 of the TFT 17 may have a larger number of contact holes, and additionally, the space between the adjacent contact holes may be smaller because one pixel has a smaller area. Accordingly, the moire is more likely to occur. In conventional configuration, the contact holes are arranged irregularly. In this configuration, each contact hole cannot be arranged beyond an area of the pixel that includes the contact hole. Namely, a distance between the adjacent contact holes cannot be larger than a certain distance. Accordingly, moire reducing effect is limited.

In this embodiment, at least a portion of the edge of each of the contact holes 26 and 33 of the insulators 35, 37, 39, 40, and 41 includes a bending portion 43 that toward an inner side of the contact hole 26 or 33 such that an outer angle of the bending portion 43 is a reflex angle in a plan view as illustrated in FIGS. 5 and 8. The “reflex angle” herein refers to an angle in the range from 180° to 360°. Because the edge of each of the contact holes 26 and 33 includes the bending portion 43, when the solution for forming the alignment film 11e supplied to the outside of the contact holes 26 and 33 spreads into the contact holes 26 and 33 and reaches the bending portion 43, the solution is drawn into the contact holes 26 and 33 by the bending portion 43. The reason why the solution is drawn to the contact holes 26 and 33 may be that a force may be exerted on the solution to spread in a wide angle toward the inside of the contact holes 26 and 33 due to the bending portion 43 that has the reflected outer angle when the solution reaches the bending portion 43. According to the configuration, it is easier to arrange the alignment film 11e inside the contact holes 26 and 33 and defects are less likely to be developed in the alignment film 11e. Accordingly, effect to reduce or suppress the moire is obtained. A shape of the contact holes 26 and 33 in a plan view will be described in detail.

The lower contact hole 30 included in the display area side contact hole 26 includes, as illustrated in FIG. 8, a contact hole main portion 30a overlapping at least a portion of the drain electrode 17c formed from the second metal film 38 and the pixel electrode 18 formed from the second transparent electrode film 24 in a plan view, and an expanded hole portion 30b formed by extending a portion of the contact hole main portion 30a. The contact hole main portion 30a and the expanded hole portion 30b of the lower contact hole 30 have a vertically-long rectangular shape (rectangular shape) in a plan view, and a length direction (long dimension) coincides with the Y-axis direction and a width direction (short dimension) coincides with the X-axis direction. Of the contact hole main portion 30a, a little more than a half of the upper side in FIG. 8 (opposite to the auxiliary capacitor line 25 side overlapping the capacitance formation portion 29a of the drain line 29 in a plan view) overlaps the drain electrode 17c and the pixel electrode 18 in a plan view and a little less than a half of the lower side in the drawing (the auxiliary capacitor line 25 side overlapping the capacitance formation portion 29a of the drain line 29 in a plan view) does not overlap the drain electrode 17c and the pixel electrode 18 in a plan view. Therefore, a little more than a half portion on the upper side in FIG. 8 of the contact hole main portion 30a can contribute to the connection between the drain electrode 17c and the pixel electrode 18. Furthermore, the lower end in FIG. 8 of the contact hole main portion 30a does not overlap the gate line 19 in a plan view. The width of the contact hole main portion 30a is set to be larger than the line width of the drain line 29. In the lower end of the contact hole main portion 30a in FIG. 8, the central portion in the width direction (X-axis direction) overlaps the drain line 29 in a plan view but both side portions in the width direction (including both corners) do not overlap the drain line 29 in a plan view.

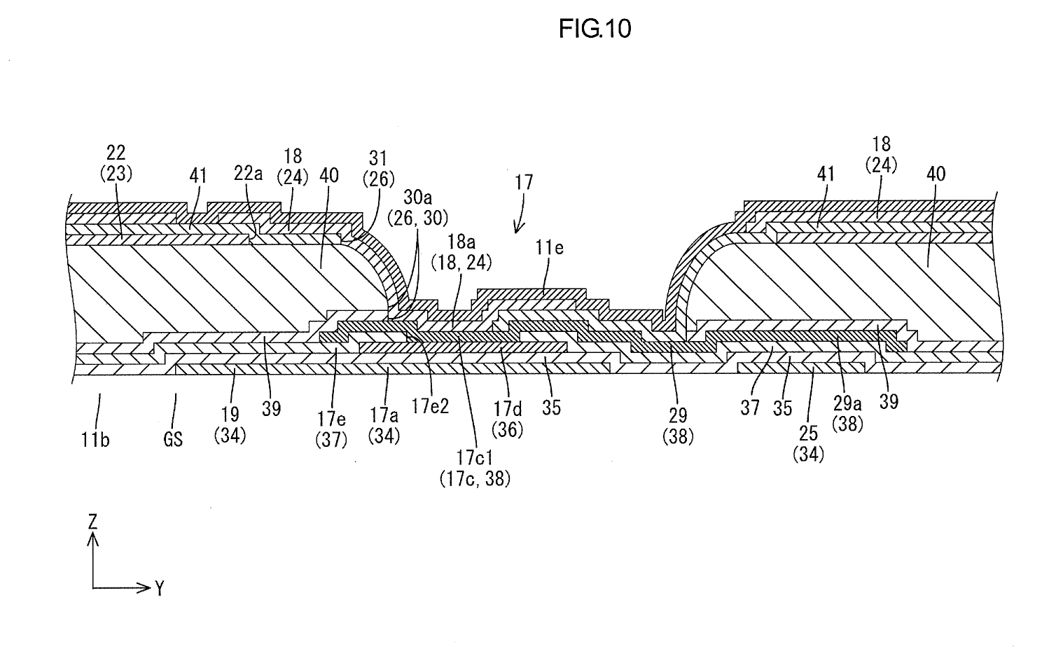

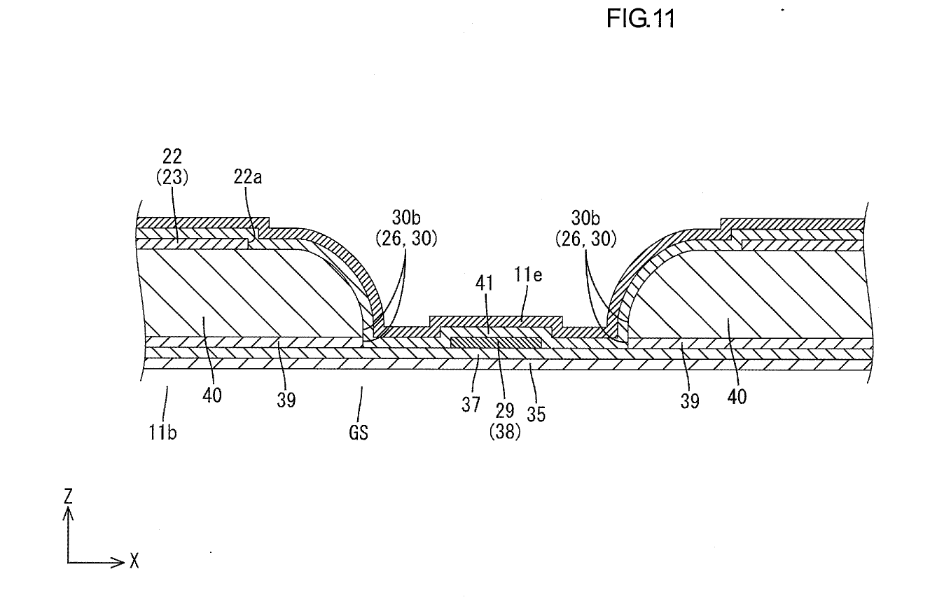

On the other hand, the expanded hole portion 30b is formed by extending a portion of the contact hole main portion 30a that is relatively far from the center of the pixel electrode 18 as illustrated in FIG. 7, more specifically extending a corner of the contact hole main portion 30a that does not overlap the pixel electrode 18 in a plan view. A pair of expanded hole portions 30b is formed at the symmetric position as illustrated in FIG. 8 by extending a pair of corners of the contact hole main portion 30a that does not overlap the pixel electrode 18 in a plan view. The expanded hole portion 30b does not overlap the pixel electrode 18 in a plan view and does not overlap the drain electrode 17c and the drain line 29 in a plan view. In addition, the expanded hole portion 30b does not overlap the gate electrode 17a, the gate line 19, and the auxiliary capacitor line 25 formed from the first metal film 34 in a plan view. Therefore, as illustrated in FIGS. 10 and 11, the bottom of the expanded hole portion 30b is lower than the portion of the contact hole main portion 30a that overlaps the drain line 29 in a plan view by the film thickness of the drain line 29b, and moreover, the bottom of the expanded hole portion 30b is lower than the portion of the contact hole main portion 30a that overlaps the drain electrode 17c in a plan view by the total film thickness of the gate electrode 17a, the drain electrode 17c, and the pixel electrode 18. Moreover, the expanded hole portion 30b is located between the gate line 19 and the auxiliary capacitor line 25 in a plan view as illustrated in FIG. 8, thereby forming a valley.

Moreover, as illustrated in FIG. 8, edges 43a and 43b communicating with each other at the contact hole main portion 30a and the expanded hole portion 30b constituting the lower contact hole 30 form the bending portions 43 as described above. Specifically, a first edge 43a of the edges of the contact hole main portion 30a, which extends along the length direction (Y-axis direction), and a second opening edge 43b of the edges of the expanded hole portion 30b, which extends along the width direction (X-axis direction) and which is adjacent to the first edge 43a, communicate with each other. The angle θ formed therebetween at their apex (intersection) on the inside of the lower contact hole 30 in a plan view is approximately 270°, a reflex angle, and these first edge 43a and second edge 43b constitute the bending portion 43. In other words, the first edge 43a forming the bending portion 43 intersects with the second edge 43b so as to forma reflex angle on the inside, namely, form a minor angle (approximately 90°) on the outside with the second edge 43b. Additionally, the expanded hole portion 30b is formed to have a smaller opening width than the contact hole main portion 30a. Specifically, the maximum value (length) of the opening width of the expanded hole portion 30b is smaller than the minimum value (width) of the opening width of the contact hole main portion 30a. Note that the opening width of each of the contact hole main portion 30a and the expanded hole portion 30b is defined by the distance between a pair of opposite edges.

As illustrated in FIG. 8, the upper contact hole 31 of the display area side contact hole 26 has a horizontally-long rectangular shape in a plan view, and the length direction (long dimension) coincides with the X-axis direction and the width direction (short dimension) coincides with the Y-axis direction. The upper contact hole 31 is disposed partially overlapping the contact hole main portion 30a of the lower contact hole 30, specifically overlapping an upper end of the contact hole main portion 30a in FIG. 8, i.e., the end opposite to the expanded hole portion 30b in a plan view. Therefore, the upper contact hole 31 is disposed not overlapping the expanded hole portion 30b of the lower contact hole 30 in a plan view. The pixel electrode 18 is connected to the drain electrode 17c through the portion where the upper contact hole 31 overlaps the lower contact hole 30 (contact hole main portion 30a). In other words, the portions of the upper contact hole 31 and the lower contact hole 30 that do not overlap each other do not contribute to the connection between the pixel electrode 18 and the drain electrode 17c.

Next, the planar shape of the non-display area side contact hole 33 will be described. The non-display area side contact hole 33 includes, as illustrated in FIG. 5, a contact hole main portion 33a overlapping the gate line side connector 19a of the gate line 19 formed from the first metal film 34 and the connection line side connector 32a of the connection line 32 formed from the second metal film 38 in a plan view, and an expanded hole portion 33b formed by extending a portion of the contact hole main portion 33a. The contact hole main portion 33a and the expanded hole portion 33b of the non-display area side contact hole 33 have a vertically-long rectangular shape (rectangular shape) in a plan view, and the length direction (long dimension) coincides with the Y-axis direction and the width direction (short dimension) coincides with the X-axis direction. These contact hole main portion 33a and expanded hole portions 33b entirely overlap the gate line side connector 19a and the connection line side connector 32a in a plan view. The expanded hole portions 33b are formed at the symmetrical position by extending a pair of lower corners of the contact hole main portion 33a in FIG. 5. The bending portion 43 is formed by the communicating edges of the contact hole main portion 33a and the expanded hole portion 33b of the non-display area side contact hole 33. Since the configuration of the bending portion 43 formed at the edge of the non-display area side contact hole 33 is similar to that of the bending portion 43 formed at the edge of the lower contact hole 30, the description is not repeated.

This embodiment has the above configuration, and next the operation thereof will be described. The procedure of manufacturing components on the array board 11b of the liquid crystal panel 11 will be described in detail.

Components are sequentially formed on the array board 11b by a known photolithography method. Specifically, first, the first metal film 34 is formed on the surface of the array board 11b and patterned, thereby forming the gate electrode 17a, the gate line 19, the auxiliary capacitor line 25, and the like as illustrated in FIG. 8. After that, the gate insulator 35 is formed and patterned, thereby forming the lower part of the non-display area side contact hole 33 (see FIG. 5). Next, the semiconductor film 36 is formed and patterned to form the channel 17d and the like and then, the protection film 37 is formed and patterned, so that the protection portion 17e having openings 17e1 and 17e2 is formed and the upper part of the non-display area side contact hole 33 is formed. In the process of forming the gate insulator 35 and the protection film 37 (first film forming process), along with the formation of the non-display area side contact hole 33, the bending portion 43 corresponding to a portion of the edges is also formed.

After that, the second metal film 38 is formed and patterned, thereby forming the source electrode 17b, the drain electrode 17c, the source line 20, the drain line 29, the connection line 32, and the like. Of the connection line 32 formed at this time, the connection line side connector 32a is connected to the gate line side connector 19a of the gate line 19 on the lower side through the non-display area side contact hole 33 provided for the gate insulator 35 and the protection film 37 (see FIG. 6). After that, the first interlayer insulator 39 and the organic insulator 40 are formed and patterned, thereby forming the lower contact hole 30 that forms the display area side contact hole 26. In the process of forming the first interlayer insulator 39 and the organic insulator 40 (first film forming process), along with the formation of the lower contact hole 30, the bending portion 43 corresponding to a portion of the edges thereof is also formed. When the organic insulator 40 is formed in the process of forming the first interlayer insulator 39 and the organic insulator 40, the opening is patterned in the organic insulator 40 using a mask and the organic insulator 40 having the opening is used as a resist to etch the first interlayer insulator 39 on the lower side. Thus, the first interlayer insulator 39 having the opening communicating to the opening of the organic insulator 40 can be formed and therefore the lower contact hole 30 is formed.

Then, the first transparent electrode film 23 is formed and patterned, thereby forming the common electrode 22 with the opening 22a. After that, the second interlayer insulator 41 is formed and patterned, thereby forming the upper contact hole 31 forming the display area side contact hole 26 so as to communicate to a portion of the lower contact hole 30. Next, the second transparent electrode film 24 is formed and patterned, thereby forming the pixel electrode 18 with the slit 18a. Of the pixel electrode 18 formed at this time, the pixel electrode side connector 18b is connected to the drain electrode side connector 17c1 of the drain electrode 17c on the lower side through the display area side contact hole 26 (see FIGS. 9 and 10). After that, the alignment film 11e is formed (see FIG. 9 to FIG. 11). In the process of forming the alignment film 11e (second film forming process), the inkjet device 42 as below is used.

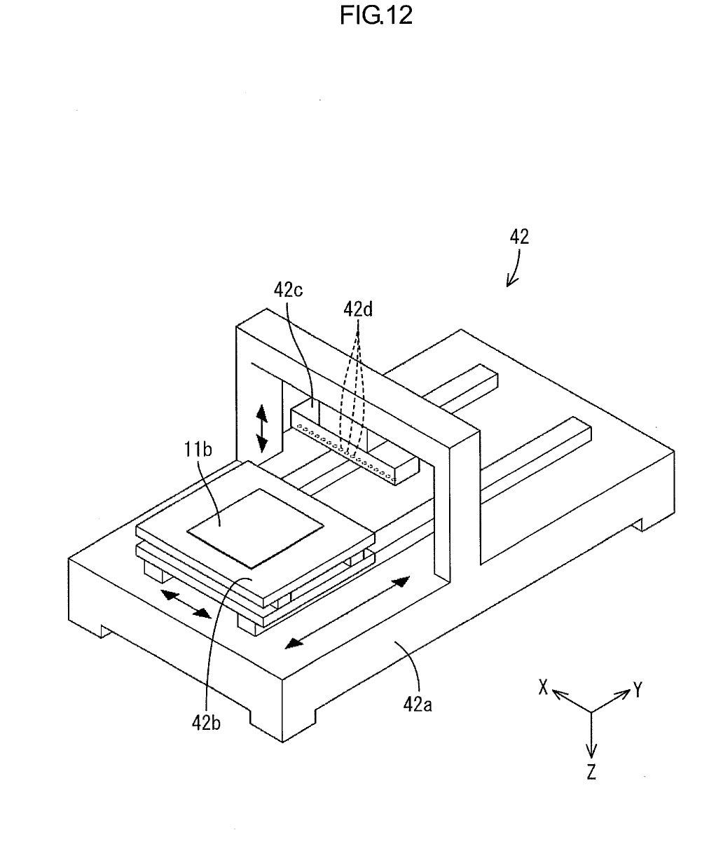

The inkjet device 42 used in the formation of the alignment film 11e includes, as illustrated in FIG. 12, at least a base stand 42a, a stage 42b which is disposed on the base stand 42a and on which the array board 11b is mounted, and a nozzle head 42c disposed on the base stand 42a and disposed opposite to the stage 42b with the array board 11b interposed between the stage 42b and the nozzle head 42c. The solution for forming the alignment film 11e is supplied to the nozzle head 42c from a supply tank, which is not illustrated, and the nozzle head 42c is provided with a number of nozzles (discharge ports) 42d configured to discharge droplets LD of the solution arranged in parallel intermittently at substantially equal intervals along the X-axis direction. The stage 42b is configured to move in the X-axis direction and the Y-axis direction relative to the nozzle head 42c on the base stand 42a. The nozzle head 42c is configured to move in the Z-axis direction relative to the stage 42b on the base stand 42a.

In the process of forming the alignment film 11e (second film forming process), as illustrated in FIG. 12, the array board 11b is mounted on the stage 42b in the inkjet device 42 with the above configuration, and the array board 11b is aligned relative to the nozzle head 42c by moving the stage 42b in the X-axis direction and the Y-axis direction and the nozzle head 42c is moved in the Z-axis direction to be disposed close to the array board 11b with a predetermined space from the array board 11b. Then, the droplets LD of the solution for forming the alignment film 11e are intermittently discharged from the nozzles 42d of the nozzle head 42c while the stage 42b is moved in the Y-axis direction so that the array board 11b crosses the nozzle head 42c. After the droplet LD of the solution discharged out of the nozzle 42d reaches a predetermined position on an inner surface of the array board 11b, the droplet LD spreads on the plate surface and connects to the adjacent droplet LD. Thus, the solution for forming the alignment film 11e is applied without unevenness to the entire region of the array board 11b (the portion overlapping the contact holes 30 and 33 in a plan view and the portion not overlapping the contact holes 30 and 33 in a plan view). After that, the applied solution for forming the alignment film 11e is dried and subjected to an optical alignment process (alignment process), thereby forming the alignment film 11e.

Here, the droplets LD of the solution for forming the alignment film 11e having reached the portion of the surface of the array board 11b which corresponds to the portion not overlapping the contact holes 30 and 33 with the bending portions 43 in a plan view spread to the inside of the contact holes 30 and 33 with the bending portions 43. In this case, upon the reach of the droplets LD at the bending portions 43 in the edges of the contact holes 30 and 33, the droplets LD are drawn into the contact holes 30 and 33 by the bending portions 43 as illustrated in FIG. 13 and moved in, for example, a direction indicated by an arrow in the drawing. Note that the droplet LD is illustrated by a two-dot chain line in FIG. 13. The reason why the droplet LD is drawn into the contact holes 30 and 33 is as follows: for example, upon the reach of the droplet LD at the bending portion 43, a force operates to cause the bending portion 43 forming the reflex angle on the inside in a plan view to spread the droplet LD in a wide angle toward the contact hole main portions 30a and 33a side and the expanded hole portions 30b and 33b side, thereby decreasing the surface tension of the droplet LD. This is considered reasonable because if the droplet LD has reached the corner with a right angle, i.e., a minor angle on the inside in a plan view at the edges of the contact holes 30 and 33, the force operates to cause the droplet LD to fall within the space held between the pair of edges constituting the corner, so that the surface tension of the droplet LD becomes relatively larger than in the above case; therefore, it is difficult for the droplet LD to enter the contact holes 30 and 33. According to the configuration, the alignment film 11e is easily formed also in the portion of the array board 11b that overlaps the contact holes 30 and 33 in a plan view. Therefore, the defects are less likely to be developed in the alignment film lie and the moire is properly reduced or suppressed.

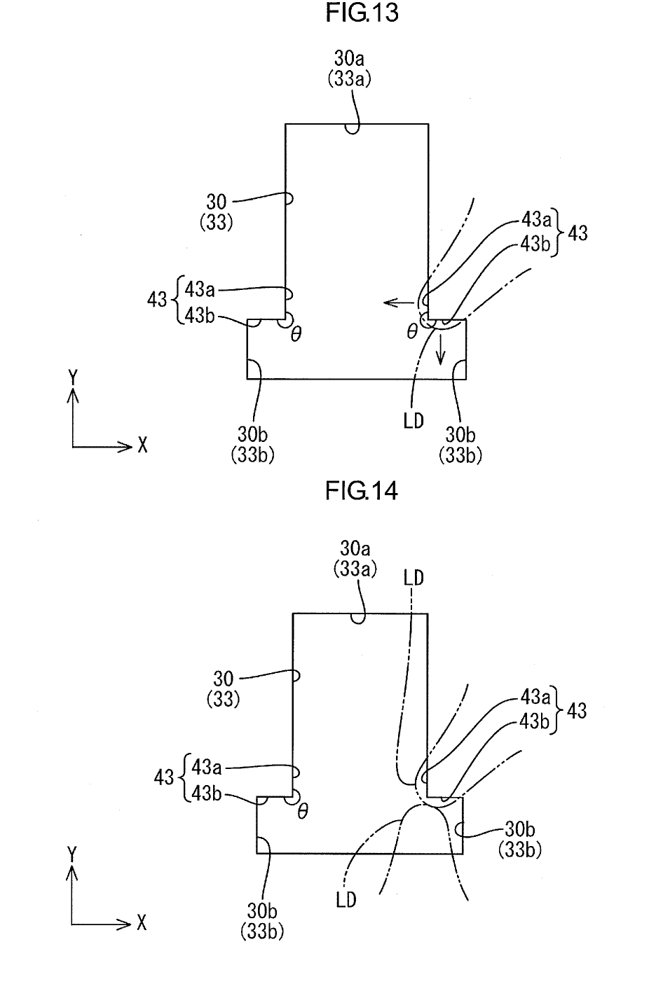

In addition, the contact holes 30 and 33 with the bending portions 43 have the expanded hole portions 30b and 33b formed by extending a portion of the contact hole main portions 30a and 33a. The bending portions 43 are formed by the communicating edges 43a and 43b at the contact hole main portions 30a and 33a and the expanded hole portions 30b and 33b, and the opening width of the expanded hole portions 30b and 33b is smaller than that of the contact hole main portions 30a and 33a, whereby the operation and effect as below can be obtained. Namely, when the droplets LD of the solution for forming the alignment film 11e have reached both the pair of opposite edges at the expanded hole portions 30b and 33b of the contact holes 30 and 33 as illustrated in FIG. 14 in the formation of the alignment film 11e, the droplets LD having reached the both edges are connected more easily than on the contact hole main portions 30a and 33a side. In this case, the connected droplets LD flow to make the surface area small due to the surface tension, enabling the droplets LD to flow into the contact holes 30 and 33 easily. Note that the droplet LD is illustrated by a two-dot chain line in FIG. 14. The second edge 43b of the expanded hole portions 30b and 33b connected to the first edge 43a of the contact hole main portions 30a and 33a forms the bending portion 43. Therefore, in combination with the easy flow of the droplet LD that forms the alignment film 11e into the contact holes 30 and 33 due to the bending portion 43, the droplet LD that forms the alignment film 11e can flow into the contact holes 30 and 33 more easily. According to the configuration, the alignment film 11e is more easily arranged in the portion overlapping the contact holes 30 and 33 in a plan view. Therefore, the defects are less likely to be developed in the alignment film 11e.

In consideration of the fact that the use of the transparent electrode material as the pixel electrode 18 reduces the fluidity of the droplet LD that forms the alignment film 11e on the pixel electrode 18, the expanded hole portion 30b of the lower contact hole 30 is disposed not overlapping the pixel electrode 18 in a plan view as illustrated in FIG. 8, so that the droplet LD easily flows into the expanded hole portion 30b. In combination with the easy flow of the solution for forming the alignment film 11e into the contact hole 30 because of the bending portion 43, the solution for forming the alignment film 11e can flow into the contact hole 30 more easily. Therefore, the defects are less likely to occur in the alignment film 11e and the moire is more effectively suppressed.

As illustrated in FIG. 8, the expanded hole portion 30b of the lower contact hole 30 is disposed not overlapping the drain electrode 17c formed from the second metal film 38, and the gate electrode 17a, the gate line 19, and the auxiliary capacitor line 25 formed from the first metal film 34 in a plan view. Therefore, as compared to the contact hole main portion 30a overlapping the drain electrode 17c, the gate electrode 17a, and the gate line 19 in a plan view, the opening depth, i.e., the gap from the surface of the pixel electrode 18 and the like to which the droplet LD that forms the alignment film 11e is supplied is larger by the total film thicknesses of the first metal film 34 and the second metal film 38. According to the configuration, the droplet LD for forming the alignment film 11e flow into the expanded hole portion 30b more easily. Therefore, the defects are less likely to be developed in the alignment film 11e and the moire is suppressed more effectively.

In this manner, the alignment film 11e is formed to the solid trace in the plate surface of the array board 11b in and out of the contact holes 30 and 33. The expanded hole portion 30b of the lower contact hole 30 is formed by extending the portion of the contact hole main portion 30a that is relatively far from the center of the pixel electrode 18 in a plan view, specifically the corner at the farthest position from the pixel electrode 18 as illustrated in FIG. 8. Therefore, even though the aligning function cannot be sufficiently exhibited because the portion of the alignment film 11e disposed inside the lower contact hole 30, particularly the expanded hole portion 30b forms the depressed shape relative to the surrounding, it is difficult for the defective alignment that may be caused by the expanded hole portion 30b to affect the display of the pixel electrode 18. As a result, the deterioration in display quality that may be caused by the expanded hole portion 30b is suppressed. The expanded hole portion 30b in the lower contact hole 30 is disposed not overlapping the pixel electrode 18 in a plan view. Therefore, even though the aligning function cannot be sufficiently exhibited because the portion of the alignment film 11e that is disposed inside the lower contact hole 30, particularly the expanded hole portion 30b forms the depressed shape relative to the surrounding, it is difficult for the defective alignment that may be caused by the expanded hole portion 30b to affect the display of the pixel electrode 18. As a result, the deterioration in display quality that may be caused by the expanded hole portion 30b is suppressed.

As described above, the array board (display component) 11b according to this embodiment includes: the second metal film 38 or the first metal film 34 as the first conductive film; the second transparent electrode film 24 or the second metal film 38 as the second conductive film, which is disposed above the second metal film 38 or the first metal film 34 as the first conductive film and which has at least a part thereof overlapping in a plan view the second metal film 38 or the first metal film 34 as the first conductive film; the first interlayer insulator 39 and the organic insulator 40 or the gate insulator 35 and the protection film 37, which correspond to the insulator disposed between the first conductive film (second metal film 38 or first metal film 34) and the second conductive film (second transparent electrode film 24 or second metal film 38) and has the lower contact hole 30 or the non-display area side contact hole 33 opened at the position overlapping the first conductive film (second metal film 38 or first metal film 34) and the second conductive film (second transparent electrode film 24 or second metal film 38) in a plan view for connecting the second conductive film (second transparent electrode film 24 or second metal film 38) to the first conductive film (second metal film 38 or first metal film 34); the alignment film 11e disposed above the second conductive film (second transparent electrode film 24 or second metal film 38) and having the portion overlapping the contact hole (lower contact hole 30 or non-display area side contact hole 33) in a plan view and the portion not overlapping the contact hole (lower contact hole 30 or non-display area side contact hole 33) in a plan view; and the bending portion 43 which is curved to form a reflex angle on the inside in a plan view and which is configured by at least a portion of the edges of the contact hole (lower contact hole 30 or non-display area side contact hole 33) in the insulator (first interlayer insulator 39 and organic insulator 40, or gate insulator 35 and protection film 37).

Thus, the second conductive film (second transparent electrode film 24 or second metal film 38) formed after the first conductive film (second metal film 38 or first metal film 34) and the insulator (first interlayer insulator 39 and organic insulator 40, or gate insulator 35 and protection film 37) is connected to the first conductive film (second metal film 38 or first metal film 34) on the lower side through the contact hole (lower contact hole 30 or non-display area side contact hole 33) in the insulator (first interlayer insulator 39 and organic insulator 40, or gate insulator 35 and protection film 37). In the formation of the alignment film 11e above the first conductive film (second metal film 38 or first metal film 34), when the solution for forming the alignment film 11e is locally supplied to the surface of the second conductive film (second transparent electrode film 24 or second metal film 38) and the like, the solution spreads to the outside of the contact hole (lower contact hole 30 or non-display area side contact hole 33) and to the inside of the contact hole (lower contact hole 30 or non-display area side contact hole 33). Thus, the alignment film 11e having the portion overlapping the contact hole (lower contact hole 30 or non-display area side contact hole 33) and the portion not overlapping the contact hole (lower contact hole 30 or non-display area side contact hole 33) is formed. Here, in the case where the solution for forming the alignment film 11e supplied to the outside of the contact hole (lower contact hole 30 or non-display area side contact hole 33) spreads to the inside of the contact hole (lower contact hole 30 or non-display area side contact hole 33), when the solution reaches the bending portion 43 curved to form the reflex angle on the inside in a plan view at the edges of the contact hole (lower contact hole 30 or non-display area side contact hole 33), the solution is moved to be drawn to the inside of the contact hole (lower contact hole 30 or non-display area side contact hole 33) by the bending portion 43. It is supposed that the solution is drawn because, for example, if the solution has reached the bending portion 43, the bending portion 43 forming the reflex angle on the inside in a plan view produces a force that causes the solution to spread in a wide angle. According to the configuration, the alignment film 11e is easily arranged inside the contact hole (lower contact hole 30 or non-display area side contact hole 33). Therefore, the defects are less likely to be developed in the alignment film 11e and the moire is properly reduced or suppressed.

The insulator (first interlayer insulator 39 and organic insulator 40, or gate insulator 35 and protection film 37) is formed such that the contact hole (lower contact hole 30 or non-display area side contact hole 33) includes the contact hole main portions 30a and 33a, which overlap at least a portion of the first conductive film (second metal film 38 or first metal film 34) and the second conductive film (second transparent electrode film 24 or second metal film 38) in a plan view and the expanded hole portions 30b and 33b formed by extending a portion of the contact hole main portions 30a and 33a. The bending portions 43 are formed by the communicating edges 43a and 43b at the contact hole main portions 30a and 33a and the expanded hole portions 30b and 33b. The expanded hole portions 30b and 33b have a smaller opening width than the contact hole main portions 30a and 33a. First, the opening width of the expanded hole portions 30b and 33b and the opening width of the contact hole main portions 30a and 33a are defined by the distance between the pair of edges opposite to each other. In the formation of the alignment film 11e, when the solution for forming the alignment film 11e has reached both the pair of edges opposite to each other at the expanded hole portions 30b and 33b in the contact hole main portions 30a and 33a, the solution having reached the edges is easily connected as compared to the contact hole main portions 30a and 33a side. When the solution is connected, the solution flows to have the smaller surface area due to the surface tension, thereby enabling the solution to flow into the contact hole (lower contact hole 30 or non-display area side contact hole 33) easily. Moreover, the bending portion 43 is formed by the second edge 43b of the expanded hole portions 30b and 33b communicating to the first edge 43a of the contact hole main portions 30a and 33a. Therefore, in combination with the easy flow of the solution for forming the alignment film 11e into the contact hole (lower contact hole 30 or non-display area side contact hole 33) due to the bending portion 43, the solution for forming the alignment film 11e can flow into the contact hole (lower contact hole 30 or non-display area side contact hole 33) more easily. According to the configuration, the alignment film 11e is more easily disposed in the portion overlapping the contact hole (lower contact hole 30 or non-display area side contact hole 33) in a plan view. Therefore, the defects are less likely to be developed in the alignment film 11e.

The second transparent electrode film 24 as the second conductive film forms the pixel electrode 18 made of the transparent electrode material. In the first interlayer insulator 39 and the organic insulator 40 as the insulator, the expanded hole portion 30b is formed by extending a portion of the contact hole main portion 30a that is relatively far from the center of the pixel electrode 18 in a plan view. The portion of the alignment film 11e that overlaps the contact hole main portion 30a in a plan view is formed to have a depressed shape relative to the non-overlapping portion. Therefore, the aligning function cannot be sufficiently exhibited in some cases, and this tendency is remarkable in the expanded hole portion 30b formed by extending the contact hole main portion 30a. In this regard, the expanded hole portion 30b is formed by extending a portion of the contact hole main portion 30a that is relatively far from the center of the pixel electrode 18 in a plan view; therefore, it is difficult for the defective alignment that may be caused by the expanded hole portion 30b to affect the display of the pixel electrode 18. As a result, the deterioration in display quality caused by the expanded hole portion 30b is suppressed.

In the first interlayer insulator 39 and the organic insulator 40 as the insulator, the expanded hole portion 30b is formed by extending a corner of the contact hole main portion 30a. Thus, the expanded hole portion 30b is formed as far from the pixel electrode 18 as possible in the contact hole main portion 30a; therefore, it is difficult for the defective alignment that may be caused by the expanded hole portion 30b to affect the display of the pixel electrode 18.

The second transparent electrode film 24 as the second conductive film forms the pixel electrode 18 made of the transparent electrode material. In the first interlayer insulator 39 and the organic insulator 40 as the insulator, the expanded hole portion 30b is disposed not overlapping the pixel electrode 18 in a plan view. The portion of the alignment film 11e that overlaps the lower contact hole 30 as the contact hole in a plan view is formed to have a depressed shape relative to the non-overlapped portion. Therefore, the aligning function cannot be sufficiently exhibited in some cases, and this tendency is remarkable in the expanded hole portion 30b formed by extending the contact hole main portion 30a. In this regard, the expanded hole portion 30b is formed not overlapping the pixel electrode 18 in a plan view; therefore, it is difficult for the defective alignment that may be caused by the expanded hole portion 30b to affect the display of the pixel electrode 18. As a result, the deterioration in display quality that may be caused by the expanded hole portion 30b is suppressed. When the transparent electrode material is employed as the material of the pixel electrode 18, the fluidity of the solution for forming the alignment film 11e on the pixel electrode 18 may become lower. However, the fluidity of the solution toward the expanded hole portion 30b can be maintained high by having the expanded hole portion 30b, which has the bending portion 43 for enabling the solution for forming the alignment film 11e to flow into the lower contact hole 30 easily, not overlap the pixel electrode 18 in a plan view. This enables the solution for forming the alignment film 11e to flow into the lower contact hole 30 more easily.

In the first interlayer insulator 39 and the organic insulator 40 as the insulator, the expanded hole portion 30b is disposed not overlapping the second metal film 38 as the first conductive film in a plan view. Thus, since the expanded hole portion 30b does not overlap the second metal film 38 as the first conductive film in a plan view, the opening depth, i.e., the gap from the surface of the second transparent electrode film 24 as the second conductive film to which the solution for forming the alignment film 11e is supplied can be set larger as compared to the contact hole main portion 30a. Therefore, the solution for forming the alignment film lie flows into the expanded hole portion 30b more easily.

The first metal film 34 as the third conductive film, which is disposed below the second metal film 38 as the first conductive film and at least a portion of which overlaps the second metal film 38 as the first conductive film is provided. In the first interlayer insulator 39 and the organic insulator 40 as the insulator, at least a portion of the contact hole main portion 30a overlaps the first metal film 34 as the third conductive film in a plan view and the expanded hole portion 30b is provided not overlapping the first metal film 34 as the third conductive film in a plan view. Thus, since the expanded hole portion 30b does not overlap the first metal film 34 as the third conductive film in a plan view, the opening depth, i.e., the gap from the surface of the second transparent electrode film 24 as the second conductive film to which the solution for forming the alignment film 11e is supplied can be set larger as compared to the contact hole main portion 30a. Therefore, the solution for forming the alignment film 11e flows into the expanded hole portion 30b more easily.

The second metal film 38 as the first conductive film forms at least the source electrode 17b and the drain electrode 17c. On the other hand, the first metal film 34 as the third conductive film forms at least the gate electrode 17a, which overlaps the source electrode 17b and the drain electrode 17c in a plan view, and the auxiliary capacitor line 25, which is disposed apart from the gate electrode 17a in a plan view. In the first interlayer insulator 39 and the organic insulator 40 as the insulator, at least a portion of the contact hole main portion 30a is disposed overlapping the drain electrode 17c and the gate electrode 17a in a plan view and the expanded hole portion 30b is held between the gate electrode 17a and the auxiliary capacitor line 25 in a plan view. Thus, the expanded hole portion 30b is held between the gate electrode 17a and the auxiliary capacitor line 25 in a plan view, so that the valley is formed on the surface of the second transparent electrode film 24 as the second conductive film and the like to which the solution for forming the alignment film 11e is supplied. Therefore, on the surface of the second transparent electrode film 24 as the second conductive film and the like, the solution for forming the alignment film 11e flows more easily into the expanded hole portion 30b from the portion overlapping the gate electrode 17a and the auxiliary capacitor line 25 in a plan view.

Moreover provided are the first metal film 34 as the third conductive film, which is disposed below the second metal film 38 as the first conductive film and at least a portion of which overlaps the second metal film 38 as the first conductive film in a plan view, and the semiconductor film 36 held between the first metal film 34 as the third conductive film and the second metal film 38 as the first conductive film. The second metal film 38 as the first conductive film forms at least the source electrode 17b and the drain electrode 17c. The first metal film 34 as the third conductive film forms at least the gate electrode 17a that overlaps the source electrode 17b and the drain electrode 17c in a plan view. The semiconductor film 36 is made of the oxide semiconductor and forms the channel 17d to be connected to the source electrode 17b and the drain electrode 17c. Upon the application of the voltage to the gate electrode 17a, current flows between the source electrode 17b and the drain electrode 17c through the channel 17d formed from the oxide semiconductor film. The oxide semiconductor film has higher electron mobility than the amorphous silicon thin film or the like, and therefore sufficient current can be supplied between the source electrode 17b and the drain electrode 17c even though the channel 17d has a smaller width. Because the width of the channel 17d is reduced, sizes of the source electrode 17b, the drain electrode 17c, and the gate electrode 17a can be reduced. The reduction in sizes of the electrodes 17a, 17b, and 17c is preferable for configuring the array board 11b to improve the definition. The array board 11b configured to improve the definition may have the higher number of the contact holes (the lower contact holes 30 and the non-display area side contact holes 33). Therefore, defects are more likely to be developed in the alignment film 11e. Each of the contact holes (the lower contact holes 30 and the non-display area side contact holes 33) in the insulators (the first interlayer insulator 39, the organic insulator 40, the gate insulator 35, and the protection film 37) includes the bending portion 43 that bends toward the inner side of the contact hole and has the reflex outer angle in a plan view at the edge of the contact hole. According to the configuration, the solution for forming the alignment film 11e more easily enters the contact holes (the lower contact holes 30 and the non-display area side contact holes 33). Therefore, the defects are less likely to be developed in the alignment film 11e.

The liquid crystal panel (display device) 11 according to this embodiment includes the aforementioned array board 11b, the CF board (opposite substrate) 11a disposed opposite to the array board 11b, and the liquid crystal layer (liquid crystal) 11c disposed between the array board 11b and the CF board 11a. In the liquid crystal panel 11, the defects are less likely to be developed in the alignment film 11e of the array board 11b and the moire is properly reduced or suppressed. As a result, the alignment of the liquid crystal layer 11c is properly performed and high display quality is achieved.

A method for manufacturing the array board 11b according to this embodiment includes a first film forming process and a second film forming process. The first film forming process is for forming the first conductive film (second metal film 38 or first metal film 34), the insulator (first interlayer insulator 39 and organic insulator 40 or gate insulator 35 and protection film 37), and the second conductive film (second transparent electrode film 24 or second metal film 38) in this sequence on the glass substrate (substrate) GS. Furthermore, the first film forming process is for forming the contact holes (lower contact holes 30 and non-display area side contact holes 33) in the insulators (the first interlayer insulator 39, the organic insulator 40, the gate insulator 35, and the protection film 37) at the positions overlapping the first conductive films (the second metal film 38 and the first metal film 34) and the second conductive films (the second transparent electrode film 24 an the second metal film 38) in a plan view. The contact holes are for connecting the second conductive films (the second transparent electrode film 24 and the second metal film 38) to the first conductive films (the second metal film 38 and the first metal film 34). Furthermore, the first film forming process is for forming the bending portions 43 at the portions of the edges of the respective contact holes (the lower contact holes 30 and the non-display area side contact holes 33) so as to bend toward the inner side of the respective contact holes and have the reflex outer angles. The second film-formation process is for forming the alignment film lie having the portions overlapping the contact holes (the lower contact holes 30 and the non-display area side contact holes 33) and the portions not overlapping the contact holes (the lower contact holes 30 and the non-display area side contact holes 33) in a plan view above the second conductive films (the second transparent electrode film 24 and the second metal film 38).

In the first film-formation process, the first conductive films (the second metal film 38 and the first metal film 34) and the insulators (the first interlayer insulator 39, the organic insulator 40, the gate insulator 35, and the protection film 37) are formed on the glass substrate GS, and then, the second conductive films (the second transparent electrode film 24 and the second metal film 38) are formed on the glass substrate GS. The second conductive films (the second transparent electrode film 24 and the second metal film 38) are connected to the first conductive films (the second metal film 38 and the first metal film 34) on the lower side via the contact holes (the lower contact holes 30 and the non-display area side contact holes 33) formed in the insulators (the first interlayer insulator 39, the organic insulator 40, the gate insulator 35, and the protection film 37). In the second film-formation process performed after the first film-formation process, the solution for forming the alignment film 11e is locally supplied to the surfaces of the second conductive films (the second transparent electrode film 24 and the second metal film 38) for forming the alignment film 11e above the first conductive films (the second metal film 38 and the first metal film 34). The solution spreads to the areas outside and inside the contact holes (the lower contact holes 30 and the non-display area side contact holes 33). As a result, the alignment film 11e is formed. The alignment film 11e includes the portions overlapping the contact holes (the lower contact holes 30 and the non-display area side contact holes 33) and the portions not overlapping the contact holes (the lower contact holes 30 and the non-display area side contact holes 33) in a plan view. When the solution for forming the alignment film 11e supplied to the areas outside of the contact holes (the lower contact holes 30 and the non-display area side contact holes 33) spreads to the areas inside the contact holes (the lower contact holes 30 and the non-display area side contact holes 33), the solution may reach the bending portions 43 each of which bends toward the inner side of the corresponding contact hole and has the reflex outer angle in a plan view the edges of the respective contact holes (the lower contact hole 30 and the non-display area side contact holes 33). When reaches any of the pending portions 43, the solution is drawn to the inner side of each contact hole (the lower contact hole 30 or the non-display area side contact hole 33) by the bending portion 43. that the reason why the solution is drawn as described above may be that a force to spread the solution in a wide angle is exerted on the solution by the bending portions 43 each of which bends toward the inner side of the corresponding contact hole and has the reflex outer angle. According to the configuration, the alignment film 11e is easily arranged inside the contact holes (the lower contact holes 30 and the non-display area side contact holes 33). Therefore, defects are less likely to be developed in the alignment film 11e and the moire is properly reduced or suppressed.

In the second film-formation process, the inkjet device 42 is used. The solution for forming the alignment film 11e is discharged from the nozzles 42d of the inkjet device 42 onto the second conductive films (the second transparent electrode film 24 and the second metal film 38). The solution discharged from the nozzles 42d of the inkjet device 42 and landed on the second conductive films (the second transparent electrode film 24 and the second metal film 38) in the second film-formation process spreads over the surfaces. The arrangement of the nozzles 42d of the inkjet device 42 and the arrangement of the contact holes (the lower contact holes 30 or the non-display area side contact holes 33) may overlap each other. If the solution for forming the alignment film 11e, which has been discharged from the plurality of nozzles 42d, does not sufficiently spread, the moire may occur. In this embodiment, the edges of the contact holes (the lower contact holes 30 and the non-display area side contact holes 33) include the bending portions 43, respectively. According to the configuration, the solution for forming the alignment film 11e is drawn into the contact holes (the lower contact holes 30 and the non-display area side contact holes 33) by the bending portions 43. Therefore, the alignment film 11e is easily formed in the contact holes (the lower contact holes 30 and the non-display area side contact holes 33) and the moire is properly reduced or suppressed.

### Second Embodiment

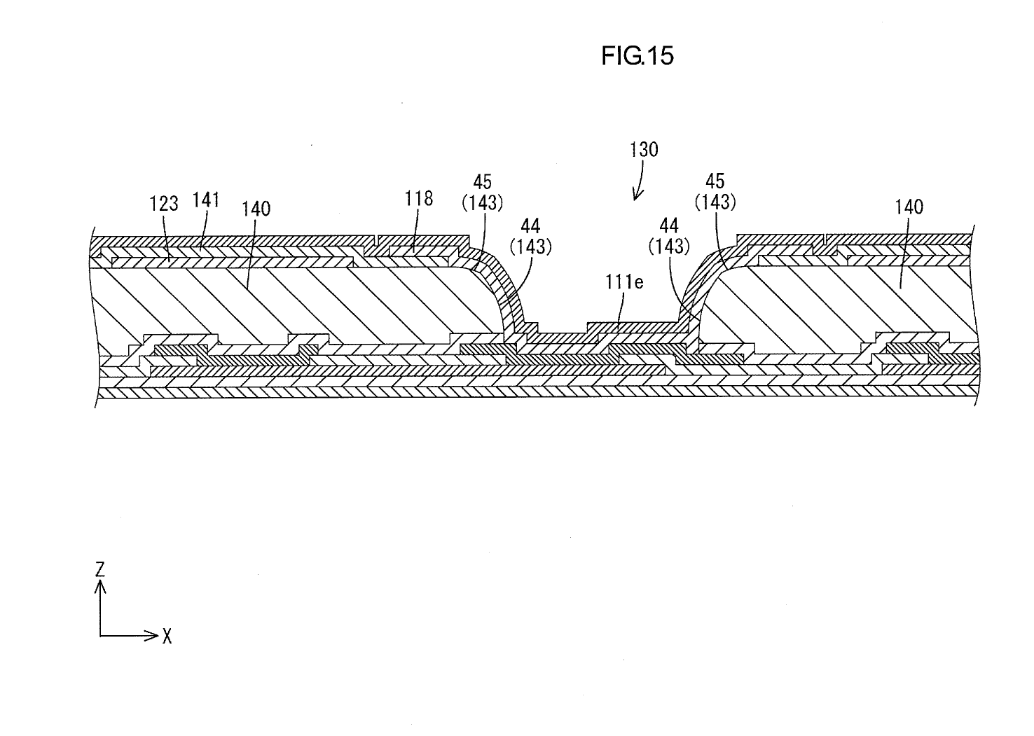

A second embodiment of the present invention will be described with reference to FIGS. 15 to 18. The second embodiment includes an organic insulator 140 that includes lower contact holes 130. Each of the contact holes 130 has an edge having a cross-sectional shape different from the first embodiment. Structures, functions, and effects similar to those of the first embodiment will not be described.

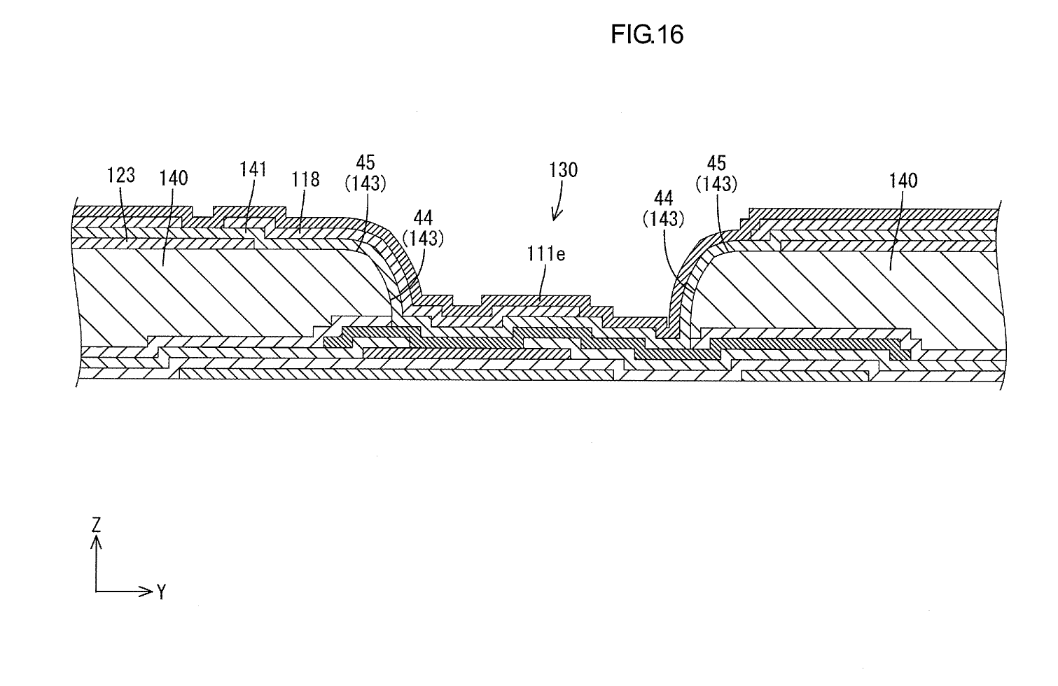

The edge of the lower contact hole 130 in the organic insulator 140 has the cross-sectional shape gradually rising as illustrated in FIGS. 15 and 16. Specifically, the edge of the lower contact hole 130 in the organic insulator 140 has a first inclined portion 44 which is disposed on the relatively lower side and whose inclination angle is relatively large to have a sharp slope, and a second inclined portion 45 which is disposed on the relatively upper side and whose inclination angle is relatively small to have a gentle slope. The first inclined portion 44 and second inclined portion 45 are formed along the entire circumference of the edge of the lower contact hole 130 in the organic insulator 140, and are also provided for a bending portion 143 included in the same edge.

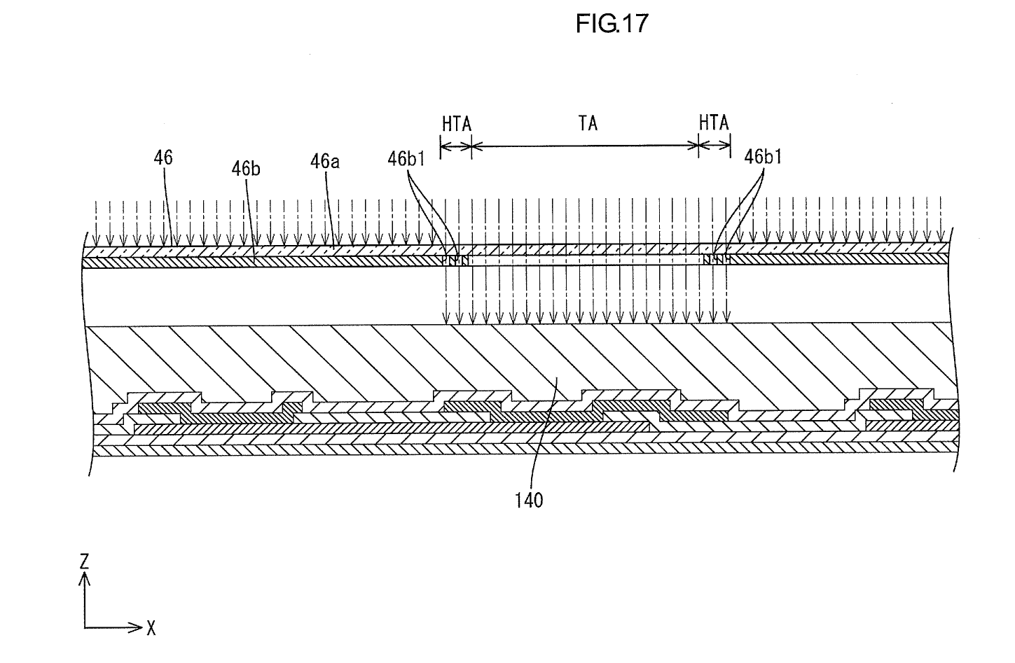

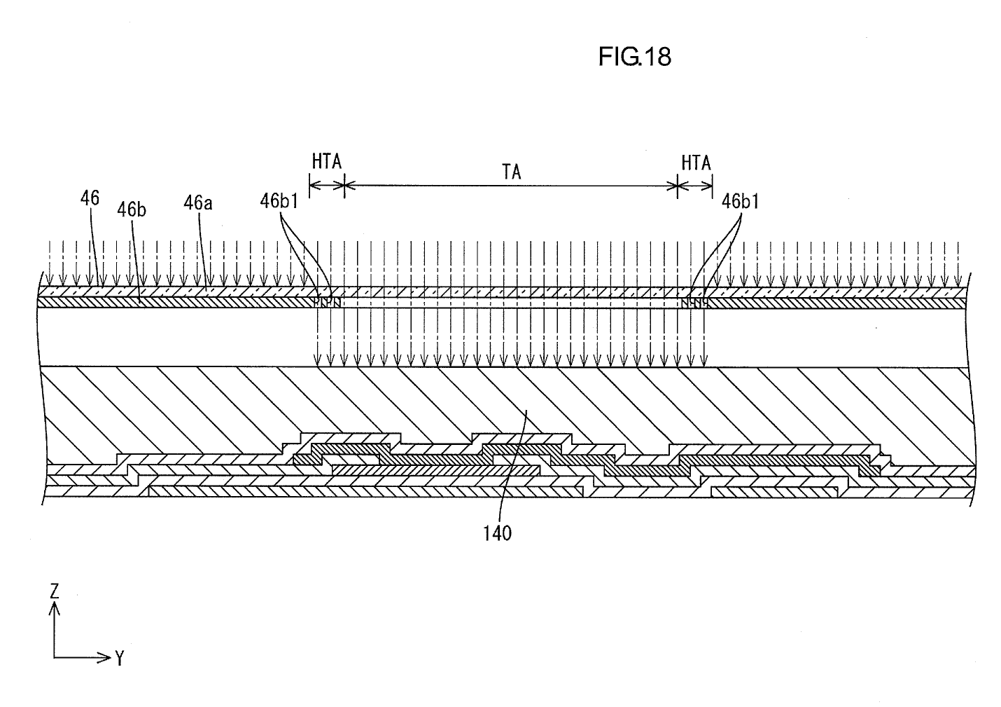

For forming the organic insulator 140 with such a sectional shape, a gray tone mask 46 is used as a photomask in patterning the organic insulator 140 in this embodiment. The gray tone mask 46 includes a transparent glass base member 46a and a light blocking film 46b that is formed on a plate surface of the glass base member 46a to block the exposing light from a light source as illustrated in FIGS. 17 and 18. The gray tone mask 46 includes a semitransmissive area HTA whose transmissivity of the exposing light is, for example, 10% to 70% by providing a portion of the light blocking film 46b with a slit 46b1 less than or equal to the resolution of the exposure device. A portion of the light blocking film 46b includes a hole equal to the resolution of the exposure device or larger. The gray tone mask 46 includes a transmissive area TA having about 100% of transmissivity for transmitting rays of the exposing light from the light source. When the organic insulator 140 is subjected to the exposing light from the light source through the gray tone mask 46 with such a structure, the lower contact hole 130 and the first inclined portion 44 are formed in the portion of the organic insulator 140 overlapping the transmissive area TA in a plan view. The first inclined portion 44 is formed at the edge of the lower contact hole 130. Furthermore, the second inclined portion 45 is formed in the portion thereof overlapping the semitransmissive area HTA in a plan view. The second inclined portion 45 is formed at the edge of the lower contact hole 130.

After the first inclined portion 44 and the second inclined portion 45 are formed at the edges of the lower contact hole 130 in the organic insulator 140, a common electrode 123, a second interlayer insulator 141, a pixel electrode 118, and an alignment film 111e are formed sequentially as illustrated in FIGS. 15 and 16. In the formation of the alignment film 111e, when the droplets of the solution for forming the alignment film 111e having reached out of the lower contact hole 130 spreads into the lower contact hole 130, first, the droplet passes the second inclined portion 45 with the gentle slope in the edge (including the bending portion 143) of the lower contact hole 130, thereby smoothly flowing into the lower contact hole 130. Thus, the droplets of the solution for forming the alignment film 111e whose fluidity has increased by the second inclined portion 45 flow into the lower contact hole 130 subsequently through the first inclined portion 44. Thus, the defects are less likely to be developed in the alignment film 111e.

As described above, in the array board according to this embodiment, the insulator includes at least the organic insulator 140 formed of the organic resin material, and at least the bending portion 143 of the edge of the lower contact hole 130 has a sectional shape gradually rising. The edge includes the first inclined portion 44 which is disposed on the relatively lower side and whose inclination angle is relatively large, and the second inclined portion 45 which is disposed on the relatively upper side and whose inclination angle is relatively small. If the bending portion is entirely formed of the first inclined portion, it is difficult for the solution for forming the alignment film 111e to move toward the first inclined portion side because the inclination is sharp. As compared to this case, when the second inclined portion 45 with the gentle slope is disposed above the first inclined portion 44, the solution for forming the alignment film 111e can be moved smoothly. Therefore, in the formation of the alignment film 111e, when the solution for forming the alignment film 111e has reached the bending portion 143 of the edge of the lower contact hole 130, the solution is induced to flow into the lower contact hole 130 by the second inclined portion 45 disposed relatively higher and having the smaller inclination angle. As a result, the solution enters the lower contact hole 130 smoothly through the first inclined portion 44. On the other hand, this is suitable when the lower contact hole 130 is small as compared to the case in which the bending portion is entirely formed of the second inclined portion because the edge of the lower contact hole 130 tends to have a larger width.

In the method for manufacturing the array board according to this embodiment, in the first film-formation process, at least the organic insulator 140 including a photosensitive organic resin material is formed as the insulator and the organic insulator 140 is exposed to light using the gray tone mask 46 including the semitransmissive area HTA by the slit 46b1 as the photomask. Thus, at least the bending portion 143 of the edge of the lower contact hole 130 is formed to have a sectional shape gradually rising and the edge includes at least the first inclined portion 44 which is disposed on the relatively lower side and whose inclination angle is relatively large, and the second inclined portion 45 which is disposed on the relatively upper side and whose inclination angle is relatively small. Thus, the organic insulator 140 formed of the photosensitive organic resin material in the first film-formation process is exposed to light using the gray tone mask 46 including the semitransmissive area HTA by the slit 46b1, so that the bending portion 143 is formed to have a sectional shape gradually rising and moreover to have at least the first inclined portion 44 which is disposed on the relatively lower side and whose inclination angle is relatively large and the second inclined portion 45 which is disposed on the relatively upper side and whose inclination angle is relatively small. If the bending portion is entirely formed of the first inclined portion, it is difficult for the solution for forming the alignment film 111e to move toward the first inclined portion side because the inclination is sharp. As compared to this case, when the second inclined portion 45 with the gentle slope is disposed above the first inclined portion 44, the solution for forming the alignment film 111e can be moved smoothly. Therefore, in the formation of the alignment film 111e, when the solution for forming the alignment film 111e has reached the bending portion 143 of the edge of the lower contact hole 130, the solution is induced to flow into the lower contact hole 130 by the second inclined portion 45 disposed relatively higher and having the smaller inclination angle, so that the solution enters the lower contact hole 30 smoothly through the first inclined portion 44. On the other hand, this is suitable when the lower contact hole 130 is small, as compared to the case in which the bending portion is entirely formed of the second inclined portion because the edge of the lower contact hole 130 tends to have a larger width.

### Third Embodiment

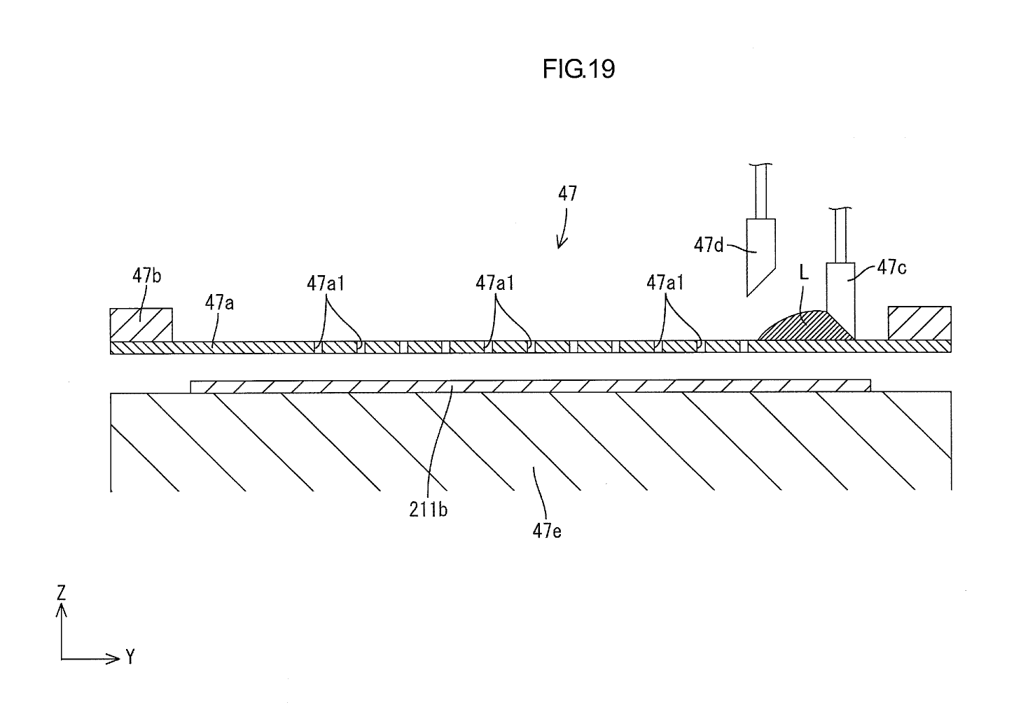

A third embodiment of the present invention will be described with reference to FIG. 19. In the third embodiment, a screen printing device 47 is used for forming the alignment film. Structures, functions, and effects similar to those of the first embodiment will not be described.

The screen printing device (stencil printing device) 47 according to this embodiment includes, as illustrated in FIG. 19, a mesh screen (stencil) 47a disposed opposite to, and with a space from the array board 211b, a frame 47b to be attached to an outer periphery of the screen 47a, a pair of squeegees 47c and 47d configured to horizontally reciprocate on the screen 47a along the surface thereof, and a stage 47e on which an array board 211b is mounted. On the screen 47a, a number of holes 47a1 are intermittently disposed in parallel to each other having a predetermined regularity along the surface thereof. In the screen 47a, the center is elastically deformed in the Z-axis direction by being pressed by each of the squeegees 47c and 47d as compared to the outer periphery supported by the frame 47b. A first squeegee 47c of the pair of squeegees 47c and 47d is moved to the left in FIG. 19 on the screen 47a to spread the supplied solution L that forms the alignment film, thereby filling the holes 47a1. A second squeegee 47d is moved to the right in FIG. 19 while pressing the screen 47a against the array board 211b, so that the solution L filled in the holes 47a1 can be transcribed to the array board 211b side. Even when the alignment film is formed on the array board 211b using the screen printing device 47, the operation and effect similar to those described in the first embodiment can be obtained.

In the second film-formation process in the method for manufacturing the array board 211b according to this embodiment, as described above, the screen printing device (stencil printing device) 47 is used. While the solution L that forms the alignment film is supplied onto the mesh screen (stencil) 47a of the screen printing device 47, the squeegees 47c and 47d are moved on the screen 47a, so that the solution L that forms the alignment film is printed onto the second conductive film (second transparent electrode film or second metal film) through the holes 47a1 of the screen 47a. Thus, the solution L that forms the alignment film, which has been supplied onto the mesh screen 47a in the screen printing device 47 in the second film-formation process, is printed onto the second conductive film (second transparent electrode film or second metal film) through the holes 47a1 of the screen 47a by the squeegees 47c and 47d moving on the screen 47a, and then spreads over the surface. Since the screen 47a of the screen printing device 47 has the holes 47a1 and has the mesh shape, the arrangement of the holes 47a may interfere with the arrangement of the contact holes (lower contact holes or non-display area side contact hole). In this case, if the solution L that forms the alignment film through the holes 47a1 does not spread sufficiently, the moire may be caused. In this regard, since the bending portion is included in the edge of the contact hole (lower contact hole or non-display area side contact hole), the solution L that forms the alignment film is drawn into the contact hole (lower contact hole or non-display area side contact hole) by the bending portion. Therefore, the alignment film is easily formed in the contact hole (lower contact hole or non-display area side contact hole) and this can suppress or prevent the occurrence of moire.

### Fourth Embodiment

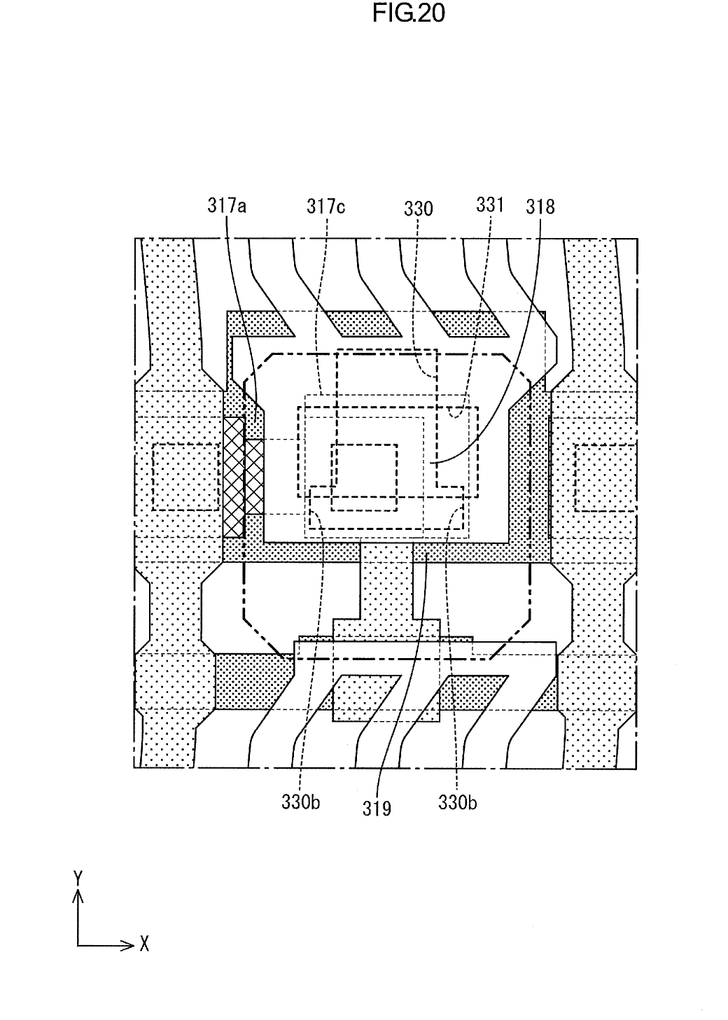

A fourth embodiment of the present invention will be described with reference to FIG. 20. In the fourth embodiment, lower contact holes 330 are arranged differently from the first embodiment in a plan view. Structures, functions, and effects similar to those of the first embodiment will not be described.

The lower contact hole 330 according to this embodiment is disposed such that expanded hole portions 330b entirely overlap a pixel electrode 318, a gate line 319 (gate electrode 317a), and a drain electrode 317c in a plan view as illustrated in FIG. 20. Moreover, the lower contact hole 330 is disposed such that a portion of the expanded hole portions 330b overlaps an upper contact hole 331.

### Fifth Embodiment

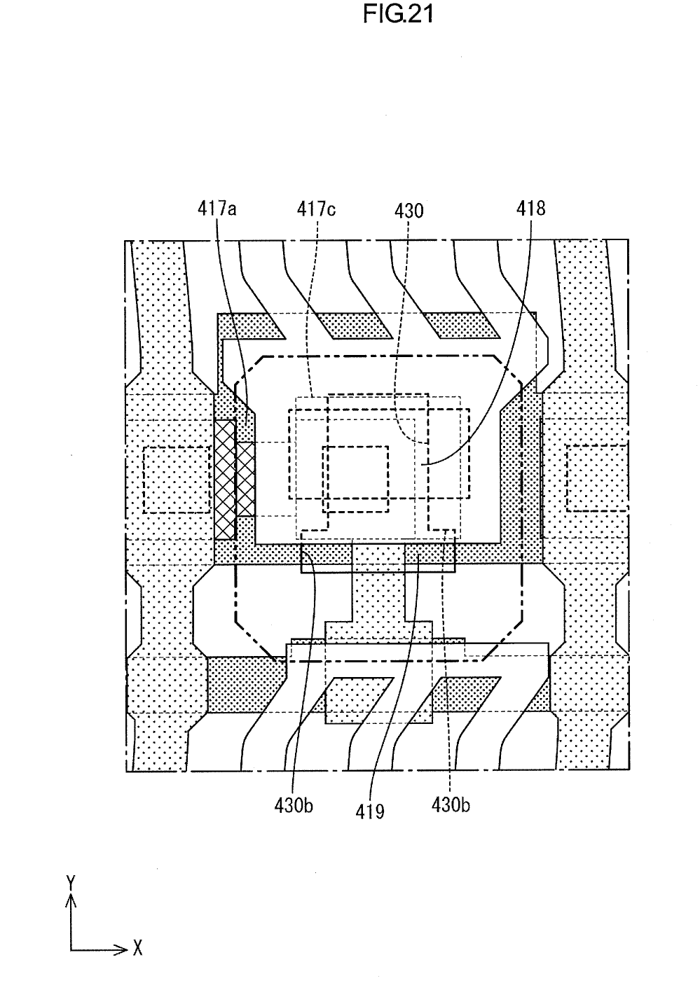

A fifth embodiment of the present invention will be described with reference to FIG. 21. In the fifth embodiment lower contact holes 430 are arranged differently from the first embodiment in a plan view. Structures, functions, and effects similar to those of the first embodiment will not be described.

The lower contact hole 430 according to this embodiment is disposed such that a portion of expanded hole portions 430b overlaps a pixel electrode 418, agate line 419 (gate electrode 417a), and a drain electrode 417c in a plan view as illustrated in FIG. 21. The area of the expanded hole portion 430b overlapping the pixel electrode 418, the gate line 419, and the drain electrode 417c are different: the area of the expanded hole portion 430b overlapping the gate line 419 in the maximum and the area of the expanded hole portion 430b overlapping the drain electrode 417c is the minimum.

### Sixth Embodiment

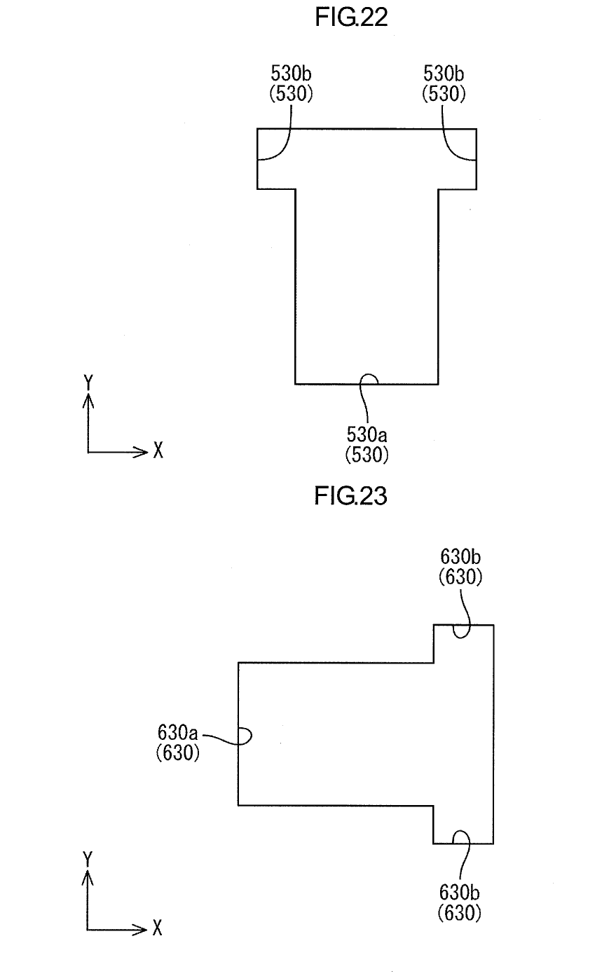

A sixth embodiment of the present invention will be described with reference to FIG. 22. In the sixth embodiment, each of lower contact holes 530 has a shape different from the first embodiment in a plan view. Structures, functions, and effects similar to those of the first embodiment described will not be described.

The lower contact hole 530 according to this embodiment is configured in a manner that a pair of expanded hole portions 530b is formed by extending upper corners of a contact hole main portion 530a as illustrated in FIG. 22. In other words, of the lower contact hole 530, the expanded hole portions 530b are formed by extending the corners of the contact hole main portion 530a closer to the center of the pixel electrode, which is not illustrated.

### Seventh Embodiment

A seventh embodiment of the present invention will be described with reference to FIG. 23. In the seventh embodiment, each of lower contact holes 630 has a shape different from the first embodiment in a plan view. Structure, functions, and effects similar to those of the first embodiment will not be described.

The lower contact hole 630 according to this embodiment is disposed in the posture with the length direction and the width direction thereof coinciding with the X-axis direction and the Y-axis direction, respectively as illustrated in FIG. 23. A pair of expanded hole portions 630b is formed by extending right corners of a contact hole main portion 630a as illustrated in FIG. 23. In other words, the lower contact hole 630 has the structure obtained by rotating the upper contact hole described in the first embodiment by 90° rightward in a plan view.

### Eighth Embodiment

An eighth embodiment of the present invention will be described with reference to FIG. 24. In the eighth embodiment, each of lower contact holes 730 has a shape different form the first embodiment in a plan view. Structures, functions, and effects similar to those of the first embodiment will not be described.

Of the lower contact hole 730 according to this embodiment, a pair of expanded hole portions 730b is formed by extending a center portion (non-corner portion) of a contact hole main portion 730a in the length direction of the contact hole main portion 730a as illustrated in FIG. 24. In this configuration, first edges 743a along the length direction out of the edges of the contact hole main portion 730a are disconnected by the pair of expanded hole portions 730b. Therefore, the pair of first edges 743a communicates with a pair of second edges 743b along the width direction out of the edges of the expanded hole portions 730b. A bending portion 743 is formed by the communicating first edges 743a and second edges 743b. In other words, in this embodiment, the two bending portions 743 are formed by one expanded hole portion 730b. This enables the droplet of the solution for forming the alignment film to be drawn into the lower contact hole 730 more easily in the formation of the alignment film.

### Ninth Embodiment

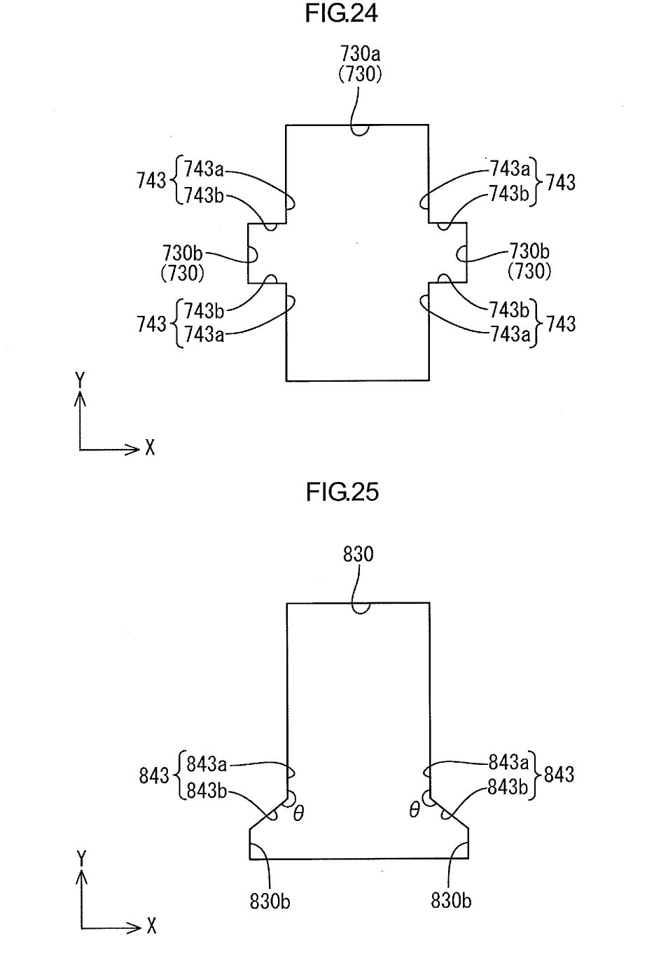

A ninth embodiment of the present invention will be described with reference to FIG. 25. In the ninth embodiment, each of lower contact holes 830 has a shape different from the first embodiment in a plan view. Structures, functions, and effects similar to those of the first embodiment will not be described.

Of edges of a pair of expanded hole portions 830b of the lower contact hole 830 according to this embodiment, second edges 843b of bending portions 843 are formed to be inclined in a plan view as illustrated in FIG. 25. The second edge 843b is formed inclined in a plan view such that the angle 8 on the inside relative to a first edge 843a is a reflex angle ranging from 180° to 270°. In other words, the second edge 843b is inclined in a plan view such that the angle on the outside relative to the first edge 843a is in the range of 90° to 180°, i.e., an obtuse angle.

### Tenth Embodiment

A tenth embodiment of the present invention will be described with reference to FIG. 26. In the tenth embodiment, each of lower contact holes 930 has a shape different from the first embodiment in a plan view. Structures, functions, and effects similar to those of the first embodiment will not be described.

Of edges of a pair of expanded hole portions 930b of the lower contact hole 930 according to this embodiment, second edges 943b of bending portions 943 are formed to be inclined in a plan view as illustrated in FIG. 26. The second edge 943b is formed inclined in a plan view such that the angle 8 on the inside relative to a first edge 943a is a reflex angle ranging from 270° to 360°. In other words, the second edge 943b is inclined in a plan view such that the angle on the outside relative to the first edge 943a is in the range of 0° to 90°, i.e., an acute angle.

### Eleventh Embodiment

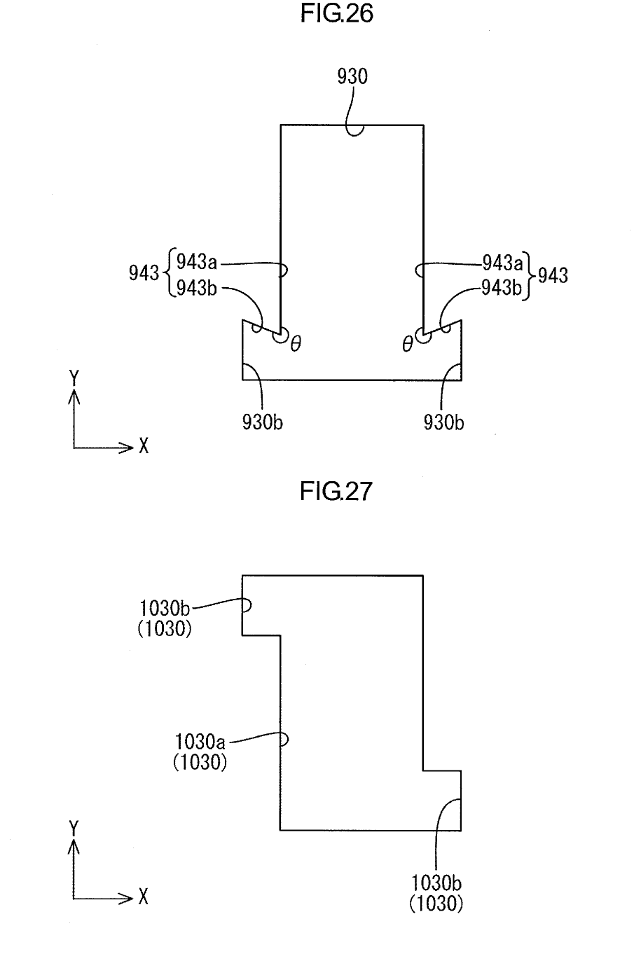

An eleventh embodiment of the present invention will be described with reference to FIG. 27. In the eleventh embodiment, each of lower contact holes 1030 has a shape different from the first embodiment in a plan view. Structures, functions, and effects similar to those of the first embodiment will not be described.

In the lower contact hole 1030 according to this embodiment, a pair of expanded hole portions 1030b is formed by extending diagonal corners of a contact hole main portion 1030a as illustrated in FIG. 27.

### Twelfth Embodiment

A twelfth embodiment of the present invention will be described with reference to FIG. 28. In the twelfth embodiment, each of lower contact holes 1130 has a shape different from the first embodiment in a plan view. Structures, functions, and effects similar to those of the first embodiment will not be described.

In the lower contact hole 1130 according to this embodiment, four expanded hole portions 1130b are formed by extending four corners of a contact hole main portion 1130a as illustrated in FIG. 28. Four bending portions 1143 are formed over the contact hole main portion 1130a and the expanded hole portions 1130b. In other words, the lower contact hole 1130 has a shape obtained by narrowing the center portion excluding the opposite ends in the length direction (portion where the expanded hole portions 1130b are formed), and the four bending portions 1143 are formed at the edges over the opposite ends and the center portion.

### Thirteenth Embodiment

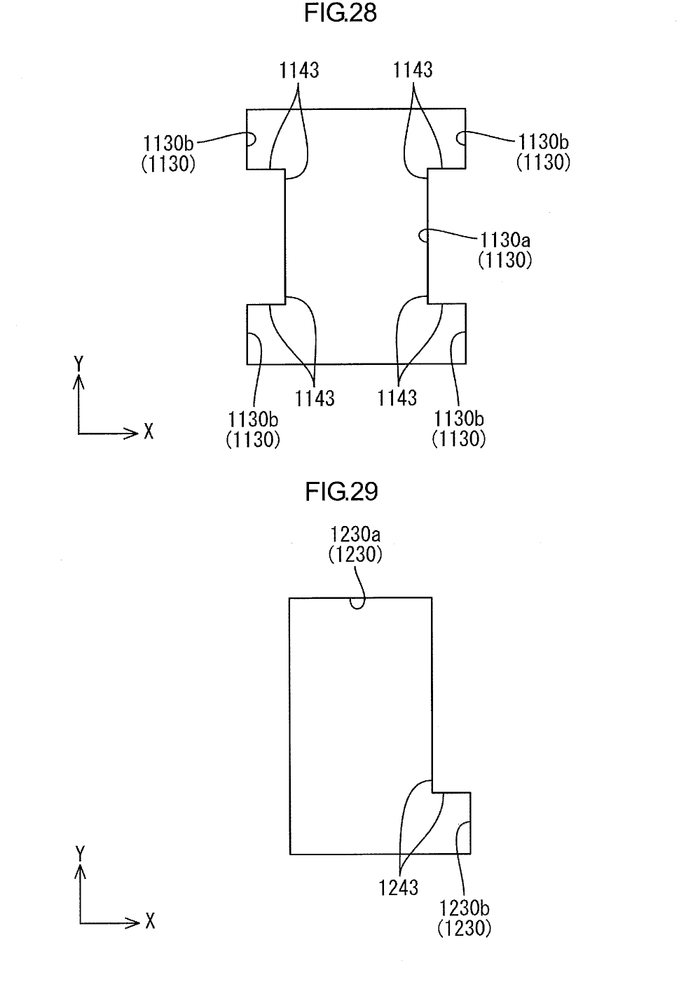

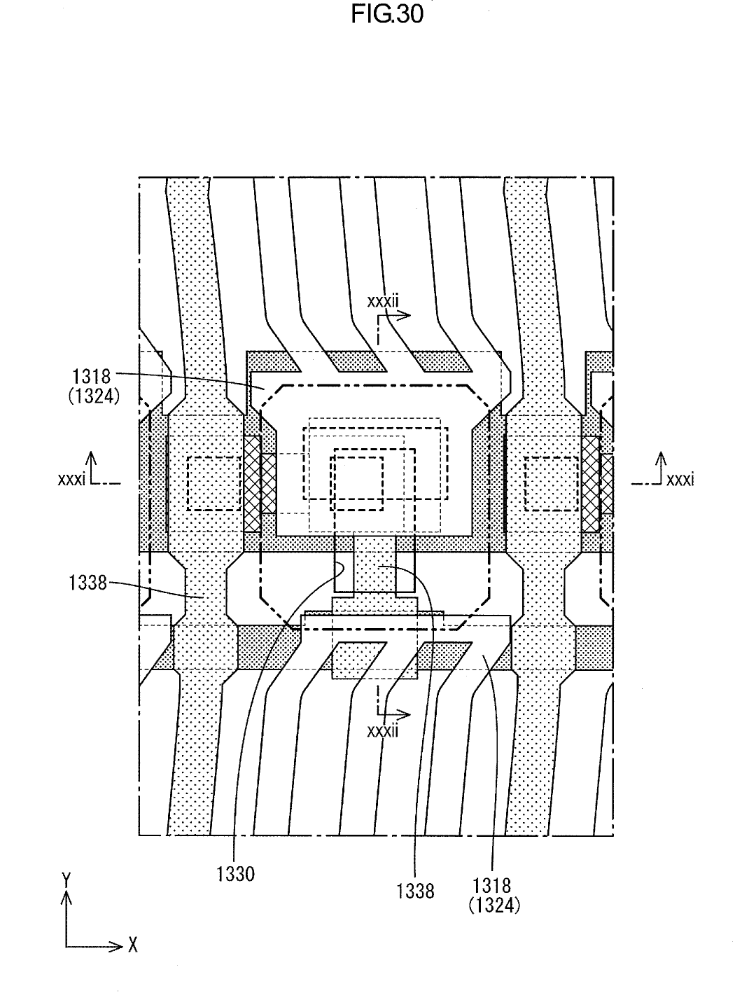

A thirteenth embodiment of the present invention will be described with reference to FIG. 29. In the thirteenth embodiment, each of lower contact holes 1230 has a shape different from the first embodiment in a plan view. Structures, functions, and effects similar to those of the first embodiment will not be described.

In the lower contact hole 1230 according to this embodiment, one expanded hole portion 1230b is formed by extending one corner of a contact hole main portion 1230a as illustrated in FIG. 29. Just one bending portion 1243 is formed over the contact hole main portion 1230a and the expanded hole portion 1230b.

### Fourteenth Embodiment

A fourteenth embodiment of the present invention will be described with reference to FIGS. 30 to 34. In the fourteenth embodiment, each of lower contact holes 1330 has a shape different from the first embodiment in a plan view and an edge has a shape different from the first embodiment in a cross-sectional view. Structures, functions, and effects similar to those of the first embodiment will not be described.

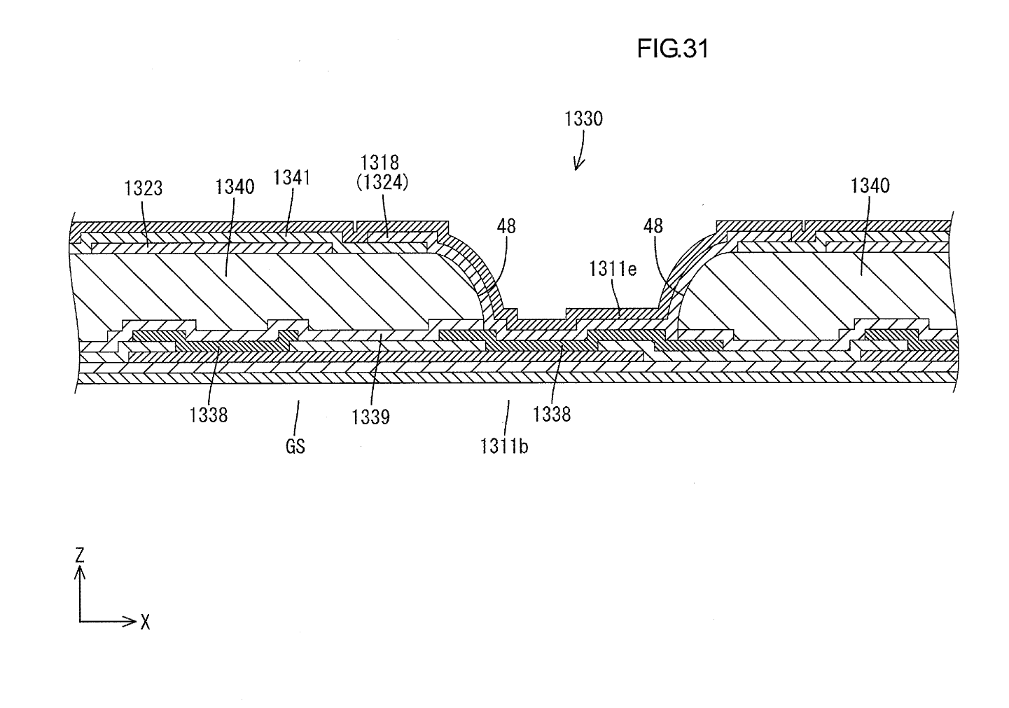

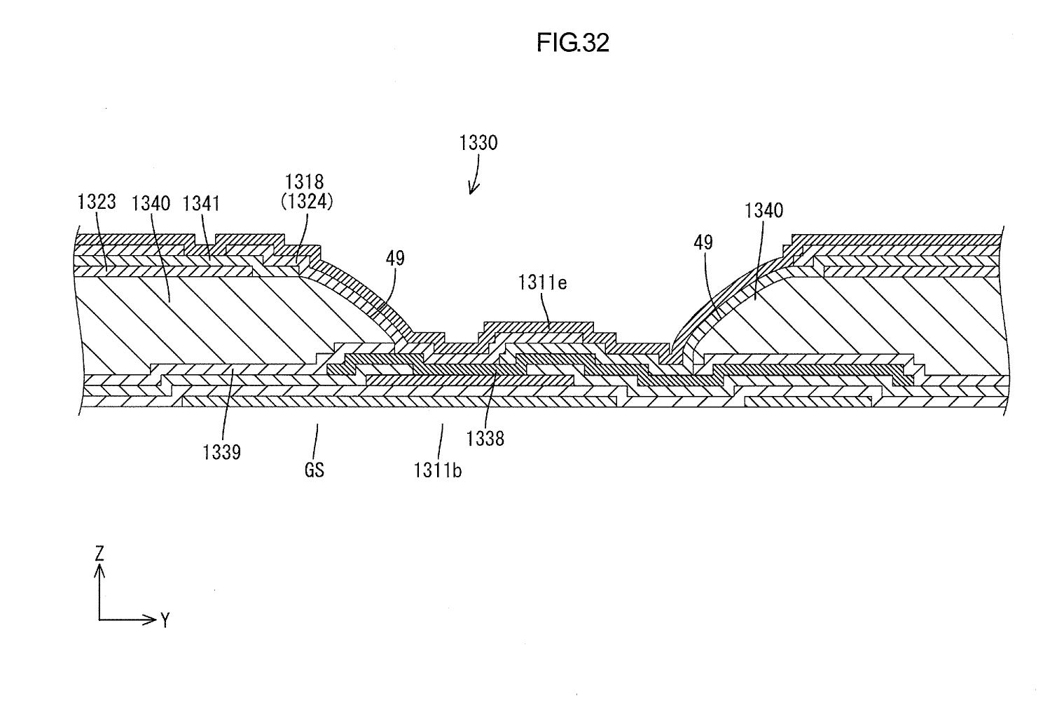

In an organic insulator 1340 according to this embodiment, the edge of the lower contact hole 1330 has a vertically-long rectangular shape in a plan view as illustrated in FIG. 30. In other words, the edges of the lower contact hole 1330 do not have the bending portions described in the first to thirteenth embodiments. In other words, it can be said that the lower contact hole 1330 includes only the contact hole main portion and is formed by omitting the expanded hole portion from the lower contact hole described in the first to thirteenth embodiments. As illustrated in FIGS. 31 and 32, the edges of the lower contact hole 1330 include a first inclined portion 48 whose sectional shape is inclined and whose inclination angle is relatively large, and a second inclined portion 49 whose sectional shape is inclined and whose inclination angle is relatively small.

As illustrated in FIGS. 30 and 31, the first inclined portion 48 is provided for each of a pair of edges opposite each other among four edges (opening periphery) of the lower contact hole 1330 with a rectangular shape in a plan view in the organic insulator 1340, specifically, a pair of right and left edges extending along the Y-axis direction and illustrated in FIG. 30. The first inclined portion 48 has its sectional shape with an approximately bow-like shape (approximately arc-like shape) and has its tangential line inclined relatively sharply to both the X-axis direction and the Z-axis direction. On the other hand, as illustrated in FIGS. 30 and 32, the second inclined portion 49 is provided for each of edges constituting a pair of sides opposite to each other and adjacent to each of the first inclined portions 48 among four edges of the lower contact hole 1330 with a rectangular shape in a plan view in the organic insulator 1340, specifically, a pair of upper and lower edges extending along the X-axis direction and illustrated in FIG. 30. The second inclined portion 49 has its sectional shape with an approximately bow-like shape (approximately arc-like shape) and has its tangential line inclined relatively gently to both the Y-axis direction and the Z-axis direction.

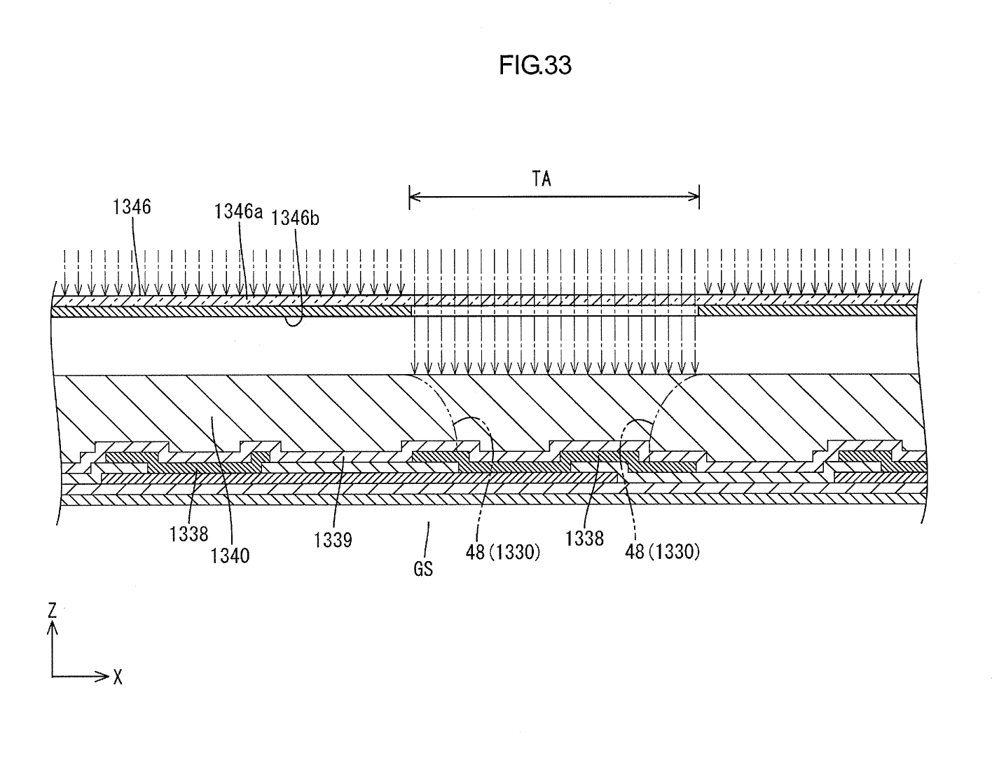

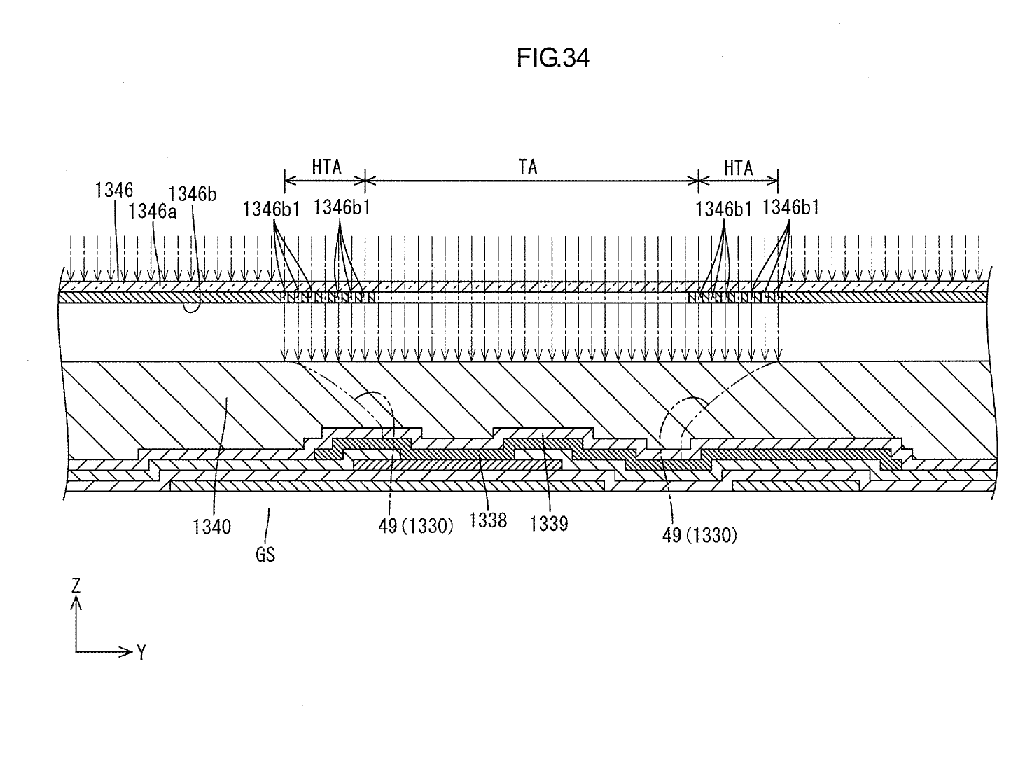

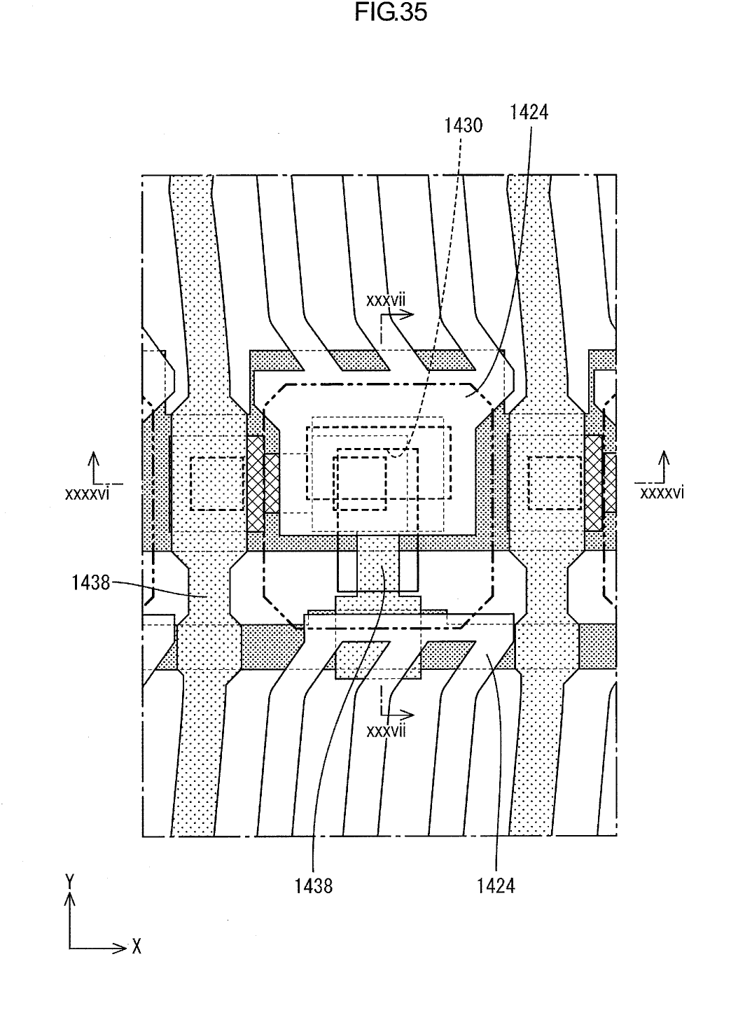

For forming the organic insulator 1340 with such a sectional shape, in this embodiment, a gray tone mask 1346 is used as a photomask in patterning the organic insulator 1340 in this embodiment. This gray tone mask 1346 has a fundamental structure similar to that described in the second embodiment. As illustrated in FIGS. 33 and 34, the gray tone mask 1346 is formed of a transparent glass base member 1346a and a light blocking film 1346b formed on a plate surface of the glass base member 1346a to block exposing light from a light source. The gray tone mask 46 includes a transmissive area TA by providing a portion of the light blocking film 1346b with an opening more than or equal to the resolution of the exposure device, and a semitransmissive area HTA by providing a portion of the light blocking film 1346b with a slit 1346b1 less than or equal to the resolution of the exposure device. In the gray tone mask 1346 according to this embodiment, the transmissive area TA is formed in a portion overlapping the opening of the lower contact hole 1330 and the first inclined portion 48 in a plan view and the semitransmissive area HTA (slit 1346b1) is formed in a portion overlapping the second inclined portion 49 in a plan view. Upon the irradiation of the organic insulator 140 with the exposing light from the light source through the gray tone mask 1346 having the above configuration, the lower contact hole 1330 and the first inclined portion 48 at the edge and having the larger inclination angle are formed in the portion of the organic insulator 1340 overlapping the transmissive area TA in a plan view and the second inclined portion 49 forming the edge of the lower contact hole 1330 and having the smaller inclination angle is formed in the portion thereof overlapping the semitransmissive area HTA in a plan view. The procedure of manufacturing an array board 1311b according to this embodiment is similar to that of the first and second embodiments.

After the first inclined portion 48 and the second inclined portion 49, which are adjacent to each other in a plan view, are formed at the edge of the lower contact hole 1330 in the organic insulator 1340, a common electrode 1323, a second interlayer insulator 1341, a pixel electrode 1318, and an alignment film 1311e are formed sequentially as illustrated in FIGS. 31 and 32. In the formation of the alignment film 1311e, when the droplet of the solution for forming the alignment film 1311e having reached out of the lower contact hole 130 spreads into the lower contact hole 1330, the droplet flows easily into the second inclined portion 49 with the slope less sharp than the first inclined portion 48, whereby the flow (introduction) of the droplets into the lower contact hole 1330 is promoted. In addition, at the boundary between the first inclined portion 48 and the second inclined portion 49 with the different inclination angle in the edge of the lower contact hole 1330, i.e., at the corner, the inclination angle is different, so that the fluidity of the droplet of the solution for forming the alignment film 1311e is increased. As a result, the droplets can flow into the lower contact hole 1330 more easily. Therefore, defects are less likely to be developed in the alignment film 1311e and the moire is reduced or suppressed. The function and the effect achieved by the configuration of this embodiment (the first inclined portions 48 and the second inclined portions 48) are substantially the same as those of the first embodiment achieved by the configuration of the first embodiment (the bending portions). Furthermore, the problem (moire due to the defects in the alignment film) can be solved by any of the first and the second embodiments.

As described above, the array board 1311b according to this embodiment includes: a second metal film 1338 as a first conductive film; a second transparent electrode film 1324 as a second conductive film disposed above the second metal film 1338 as the first conductive film and having at least a part thereof overlapping the second metal film 1338 as the first conductive film in a plan view; a first interlayer insulator 1339 and the organic insulator 1340, which are interposed between the second metal film 1338 as the first conductive film and the second transparent electrode film 1324 as the second conductive film and have the lower contact hole 1330 opened at the position overlapping the second metal film 1338 as the first conductive film and the second transparent electrode film 1324 as the second conductive film in a plan view for connecting the second metal film 1338 as the first conductive film to the second transparent electrode film 1324 as the second conductive film; the alignment film 1311e disposed above the second transparent electrode film 1324 as the second conductive film and having a portion overlapping the lower contact hole 1330 in a plan view and a portion not overlapping the lower contact hole 1330 in a plan view; and the two inclined portions 48 and 49 formed at the edge of the lower contact hole 1330 in the first interlayer insulator 1339 as the insulator and having the sectional shape inclined with the different inclination angles.

Thus, the second transparent electrode film 1324 as the second conductive film formed after the formation of the second metal film 1338 as the first conductive film and the first interlayer insulator 1339 and the organic insulator 1340 as the insulator is connected to the first conductive film on the lower side through the lower contact hole 1330 of the first interlayer insulator 1339 and the organic insulator 1340 as the insulator. In the film-formation of the alignment film 1311e above the second metal film 1338 as the first conductive film, when the solution for forming the alignment film 1311e is locally supplied to the surface of the second transparent electrode film 1324 as the second conductive film, the solution spreads to the outside of the lower contact hole 1330 and to the inside of the lower contact hole 1330. Thus, the alignment film 1311e having the portion overlapping the lower contact hole 1330 in a plan view and the portion not overlapping the lower contact hole 1330 in a plan view is formed. In the case where the solution for forming the alignment film 1311e supplied on the outside of the lower contact hole 1330 spreads to the inside the lower contact hole 1330, when the solution has reached the edge of the lower contact hole 1330, the solution is induced to flow into the lower contact hole 1330 by the second inclined portion 49 with the less sharp slope and with the smaller inclination angle out of the two inclined portions 48 and 49 whose sectional shapes are inclined at the edge and whose inclination angles are different from each other. In addition, at the boundary between the inclined portions 48 and 49 with the different inclination angle in the edge of the lower contact hole 1330, the fluidity of the solution for forming the alignment film 1311e is increased because the inclination angle is different. As a result, the solution can flow into the lower contact hole 1330 more easily. According to the configuration, the alignment film 1311e is easily arranged in the lower contact hole 1330. Therefore, the defects are less likely to be developed in the alignment film 1311e and the moire is properly reduced or suppressed.

A method for manufacturing the array board 1311b according to this embodiment includes a first film-formation process and a second film-formation process. In the first film-formation process, the second metal film 1338 as the first conductive film, the first interlayer insulator 1339 and the organic insulator 1340 as the insulator, and the second transparent electrode film 1324 as the second conductive film are formed in this order on the glass substrate GS, the lower contact hole 1330 is opened at the position of the first interlayer insulator 1339 and the organic insulator 1340 as the insulator overlapping the second metal film 1338 as the first conductive film and the second transparent electrode film 1324 as the second conductive film in a plan view for connecting the second transparent electrode film 1324 as the second conductive film to the second metal film 1338 as the first conductive film, and the two inclined portions 48 and 49 whose sectional shapes are inclined and whose inclination angles are different are formed at the edge of the lower contact hole 1330. In the second film-formation process, the alignment film 1311e having the portion overlapping the lower contact hole 1330 and the portion not overlapping the lower contact hole 1330 in a plan view is formed above the second transparent electrode film 1324 as the second conductive film.

Thus, when the second transparent electrode film 1324 as the second conductive film is formed after the formation of the second metal film 1338 as the first conductive film and the first interlayer insulator 1339 and the organic insulator 1340 as the insulator on the glass substrate GS in the first film-formation process, the second transparent electrode film 1324 as the second conductive film is connected to the second metal film 1338 as the first conductive film on the lower side through the lower contact hole 1330 formed in the first interlayer insulator 1339 and the organic insulator 1340 as the insulator. In the subsequent second film-formation process, when the solution for forming the alignment film 1311e is locally supplied to the surface of the second transparent electrode film 1324 as the second conductive film or the like for forming the alignment film 1311e above the second metal film 1338 as the first conductive film, the solution spreads to the outside of the lower contact hole 1330 and to the inside of the lower contact hole 1330. Thus, the alignment film 1311e is formed which has the portion overlapping the lower contact hole 1330 and the portion not overlapping the lower contact hole 1330 in a plan view. Here, in the case where the solution for forming the alignment film 1311e supplied on the outside of the lower contact hole 1330 spreads to the inside the lower contact hole 1330, when the solution has reached the edge of the lower contact hole 1330, the solution is induced to flow into the lower contact hole 1330 by the second inclined portion 49 with the less sharp slope and with the smaller inclination angle out of the two inclined portions 48 and 49 whose sectional shapes are inclined at the edge and whose inclination angles are different from each other. In addition, at the boundary between the inclined portions 48 and 49 with the different inclination angle in the edge of the lower contact hole 1330, the fluidity of the solution for forming the alignment film 1311e is increased because the inclination angle is different. As a result, the solution can flow into the lower contact hole 1330 more easily. According to the configuration, the alignment film 1311e is easily arranged in the lower contact hole 1330. Therefore, defects are less likely to be developed in the alignment film 1311e and the moire is properly reduced or suppressed.

In the first film-formation process of the method for manufacturing the array board 1311b, at least the organic insulator 1340 including a photosensitive organic resin material is formed as the insulator and the organic insulator 1340 is exposed to light using the gray tone mask 1346 including the semitransmissive area HTA by the slit 1346b1 as the photomask. Thus, with the light transmitted through the semitransmissive area MIA of the gray tone mask 1346, at least the second inclined portion 49 with the relatively smaller inclination angle among the two inclined portions 48 and 49 is formed at the edge of the lower contact hole 1330. Thus, the organic insulator 1340 formed of the photosensitive organic resin material in the first film-formation process is exposed to light using the gray tone mask 1346 including the semitransmissive area HTA by the slit 1346b1, so that the lower contact hole 1330 is formed. At the edge of the lower contact hole 1330, at least the second inclined portion 49 with the relatively smaller inclination angle among the two inclined portions 48 and 49 is formed due to the light transmitted through the semitransmissive area HTA of the gray tone mask 1346.

### Fifteenth Embodiment

A fifteenth embodiment of the present invention will be described with reference to FIGS. 35 to 38. In the fifteenth embodiment, each of second inclined portions 1449 has an angle different from the fourteenth embodiment. Furthermore, results of comparative experiments will be described. Structures, functions, and effects similar to those of the first embodiment will not be described.

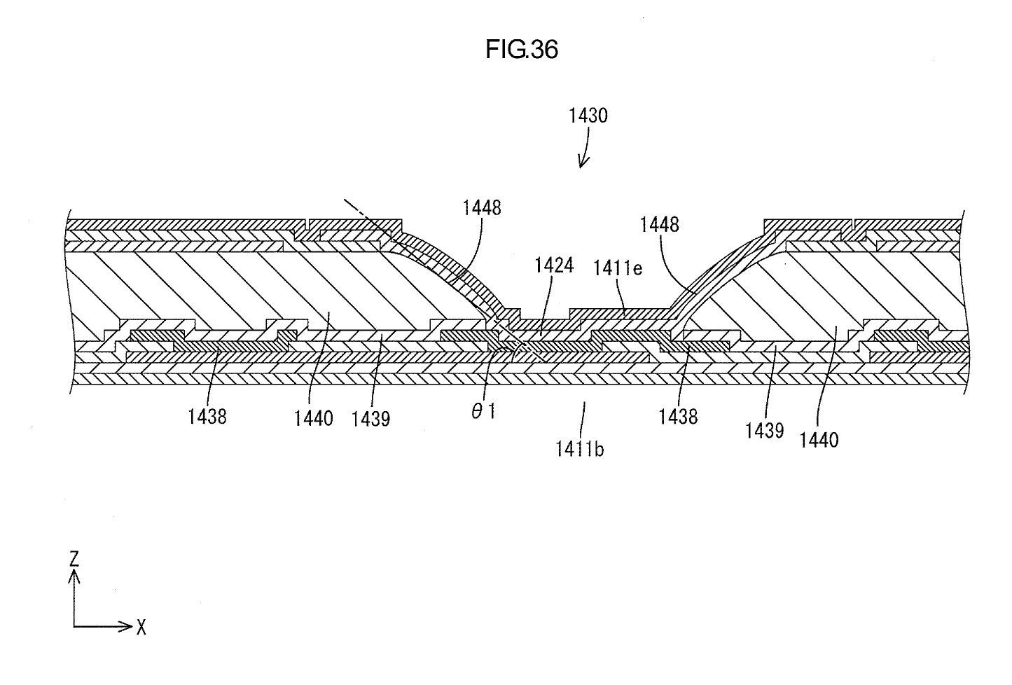

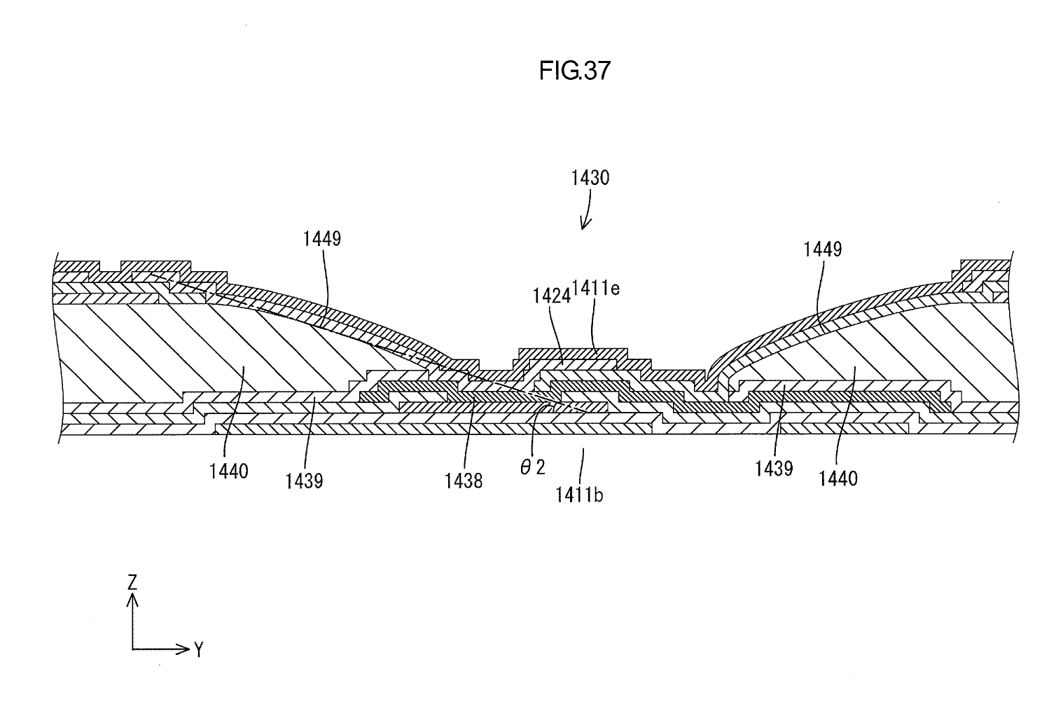

As illustrated in FIGS. 35 to 37, each lower contact hole 1430 according to this embodiment includes first inclined portions 1448 and second inclined portions 1449 at edges. A cross-sectional shape of each of the first inclined portions 1448 and the second inclined portions 1449 has a curved shape (an arched shape). The first inclined portions 1448 are located at short edges of the lower contact hole 1430 opposed to each other. The second inclined portions 1449 are located at long edges of the lower contact hole 1430 opposed to each other. A slope of each of the first inclined portions 1448 is steeper. An inclination angle θ1 is about 40°. A slope of each of the second inclined portions 1449 is gentler. An inclination angle θ2 is about 21°. A difference between the inclination angle θ1 of the first inclined portion 1448 and the inclination angle θ2 of the second inclined portion 1449 is in a range from 10° to 50°, preferably, 19°. Each of the inclination angles of the first inclined portions 1448 and the second inclined portion 1449 is an angle between the X axis or the Y axis an a tangent line at a midpoint of the first inclined portion 1448 or the second inclined portion 1449 (a point at which distances from ends of the slope are equal). Tangent lines are indicated by chain lines in FIGS. 36 and 37.

As illustrated in FIG. 35, each lower contact hole 1430 has a vertically-long rectangular shape in a plan view. A short dimension of the lower contact hole 1430 is about 5 μm and a long dimension thereof is about 10 μm. Therefore, an area of the lower contact hole 1430 is 50 μm². The area of the lower contact hole 1430 may be defined in a range from 10 μm² to 150 μm². Each of the second inclined portions 1449 at the short edge of each lower contact hole 1430 extends about the entire short edge of the lower contact hole 1430 and thus a dimension of the second inclined portion 1449 along the short edge of the lower contact hole 1430 is about 5 μm, that is, smaller than 8 μm.

### Comparative Experiments

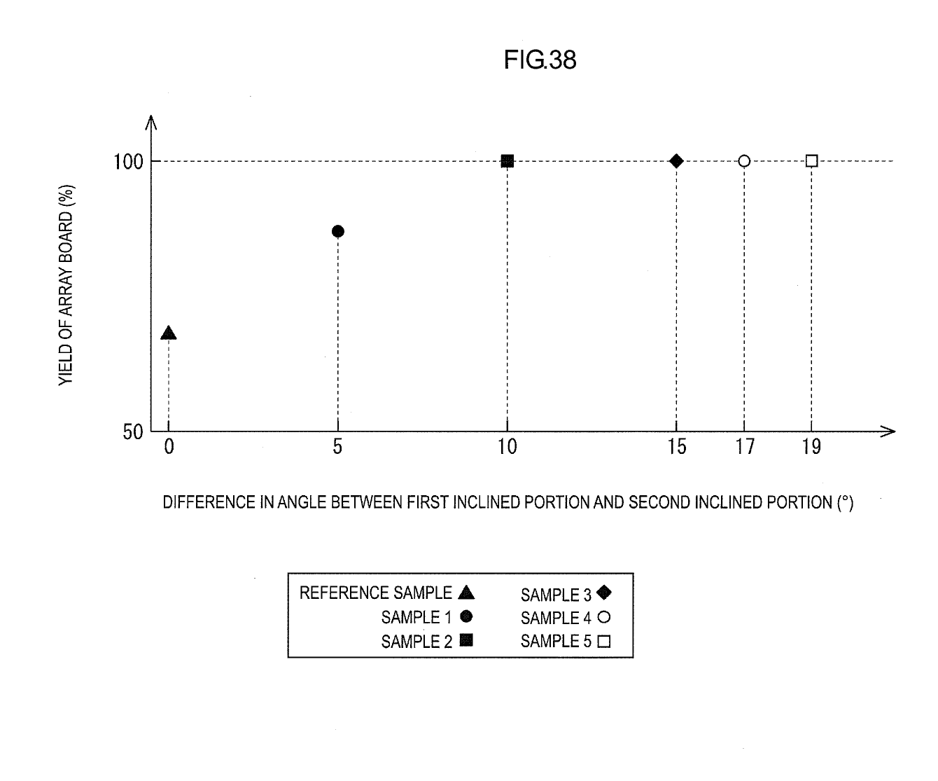

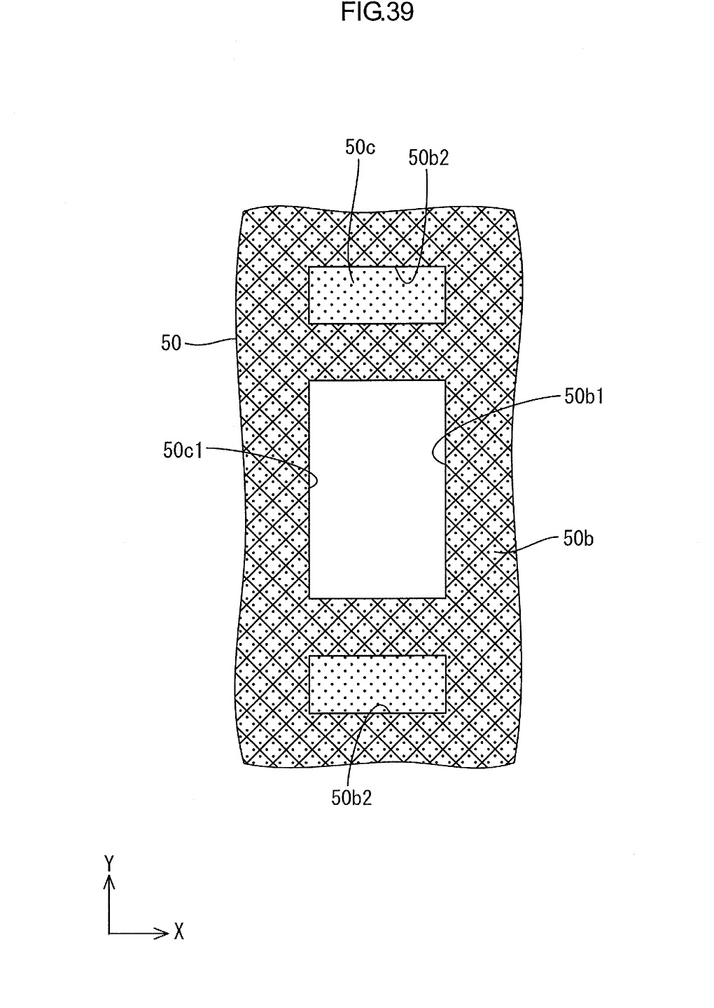

Next, results of comparative experiments will be described with reference to FIG. 38. In the comparative experiments, the inclination angle θ2 of each second inclined portion 1449 was altered to different values while the inclination angle θ1 of the corresponding first inclined portion 1448 was maintained constant. Namely, a difference between the inclination angle θ1 of the first inclined portion 1448 and the inclination angle θ2 of the second inclined portion 1449 was altered. Then, changes in the number of array boards 1411b that do not have defects in alignment films 1411e (or yield rate) were observed. In the comparative example, a sample including inclined portions with inclination angles, a difference between which was zero was defined as a reference sample. A sample including the inclination angle θ1 of the first inclined portion 1448 and the inclination angle θ2 of the second inclined portion 1449, a difference between which was 5° was defined as sample 1. A sample including the inclination angle θ1 of the first inclined portion 1448 and the inclination angle θ2 of the second inclined portion 1449, a difference between which was 10° was defined as sample 2. A sample including the inclination angle θ1 of the first inclined portion 1448 and the inclination angle θ2 of the second inclined portion 1449, a difference between which was 15° was defined as sample 3. A sample including the inclination angle θ1 of the first inclined portion 1448 and the inclination angle θ2 of the second inclined portion 1449, a difference between which was 17° was defined as sample 4. A sample including the inclination angle θ1 of the first inclined portion 1448 and the inclination angle θ2 of the second inclined portion 1449, a difference between which was 19° was defined as sample 5. The predefined number of the array boards according to the reference sample and samples 1 to 5 were prepared. Inspections were performed using an electronic microscope for determining whether detective were developed in the alignment films 1411e in the lower contact holes 1430. A percentage of the array boards 1411b that were defined that no defects were observed (defined as products without defects) in the inspections among all samples was defined as a yield. In FIG. 38, the vertical axis represents the yield of the array boards 1411b, that is, the percentage of the array boards 1411b that do not include defects in the alignment films 1411e in the lower contact holes 1430 (in percent [%]). The horizontal axis represents a difference between the inclination angle θ1 of the first inclined portion 1448 and the inclination angle θ2 of the second inclined portion 1449 (in degree [°]). In FIG. 38, a black triangle, a black circle, a black square, a black diamond, a white circle, and a white square represent results regarding the reference sample, sample 1, sample 2, sample 3, sample 4, and sample 5, respectively.

The results of the comparative experiments will be described. According to the chart in FIG. 38, the yield of the array boards in the reference sample is 68%, the yield of the array boards in sample 1 is 87%, and the yields of the array boards in samples 2 to 5 are about 100%. Although the yields of the array boards in samples 2 to 5 are about 100%, the yields of sample 2, sample 3, sample 4, and sample 5 slightly increase in this sequence. The yields of samples 4 and 5 among samples 2 to 5 are very high and very closer to 100%. The configurations regarding samples 4 and 5 are preferable for producing the array boards 1411b, each of which includes the lower contact holes 1430 arranged separately and the large number of pixels. The results show tendency of the yield to improve as the difference between the inclination angle θ1 of the first inclined portion 1448 and the inclination angle θ2 of the second inclined portion 1449 increases. This may be because the droplets of the solution for forming the alignment films 1411e are more likely to enter the lower contact holes 1430 during the formation of the alignment films 1411e as the difference between the inclination angle θ1 and the inclination angle θ2 increases and thus defects are less likely to be developed in the alignment films 1411e.

As described earlier, at least two inclined portions 1448 and 1449 are formed in the array board 1411b such that the difference between the inclination angles θ1 and θ2 is in the range from 10° to 50°. If the difference between the inclination angles of the inclined portions is smaller than 10°, the difference is so small that the flowability of the solution for forming the alignment film at a boundary between the inclined portions having different inclination angles is not sufficient. Namely, a sufficient level of promotion of flow of the solution is not achieved. If the difference between the inclination angles of the inclined portions is larger than 50°, the slope of the inclined portion having the smaller inclination angle is so gentle that a creepage distance thereof tends to become large. Therefore, an area of a portion that is not used for display increases and display performance may decrease. As described above, the difference between the inclination angle θ1 of the first inclined portion 1448 and the inclination angle θ2 of the second inclined portion 1449 is within the range from 10° to 50°. Therefore, the flow of the solution for forming the alignment film 1411e is sufficiently promoted. Furthermore, the creepage distance of the second inclined portion 1449 having the smaller inclination angle is sufficiently small. Therefore, the array board 1411b can exert the sufficient level of the display performance.

A first interlayer insulator 1439 and an organic insulator 1440 include the lower contact holes 1430. Each of the lower contact holes 1430 has the long edges and the short edges in a plan view. The second inclined portion 1449 having the smaller inclination angle among the inclined portions 1448 and 1449 is located at the short edge of the lower contact hole 1430. In comparison to a configuration in which the inclined portion having the smaller inclination angle is formed at the long edge of the lower contact hole 1430, the solution for forming the alignment film 1411e, the flow of which into the lower contact hole 1430 is promoted by the second inclined portion 1449 having the smaller inclination angle, is more likely to reach the boundary between the inclined portions 1448 and 1449 of the edges of the lower contact hole 1430 having different inclination angles. Because the inclination angles θ1 and θ2 at the boundary are different, the flowability of the solution for forming the alignment film 1411e increases and thus the solution is more likely to flow into the lower contact hole 1430.

Each second inclined portion 1449 having the smaller inclination angle is formed such that the dimension along the short edge of the contact hole is equal to 8 μm or smaller. In comparison to a configuration in which the dimension is equal to 8 μm or larger, the solution for forming the alignment film 1411e, the flow of which into the lower contact hole 1430 is promoted by the second inclined portion 1449 having the smaller inclination angle is more likely to reach the boundary between the inclined portions 1448 and 1449 at the edges of the lower contact hole 1430 having the different inclination angles θ1 and θ2, respectively. Therefore, the flow of the solution into the lower contact hole 1430 is further promoted and thus the defects are further less likely to be developed in the alignment film 1411e.

Each of the lower contact holes 1430 in the first interlayer insulator 1439 and the organic insulator 1440 has an opening area in a range from 10 μm² to 150 μm². If the opening area of the lower contact hole is smaller than 10 μm², a connecting area between the second metal film and the second transparent electrode film is so small that reliability of the connection may decrease and it may be difficult to form the lower contact hole. If the opening area of the lower contact hole is larger than 150 μm², the solution that has reached the edge of the lower contact hole is less likely to merge with the solution that has reached from a different way. Therefore, the solution is less likely to flow into the lower contact hole. According to the configuration in which the opening area of the lower contact hole 1430 is within the range from 10 μm² to 150 μm², the connecting area between the second metal film 1438 and the second transparent electrode film 1424 has a sufficient size and thus the reliability of the connection is ensured. Furthermore, the lower contact hole 1430 is easily formed and the solution for forming the alignment film 1411e is more likely to flow into the lower contact hole 1430.

### Sixteenth Embodiment

A sixteenth embodiment of the present invention will be described with reference to FIGS. 39 to 41. In the sixteenth embodiment, a photomask for exposing an organic insulator 1540 different from that used in the fourteenth embodiment is used. Structures, functions, and effects similar to those of the fourteenth embodiment will not be described.

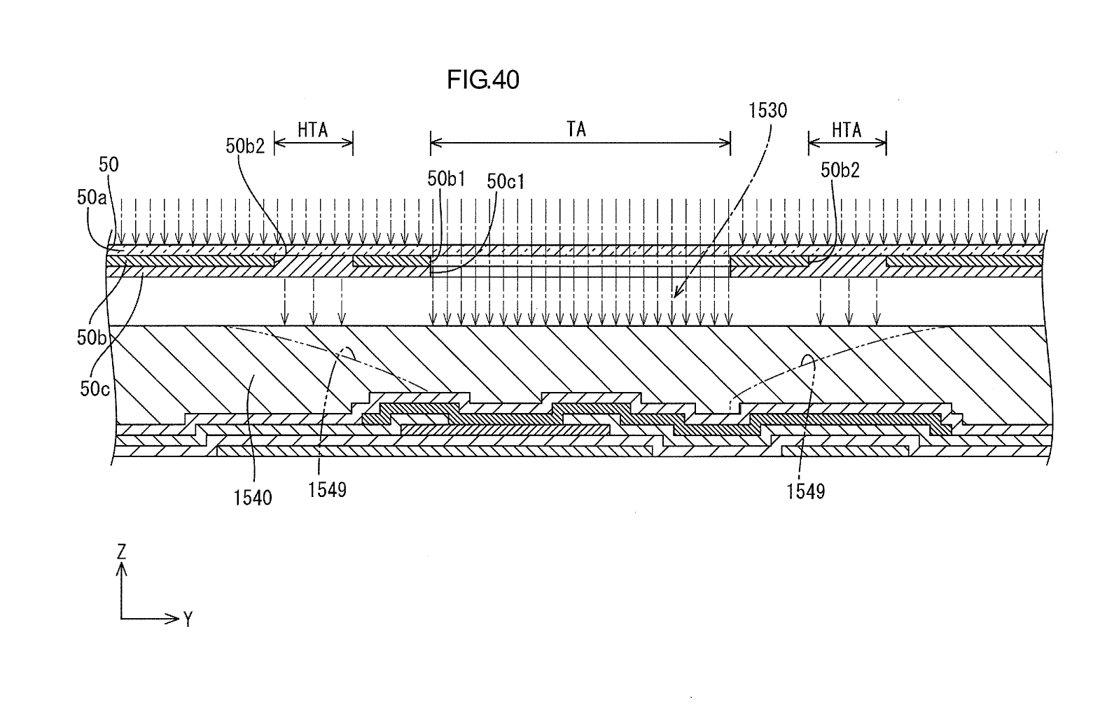

The organic insulator 1540 according to this embodiment is made of photosensitive organic resin material having positive photosensitivity. For patterning of the organic insulator 1540, a halftone mask 50 having the following configuration is used as a photomask. As illustrated in FIGS. 39 and 40, the halftone mask 50 includes a transparent glass substrate 50a, a light blocking film 50b, and a semitransmissive film. The light blocking film 50b is formed on a plate surface of the glass substrate 50a to block exposing light from a light source. The semitransmissive film 50c is configured to pass the exposing light from the light source with a predefined transmissivity. In FIG. 39, an area of the halftone mask 50 in which the light blocking film 50b is formed is indicated by a lattice pattern and an area thereof in which the semitransmissive film 50c is formed is indicated by a dot pattern. In FIG. 39, in an area in which the lattice pattern and the dot pattern overlap each other, the light blocking film 50b and the semitransmissive film 50c overlap each other. The transmissivity of the light blocking film 50b to pass the exposing light is about 0%. The semitransmissive film 50c is layered on the other side of the light blocking film 50b relative to the glass substrate 50a. The transmissivity of the semitransmissive film 50c to pass the exposing light is in a range from 10% to 70%.

As illustrated in FIGS. 39 and 40, the light blocking film 50b and the semitransmissive film 50c include holes 50b1, 50b2, and 50c1 within areas corresponding to the plate surface of the glass substrate 50a. Positions at which the holes 50b1, 50b2, and 50c1 are formed and areas in which 50b1, 50b2, and 50c1 are formed are different between the light blocking film 50b and the semitransmissive film 50c. The light blocking film 50b includes first holes 50b1 and second holes 50b2. Each of the first holes 50b1 has a vertically-long rectangular shape and does not overlap the semitransmissive film 50c in a plan view (i.e., overlaps the corresponding hole 50c1 in the semitransmissive film 50c). Each of the second holes 50b2 has a horizontally-long rectangular shape. The second hole 50b2 is arranged between the first holes 50b1 with predefined distances from the first holes 50b1 so as to overlap the semitransmissive film 50c in a plan view (i.e., does not overlap the hole 50c1 in the semitransmissive film 50c). The semitransmissive film 50c includes the holes 50c1 each having a horizontally-long rectangular shape in a plan view. Each of the holes 50c1 is arranged between the first holes 50b1 in the light blocking film 50b with predefined distances from the first holes 50b1 so as to overlap the corresponding second hole b2 in a plan view. Areas of the halftone mask 50 in which the first holes 50b1 in the light blocking film 50b overlap the respective holes 50c1 in the semitransmissive film 50c in a plan view are defined as transmissive areas TA in which about 100% of rays of the exposing light from the light source pass. Areas of the halftone mask 50 in which the second holes 50b2 in the light blocking film 50b overlap the semitransmissive film 50c in a plan view are defined as semitransmissive areas HTA in which rays of the exposing light from the light source pass with the transmissivity about equal to the transmissivity of the semitransmissive film 50c. Furthermore, in areas of the halftone mask 50 in which the light blocking portion 50b is formed, the transmissivity to pass rays of the exposing light is about 0% regardless of existence of the semitransmissive film 50c.

Within the plate surface of the halftone mask 50, the second holes 50b2 (the semitransmissive areas HTA) in the light blocking film 50b are arranged separated from the first hole 50b1 (the transmissive area TA) in the Y-axis direction as illustrated in FIGS. 39 and 40. Each of the second holes 50b2 has a X-axis dimension, or a length, about equal to that of the first hole 50b1. Each of the second holes 502b (the semitransmissive area HTA) in the light blocking film 50b has a Y-axis dimension, or a width, in a range from 0.5 μm to 5 μm, for example, it as the width of 2 μm. According to the configuration, underexposure of the organic insulator 1540 which may occurs when the width of each second hole is 0.5 μm or smaller is less likely to occur. Furthermore, holes different from the lower contact holes 1530 which may be formed when the width of each second hole is 5 μm or larger are less likely to be formed. Namely, according to the configuration, second inclined portions 1549 are properly formed at edges of the lower contact holes 1530. A distance between each second hole 50b2 (the semitransmissive area HTA) in the light blocking film 50b and the corresponding first hole 50b1 (the transmissive area TA) in the Y-axis direction is in the range from 0.5 μm to 5 μm, for example, 2 μm. The width of the second hole 50b2 and the distance between the second hole 50b2 and the first hole 50b1 are about equal. According to the configuration, each second inclined portion is properly formed unlike a configuration in which the distance between the second hole and the first hole is 0.5 μm or smaller, that is, the holes are too close to each other and thus it is difficult to form the second inclined portion. Furthermore, according to the configuration, the holes different from the lower contact holes 1530 are less likely to be formed unlike a configuration in which the distance between the second hole and the first hole is 5 μm or larger. Therefore, the second inclined portions 1549 are properly formed at the edges of the lower contact holes 1530.

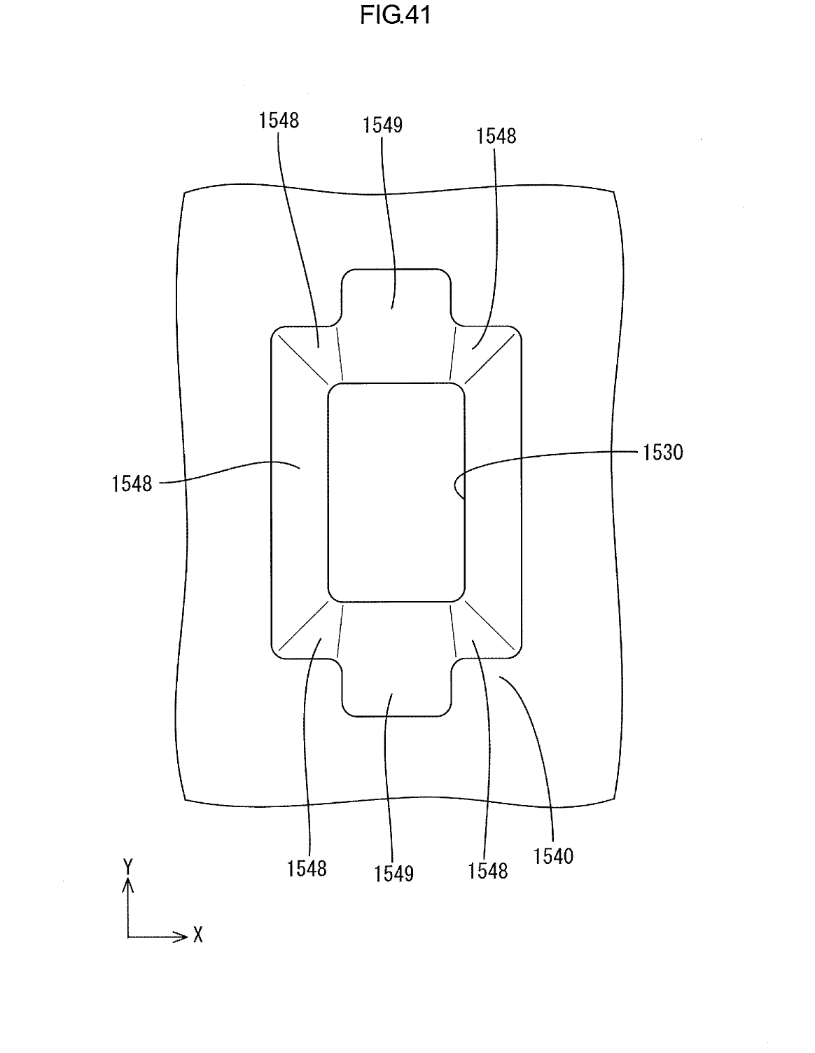

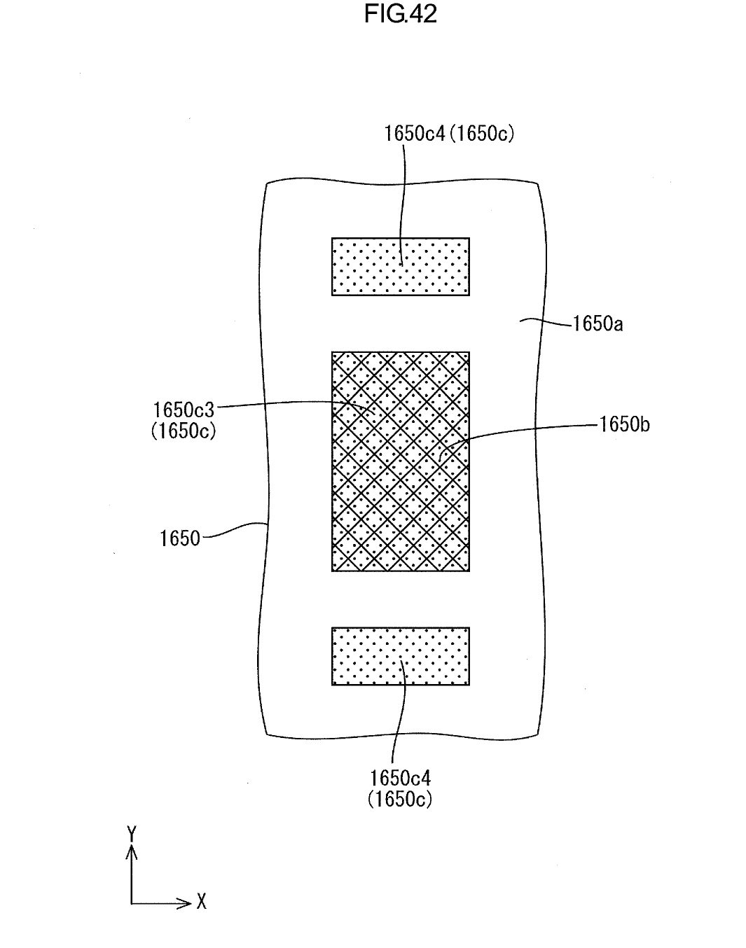

When the organic insulator 1540 is exposed to the exposing light from the light source via the halftone mask 50 having the above configuration and developed, the lower contact holes 1530 and first inclined portions 1548 are formed at positions that overlap the transmissive areas TA in the organic insulator 1540 in a plan view, respectively. Each first inclined portion 1548 defines the edge of the corresponding lower contact hole 1530 and has an inclination angle that is larger. Furthermore, second inclined portions 1549 are formed at positions that overlap the semitransmissive areas HTA in a plan view. Each second inclined portion 1549 has an inclination angle that is smaller. As illustrated in FIG. 41, portions of the halftone mask 50 for forming the respective second inclined portions 1549 with transmitting light through the semitransmissive areas THA are located at the middle of the respective short edges of the lower contact hole 1530. The first inclined portions 1548 are formed at ends of the short edges of the lower contact hole 1530. FIG. 41 is a plan view of the organic insulator 1540 in which the lower contact hole 1530 is formed. Each second inclined portion 1549 is formed at a portion of the corresponding short edge of the lower contact hole 1530. The reason why the second inclined portion 1549 has such a configuration may be that the semitransmissive area HTA of the halftone mask 50 is smaller than the transmissive area TA and thus the rays of the exposing light are more likely to be scattered at the ends of the long dimension and the exposing area of the organic insulator 1540 is relatively small.

Each lower contact hole 1530 of an array board 1511b according to this embodiment formed in the organic insulator 1540 has a polygonal shape in a plan view. The second inclined portion 1549 having the smaller inclination angle and the first inclined portion 1548 having the larger inclination angle of at least two inclined portions 1548 and 1549 are formed at portions of the at least one edge of the lower contact hole 1530, respectively. According to the configuration, when the solution for forming the alignment film reaches at least one edge of the lower contact hole 1530 during the formation of the alignment film, the flow of the solution into the lower contact hole 1530 is promoted by the second inclined portion 1549 formed at a portion of at least one edge of the lower contact hole 1530 and having the smaller inclination angle. Furthermore, the flowability of the solution is increased at the boundary between the second inclined portion 1549 and the first inclined portion 1548 formed at a portion of at least edge of the lower contact hole 1530 and having the larger inclination angle. According to the configuration, the flowability of the solution for forming the alignment film into the lower contact hole 1530 is further promoted and thus defects are further less likely to be developed in the alignment film.

In a first film formation process in a method of producing the array board 1511b according this embodiment, at least the organic insulator 1540 made of photosensitive organic resin material is formed as an insulator. In the process, the halftone mask 50 is used as a photomask. The halftone mask 50 includes the light blocking film 50b and the semitransmissive film 50c. The light blocking film 50b and the semitransmissive film 50c include the holes 50b1, 50b2, and 50c1. The width of the semitransmissive area HTA that is an area in which the second hole 50b2 in the light blocking film 50b and the semitransmissive film 50c overlap each other in a plan view is in the range from 0.5 μm to 5 μm. Using the halftone mask 50, the organic insulator 1540 is exposed to light and the second inclined portion 1549 having the smaller inclination angle among at least two inclined portions 1548 and 1549 is formed at the edge of the lower contact hole 1530 with the light transmitted through the semitransmissive area HTA. According to the method, the lower contact hole 1530 is formed in the organic insulator 1540 formed in the first film formation process with photosensitive organic resin material. The lower contact hole 1530 is formed through the exposure of the organic insulator 1540 using the halftone mask 50. At the edge of the lower contact hole 1530, the second inclined portion 1549 having the smaller inclination angle of at least two inclined portions 1548 and 1549 is formed with the light transmitted through the semitransmissive area HTA that is the area in which the second hole 50b2 in the light blocking film 50b overlaps the semitransmissive film 50c. If the width of the semitransmissive area is smaller than 0.5 μm, the amount of light transmitted through the semitransmissive area may be so small that underexposure may occur. As a result, the second inclined portion having the smaller inclination angle may not be formed in the organic insulator 1540. If the width of the semitransmissive area is larger than 5 μm, holes different from the lower contact hole 1530 may be formed in the organic insulator 1540. As a result, the second inclined portion having the smaller inclination angle may not be formed in the organic insulator 1540. By setting the width of the semitransmissive area HTA of the halftone mask 50 in the range from 0.5 μm to 5 μm as described earlier, the organic insulator 1540 is properly exposed and the second inclined portion 1549 having the smaller inclination angle is properly formed at the edge of the lower contact hole 1530.

In the first film formation process in the method of producing the array board 1511b, the organic insulator 1540 made of positive photosensitive organic resin material is exposed using the halftone mask 50. The halftone mask 50 includes the transmissive area TA that is an area in which the first hole 50b1 in the light blocking film 50b and the hole 50c1 in the semitransmissive film 50c overlap each other in a plan view and the distance between the transmissive area TA and the semitransmissive area HTA is in the range from 0.5 μm to 5 μm. If the distance between the transmissive area TA and the semitransmissive area HTA is smaller than 0.5 μm, the semitransmissive area is so close to the transmissive area that it may be difficult to form the second inclined portion having the smaller inclination angle. If the distance between the transmissive area TA and the semitransmissive area HTA is larger than 5 μm, holes different from the lower contact hole 1530 may be formed in the organic insulator 1540. Therefore, the second inclined portions having the smaller inclination angle may not be formed in the organic insulator 1540. By setting the distance between the transmissive area TA and the semitransmissive area HTA of the halftone mask 50 in the range from 0.5 μm to 5 μm, the organic insulator 1540 is properly exposed and the second inclined portions 1549 having the smaller inclination angle are properly formed to the edges of the lower contact hole 1530.

### Seventeenth Embodiment

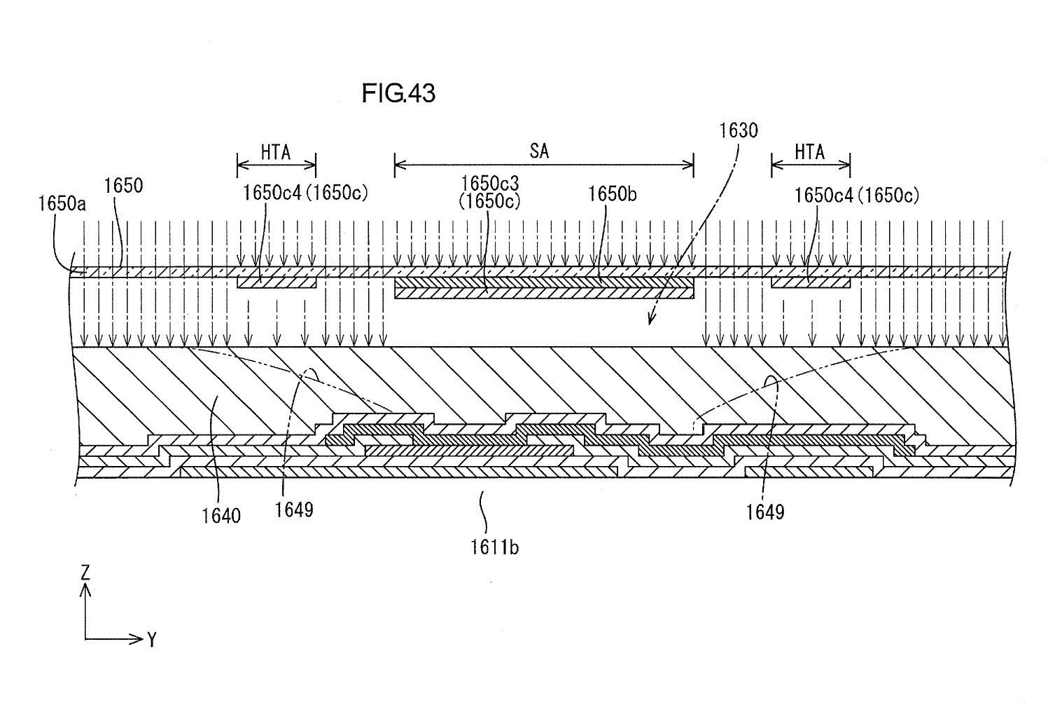

A seventeenth embodiment will be described with reference to FIGS. 42 and 43. In the seventeenth embodiment, a photomask for exposing an organic insulator 1640 different from the sixteenth embodiment is used. Structures, functions, and effects similar to those of the sixteenth embodiment will not be described.

The organic insulator 1640 according to this embodiment is made of photosensitive organic resin material having negative photosensitivity. For patterning of the organic insulator 1640, a halftone mask 1650 having a basic configuration similar to the sixteenth embodiment (a configuration including a glass substrate 1650a, a light blocking film 1650b, and a semitransmissive film 1650c) is used as a photomask. As illustrated in FIG. 42, an area of the halftone mask 1650 in which the light blocking film 1650b is formed and an area thereof in which the semitransmissive film 1650c is formed are different (or reversed) from those of the halftone mask 50 in the sixteenth embodiment. The light blocking film 1650b has a vertically-long rectangular shape in a plan view. The light blocking film 1650b is formed in areas that overlap lower contact holes 1630 in a plan view and other areas are holes. The semitransmissive film 1650c includes first semitransmissive portions 1650c3 and second semitransmissive portions 1630c4. Each first semitransmissive portion 1630c3 is formed in an area that overlaps the light blocking film 1650b in a plan view. Each second semitransmissive portion 1630c4 is formed at a position a predefined distance away from the first semitransmissive portion 1650c3 and a predefined distance away from the light blocking film 1650b. Namely, the second semitransmissive portion 1630c4 is formed at a position that does not overlap the light blocking film 1650b in a plan view. The other areas in which the first and the second semitransmissive portions are not formed are holes. Areas of the halftone mask 1650 which do not overlap the light blocking film 1650b and the semitransmissive film 1650c (the first semitransmissive portions 1650c3 and the second semitransmissive portions 1650c4) are defined as transmissive areas through which about 100% of rays of exposing light from a light source pass. Areas of the semitransmissive film 1650c which overlap the second semitransmissive portions 1650c4 in a plan view are defined as semitransmissive area HTA though which rays of exposing light from the light source pass with transmissivity about equal to the transmissivity of the semitransmissive film 1650c. Areas of the light blocking portion 1650b and the semitransmissive film 1650c in which third semitransmissive portions 1650c3 are formed are defined as light blocking areas SA having about 0% of exposing light transmissivity. In FIG. 42, an area of the halftone mask 1650 in which the light blocking film 50b is formed is indicated by a lattice pattern and an area thereof in which the semitransmissive film 1650c is formed is indicated by a dot pattern. In FIG. 42, in an area in which the lattice pattern and the dot pattern overlap each other, the light blocking film 1650b and the semitransmissive film 1650c overlap each other.

As illustrated in FIGS. 42 and 43, within the plate surface of the halftone mask 1650, second semitransmissive portions 1650c4 (semitransmissive areas HTA) are away from edges of a light blocking film 1650b (a light blocking area SA) in the Y-axis direction so as to be opposed to each other. A dimension of each of the second semitransmissive portions 1650c4 along the X-axis direction, that is, a length thereof is about equal to that of the first light blocking portion 1650b. A dimension of each second semitransmissive portion 1650c4 (the semitransmissive area HTA) of the semitransmissive film 1650c, that is, a width thereof is in a range from 0.5 μm to 5 μm, for example, 2 μm. According to the configuration, underexposure of the organic insulator 1640 which may occurs when the width of each second semitransmissive portion is 0.5 μm or smaller is less likely to occur. Furthermore, holes different from the lower contact holes 1630 which may be formed when the width of each second semitransmissive portion is 5 μm or larger are less likely to be formed. Namely, according to the configuration, second inclined portions 1649 are properly formed at edges of the lower contact holes 1630. A distance between each second semitransmissive portion 1650c4 (the semitransmissive area HTA) in the semitransmissive film 1650c and the light blocking film 1650b (the light blocking area SA) in the Y-axis direction is in the range from 0.5 μm to 5 μm, for example, 2 μm. The width of the second semitransmissive portion 1650c4 and the distance between the second semitransmissive portion 1650c4 and the light blocking film 1650b are about equal. According to the configuration, each second inclined portion is properly formed unlike a configuration in which the distance between the semitransmissive portion and the light blocking film is 0.5 μm or smaller, that is, the second semitransmissive portion and the light blocking film are too close to each other and thus it is difficult to form the second inclined portion. Furthermore, according to the configuration, the holes different from the lower contact holes 1630 are less likely to be formed unlike a configuration in which the distance between the second semitransmissive portion and the light blocking film is 5 μm or larger. Therefore, the second inclined portions 1649 are properly formed at the edges of the lower contact holes 1630.

After the organic insulator 1640 is exposed with the exposing light from the light source via the halftone mask 1650 having the above configuration, the organic insulator 1640 is developed. As a result, the lower contact holes 1630 and the first inclined portions 1648 are formed in the portions overlapping the light blocking area SA of the organic insulator 1640 in a plan view. The first inclined portions 1648 are at edges of the lower contact holes 1630 and each first inclined portion 1648 has the larger inclination angle. Furthermore, the second inclined portions 1649 are formed in the portions overlapping the semitransmissive areas HTA in a plan view. The second inclined portions 1649 are at edges of the lower contact holes 1630 and each second inclined portion 1649 has the smaller inclination angle. The areas in which the second inclined portions 1649 are formed are similar to those of the sixteenth embodiment (see FIG. 41).

As described earlier, the method of producing the array board 1611b according to this embodiment includes the first film forming process. In the first film forming process, the photosensitive organic resin material of the organic insulator 1640 is used as a negative and the organic insulator 1640 is exposed with the halftone mask 1650. The halftone mask 1650 includes the light blocking areas SA in the portions overlapping the light blocking film 1640b in a plan view and the distance between each light blocking area SA and the corresponding semitransmissive area HTA is in the range from 0.5 μm to 5 μm. If the distance between the light blocking area and the semitransmissive area of the halftone mask is 0.5 μm or smaller, that is, the semitransmissive portion is so close to the light blocking area that it may be difficult to form the second inclined portion having the smaller inclination angle. If the distance between the light blocking area and the semitransmissive area of the halftone mask is 5 μm or larger, the holes different from the lower contact hole 1630 may be formed in the organic insulator 1640. As a result, the second inclined portion having the smaller inclination angle may not be formed in the organic insulator 1640. By setting the distance between the light blocking area SA and the semitransmissive area HTA of the halftone mask 1650 in the range from 0.5 μm to 5 μm as described earlier, the organic insulator 1640 is properly exposed and the second inclined portions 1649 having the smaller inclination angle are properly formed at the edge of the lower contact holes 1630.

### Eighteenth Embodiment

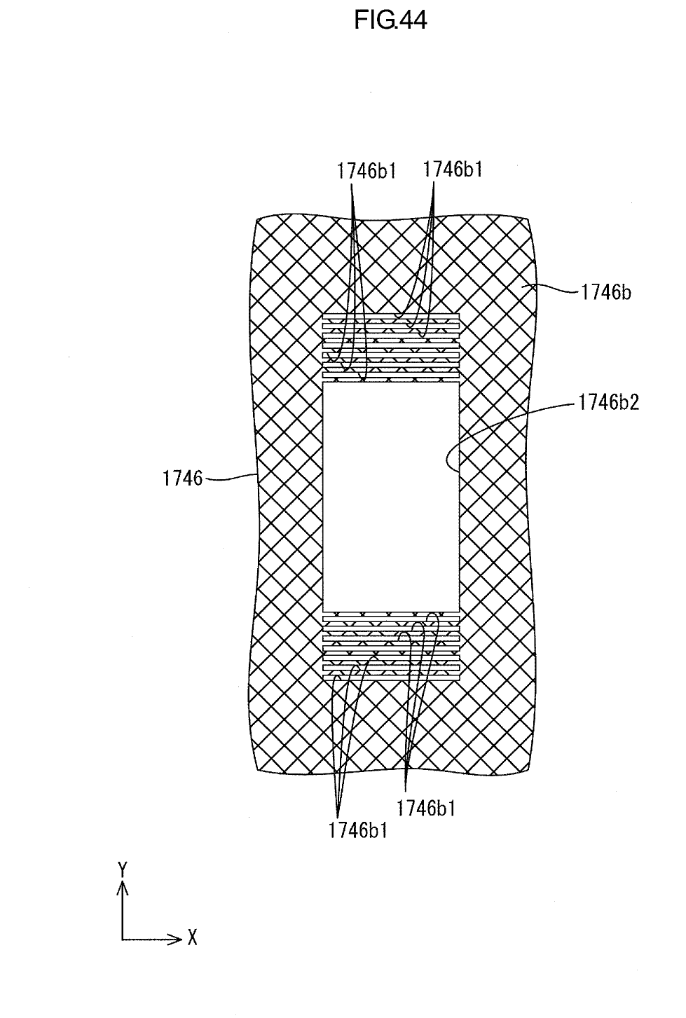

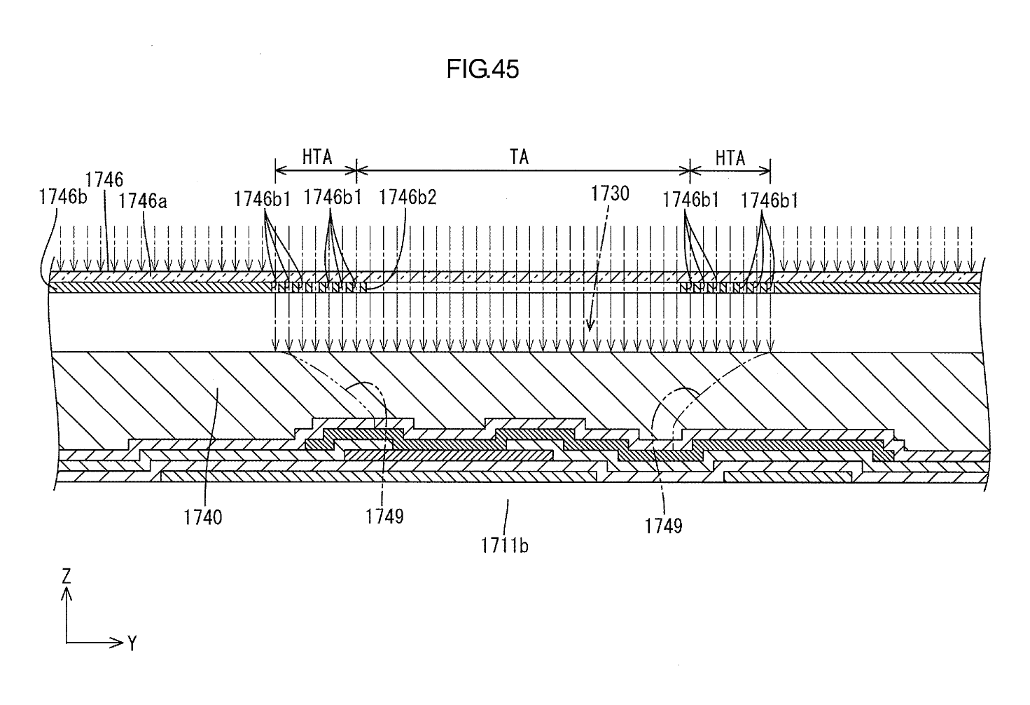

An eighteenth embodiment of the present invention will be described with reference to FIGS. 44 and 45. In the eighteenth embodiment, a photomask for exposing an organic insulator 1740 different from the sixteenth embodiment is used. Structures, functions, and effects similar to those of the sixteenth embodiment will not be described.

The organic insulator 1740 according to this embodiment is made of photosensitive organic resin material having negative photosensitivity. For patterning of the organic insulator 1740, a gray tone mask 1746 is used as a photomask. The gray tone mask 1746 has a basic configuration similar to the one used in the fourteenth embodiment (a configuration including a glass substrate 1746a and a light blocking film 1746b). As illustrated in FIGS. 44 and 45, the light blocking film 1746b of the gray tone mask 1746 includes holes 1746b2 in portions overlapping lower contact holes 1730 in a plan view and slits 1746b1 adjacent to the respective holes 1746b2 in the Y-axis direction. Each slit 1746b1 has a width smaller than a resolution of an exposure device. Multiple slits 1746b1 are arranged separately from one another on either sides of the corresponding hole 1746b2 in the Y-axis direction. Namely, two groups of slits are formed such that the hole 1746b2 are therebetween in the Y-axis direction. Portions of the gray tone mask 1746 including the groups of the slits are semitransmissive areas HTA. Portions of the gray tone mask 1746 including the holes 1746b2 are transmissive areas TA. In FIG. 44, a portion of the gray tone mask 1746 including the light blocking film 1746b is indicated by a lattice pattern.

After the organic insulator 1740 is subjected to exposing light from a light source via the gray tone mask 1746 having the above configuration, the organic insulator 1740 is developed. As a result, lower contact holes 1730, first inclined portions, and second inclined portions 1749 are formed. The lower contact holes are formed in portions of the organic insulator 1740 overlapping the transmissive areas TA. The first inclined portions are formed at edges of the lower contact holes 1730. Each first inclined portion has a larger inclination angle. The second inclined portions 1749 are formed in portions of the organic insulator 1740 overlapping the semitransmissive areas HTA in a plan view. The second inclined portions 1749 are formed at edges of lower contact holes 1730. Each second inclined portion has a smaller inclination angle. The portions in which the second inclined portions 1749 are formed are similar to those of the sixteenth embodiment described earlier (see FIG. 41).

As described earlier, the method of producing the array board 1711b according to this embodiment includes the first film forming process. In the first film forming process, at least the organic insulator is formed from photosensitive organic resin material as an insulator. The organic insulator 1740 is exposed using the gray tone mask 1746 as a photomask. The gray tone mask 1746 includes the light blocking film 1746b including the slits 1746b1 and the semitransmissive areas THA in which the slits 1746b1 are formed and the width of which is in the range from 0.5 μm to 5 μm. With rays of light transmitted through the semitransmissive areas HTA, at least second inclined portion 1749 having the smaller inclination angle among the inclined portions is formed at the edge of the corresponding lower contact hole 1730. By exposing the organic insulator 1740, which is made of photosensitive organic resin material in the first film forming process, using the gray tone mask 1746, the lower contact holes 1730 are formed in the organic insulator 1740. The second inclined portions 1749 are formed at the edges of the lower contact holes 1730 with the rays of light transmitted through the semitransmissive areas HTA of the light blocking film 1746b in which the slits 1746b1 are formed. The second inclined portions 1749 are the inclined portions having the smaller inclination angle among the inclined portions. If the width of the semitransmissive area is smaller than 0.5 μm, an amount of light transmitted through the semitransmissive areas may be so small that underexposure may occur. As a result, the second inclined portions having the smaller inclination angle may not be formed in the organic insulator 1740. If the width of the semitransmissive area is larger than 5 μm, multiple steps may be formed at the edges of the lower contact holes 1730. As a result, the second inclined portions having the smaller inclination angle may not be formed in the organic insulator 1740. By setting the width of each semitransmissive area HTA of the in the range from 0.5 μm to 5 μm, the organic insulator 1740 are properly exposed and the second inclined portions 1749 are properly formed at the edges of the lower contact holes 1730.

### Nineteenth Embodiment

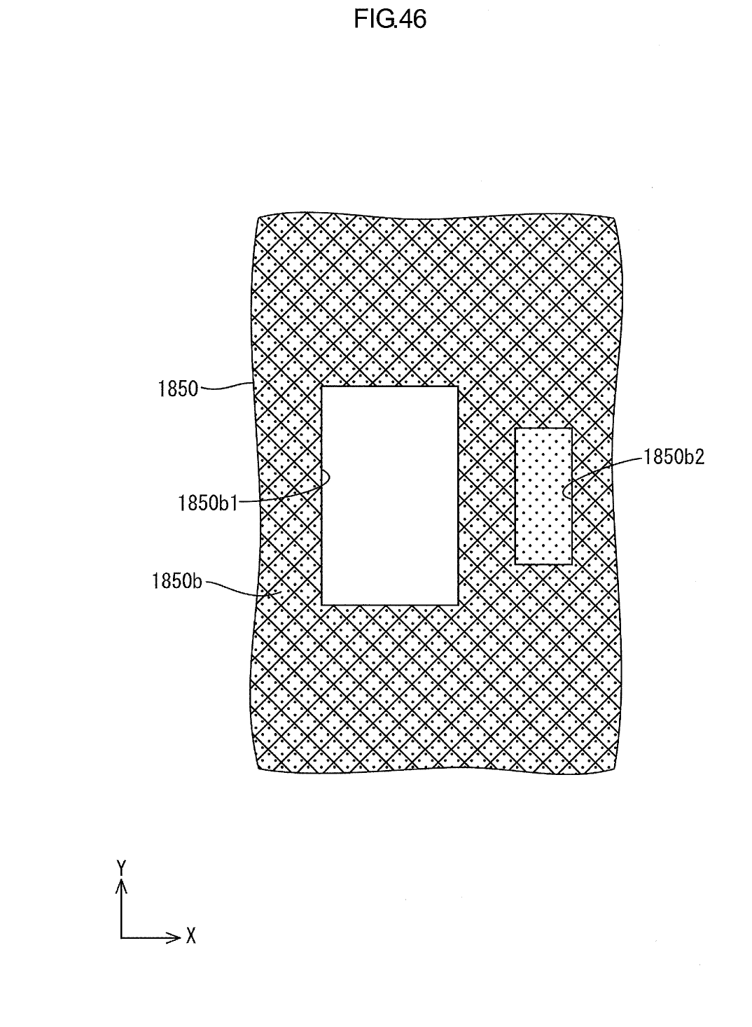

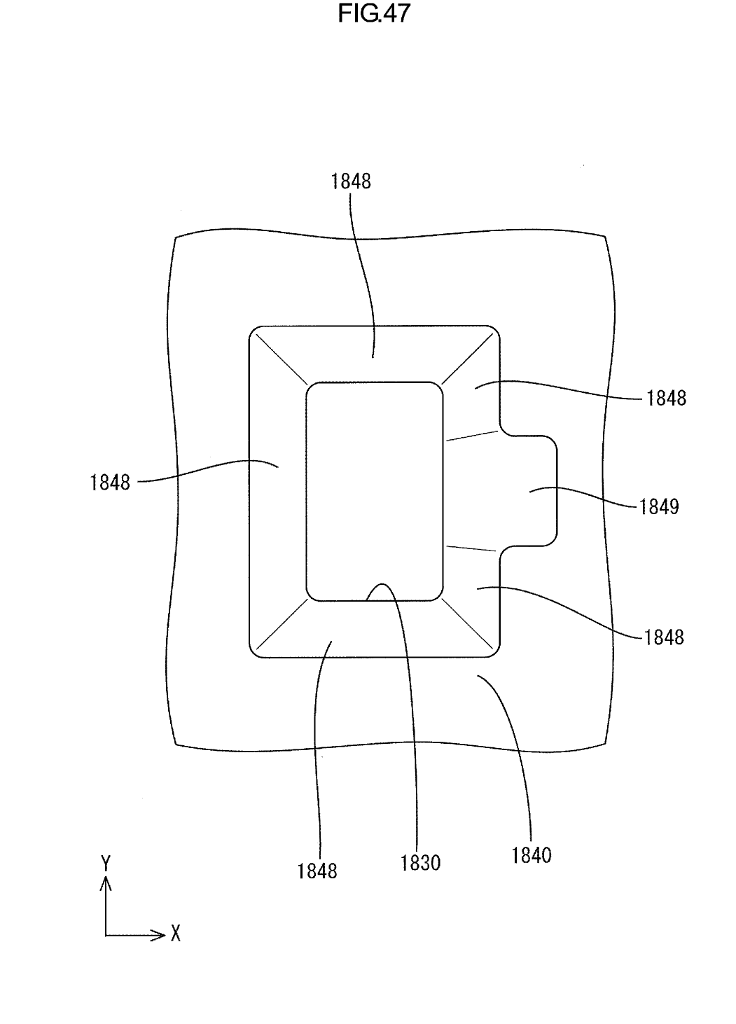

A nineteenth embodiment of the present invention will be described with reference to FIGS. 46 and 47. In the nineteenth embodiment, a halftone mask 1850 including a light blocking film 1850b is used. The light blocking film 1850b includes second holes 1850b2, the number and arrangement of which are different from those of the sixteenth embodiment. Structures, functions, and effects similar to those of the sixteenth embodiment will not be described.

As illustrated in FIG. 46, the halftone mask 1850 according to this embodiment includes a light blocking film 1850b that includes a single second hole 1850b2 for each first hole 1850b1. The second hole 1850b2 is a predefined distance away from the first hole 1850b1. The second hole 1850b2 has a length (a dimension along the Y-axis direction) is smaller than the length of the first hole 1850b1. A Y-axis position of the center of the second hole 1850b2 correspond with a Y-axis position of the center of the first hole 1850b1. The width of the second hole 1850b2 and a distance between the first hole 1850b1 and the second hole 1850b2 are equal to those of the sixteenth embodiment. When the organic insulator 1840 is developed after exposed using the halftone mask 1850 having the above configuration, first inclined portions 1848 having a larger inclination angle are formed in portions of the organic insulator 1840 overlapping the first holes 1850b1 (the transmissive areas TA) in a plan view as illustrated in FIG. 47. The first inclined portions 1848 are formed at edges of the lower contact holes 1830 and have a larger inclination angle. Furthermore, second inclined portions 1849 are formed in portions of the organic insulator 1840 overlapping the second holes 1850b2 (the semitransmissive areas HTA) in a plan view. The second inclined portions 1849 are formed at the lower contact holes 1830 and have a smaller inclination angle. Each second inclined portion 1849 is formed at one of long edges of the corresponding lower contact hole 1830. A portion of the long edge at which the second inclined portion 1849 is formed is a middle portion of the long edge. At side portions of the long edge, the first inclined portions 1848 are formed.

As described above, the organic insulator 1840 in the array board according to this embodiment includes the lower contact holes 1830 each having the rectangular shape in a plan view. The second inclined portion 1849 having the smaller inclination angle and the first inclined portions 1848 having the larger inclination angle are formed at the portions of long edge of each lower contact hole. According to the configuration, that is, the second inclined portion 1849 having the smaller inclination angle and the first inclined portions 1848 having the larger inclination angle are formed at the portions of long edge of each lower contact hole, flowability of a solution for forming an alignment film is increased at a boundary between the inclined portions 1848 and 1849 having different inclination angles during the formation of the alignment film. This configuration is especially preferable when there is not sufficient space for forming the second inclined portions 1849 having the smaller inclination angle at the short edges of the lower contact holes 1830.

### Twentieth Embodiment

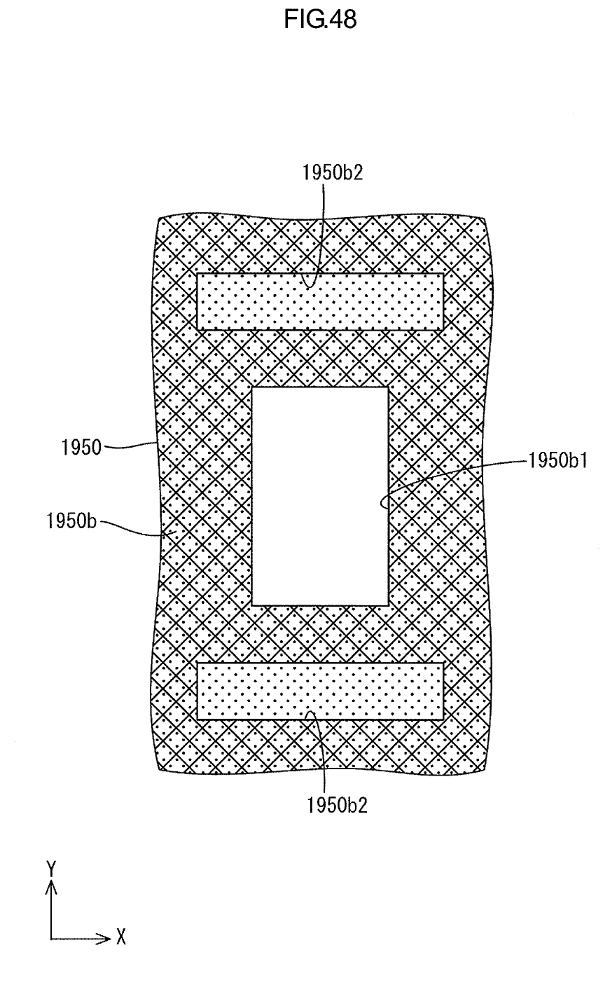

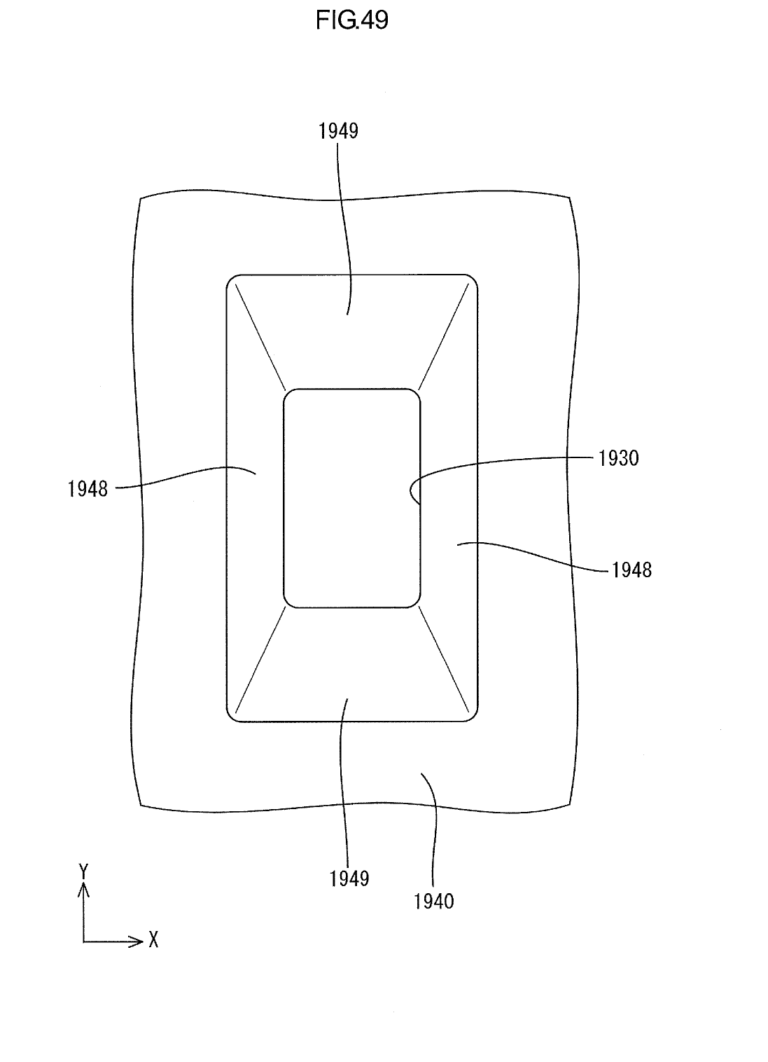

A twentieth embodiment of the present invention will be described with reference to FIGS. 48 and 49. In the twentieth embodiment, a halftone mask 1950 including a light blocking film 1950b is used. The light blocking film 1950b includes second holes 1950b2 formed in portions different from the sixteenth embodiment. Structures, functions, and effects similar to those of the sixteenth embodiment will not be described.

As illustrated in FIG. 48, the halftone mask 1950 according to this embodiment includes alight blocking film 1950b that includes second holes 1950b2 each having a length (a dimension along the X-axis direction) is larger than a width of a first hole 1950b1. An exposed area of the organic insulator 1940 may be decreased due to scattering of exposing light at ends of the long dimension of the second holes 1950b2. A difference between the length of the second hole 1950b2 and the width of the first hole 1950b1 is defined to compensate the decrease of the exposed area. When the organic insulator 1940 is developed after exposed using the halftone mask 1950 having the above configuration, as illustrated in FIG. 49, the second inclined portion 1949 is formed at one of short edges of each lower contact hole 1930 for an entire length thereof. Namely, the first inclined portion 1948 and the second inclined portion 1949 are not formed at the same short edge.

### Twenty-First Embodiment

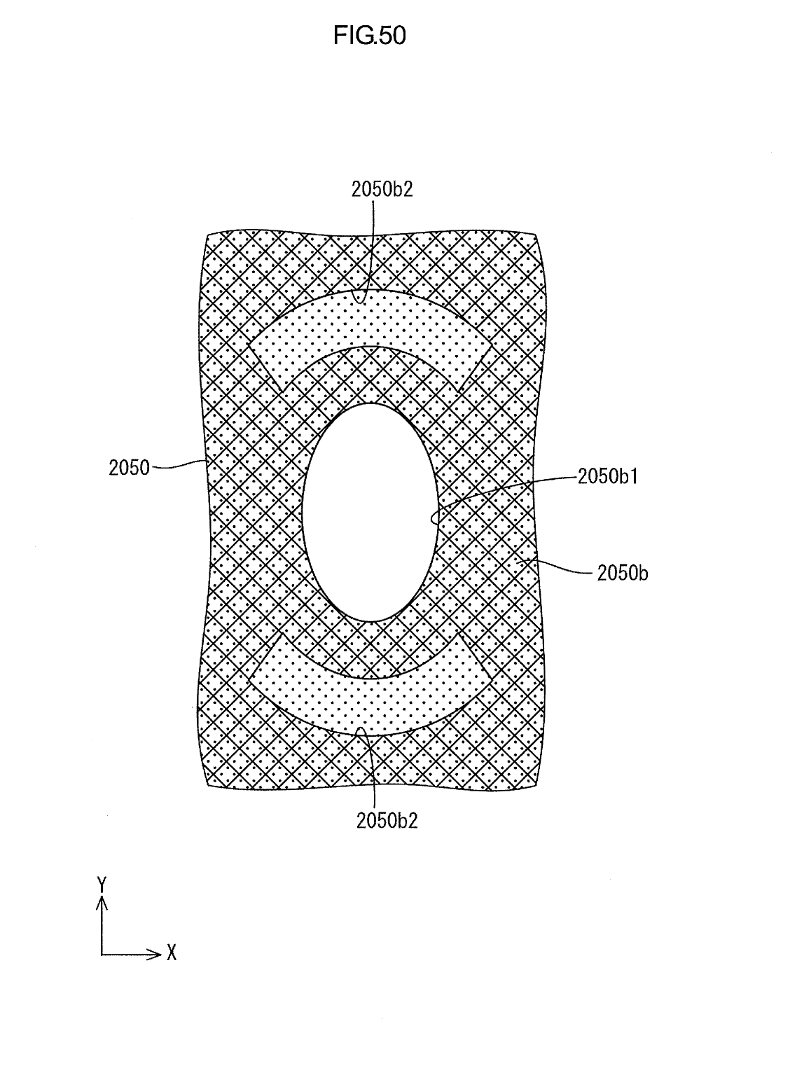

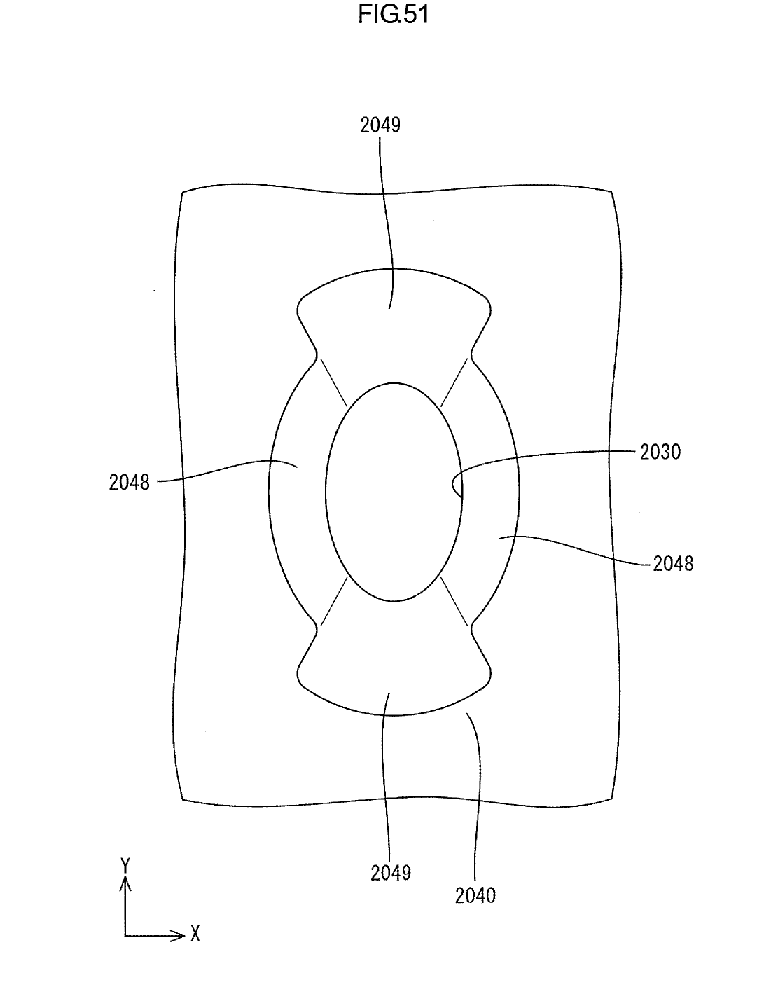

A twenty-first embodiment of the present invention will be described with reference to FIGS. 50 and 51. In the twenty-first embodiment, a halftone mask 2050 including a light blocking film 2050b that includes first holes 2050b1 and second holes 2050b2 having shapes different from the sixteenth embodiment in a plan view. Structures, functions, and effects similar to those of the sixteenth embodiment will not be described.

As illustrated in FIG. 50, each of the first holes 2050b1 formed in the light blocking film 2050b of the halftone mask 2050 has a vertically-long oval shape in a plan view. Each of the second holes 2050b2 has a fan-like shape along the outline of the first hole 2050b1 in a plan view. When the organic insulator 2040 is developed after exposed using the halftone mask 2050 having the above configuration, as illustrated in FIG. 51, each lower contact hole 2030 is formed in a vertically-long oval shape in a plan view and second inclined portions 2049 are formed at edges of the lower contact hole 2030 opposite to each other in the long-axis direction (the Y-axis direction). First inclined portions 2048 are formed at edges of the lower contact hole 2030 opposite to each other in the short-axis direction (the X-axis direction).

As described above, the organic insulator 2040 in the array board according to this embodiment includes the lower contact holes 2030 each having the oval shape in a plan view. Each lower contact hole 2030 having the oval shape in a plan view does not have edges that cross each other. When a solution for forming an alignment film reaches the edge of the lower contact hole 2030 during the formation of the alignment film, droplets of the solution are less likely to merge and thus the solution is less likely to flow into the lower contact hole 2030. By forming at least two inclined portions having different inclination angles at the edge of the lower contact hole 2030, a sufficient level of flowability of the solution for forming the alignment film into the lower contact hole 2030 is achieved.

### Twenty-Second Embodiment

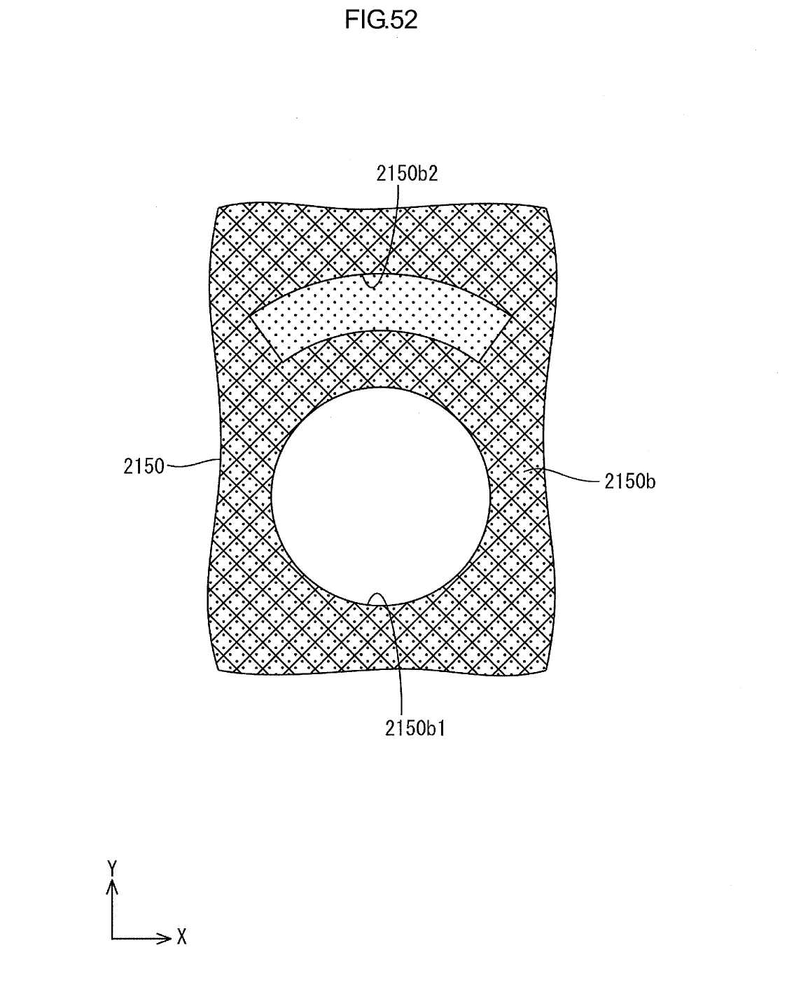

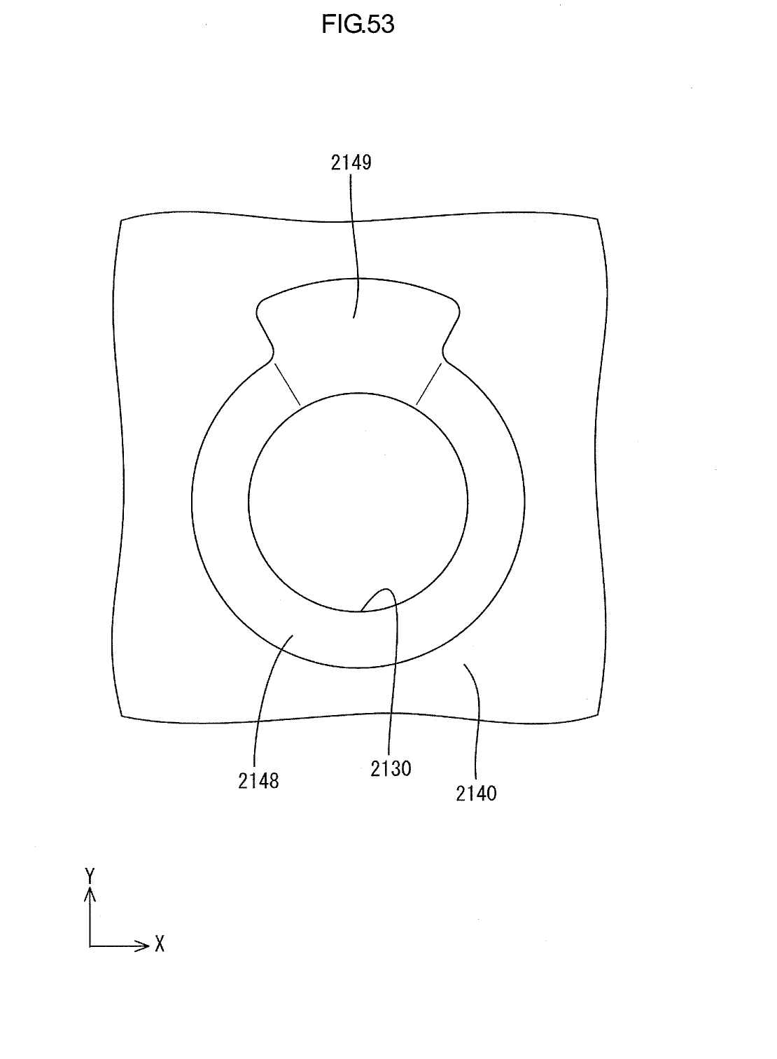

A twenty-second embodiment of the present invention will be described with reference to FIGS. 52 and 53. In the twenty-second embodiment, a halftone mask 2150 including a light blocking film 2150b that includes first holes 2150b1 and second holes 2150b2 is used. The first holes 2150b1 and the second holes 2150b2 have shapes different from those in the sixteenth embodiment. Structures, functions, and effects similar to those of the sixteenth embodiment will not be described.

As illustrated in FIG. 52, each of the first holes 2150b1 formed in the light blocking film 2150b of the halftone mask 2150 according to this embodiment has a round shape in a plan view. Each of the second holes 2150b2 has a fan-like shape along an outline of the corresponding first hole 2150b1 in a plan view. A single second hole 2150b2 is formed in the light blocking film 2150b. When an organic insulator 2140 is developed after exposed using the halftone mask 2150 having the above configuration, as illustrated in FIG. 53, the lower contact hole 2130 having the round shape in a plan view is formed. Furthermore, a second inclined portion 2149 is formed at a portion of an edge of the lower contact hole 2130 and a first inclined portion 2148 is formed at the rest of the edge.

As described above, each lower contact hole 2130 is formed in the round shape in a plan view in the organic insulator 2140 in an array board according to this embodiment. The lower contact hole 2130 having the round shape in a plan view does not have edges that cross each other. When a solution for forming an alignment film reaches the edge of the lower contact hole 2130 during the formation of the alignment film, droplets are less likely to merge and thus the solution is less likely to flow into the lower contact hole 2130. By forming at least two inclined portions having different inclination angles at the edge of the lower contact hole 2130, a sufficient level of flowability of the solution for forming the alignment film into the lower contact hole 2130 is achieved.

### Twenty-Third Embodiment

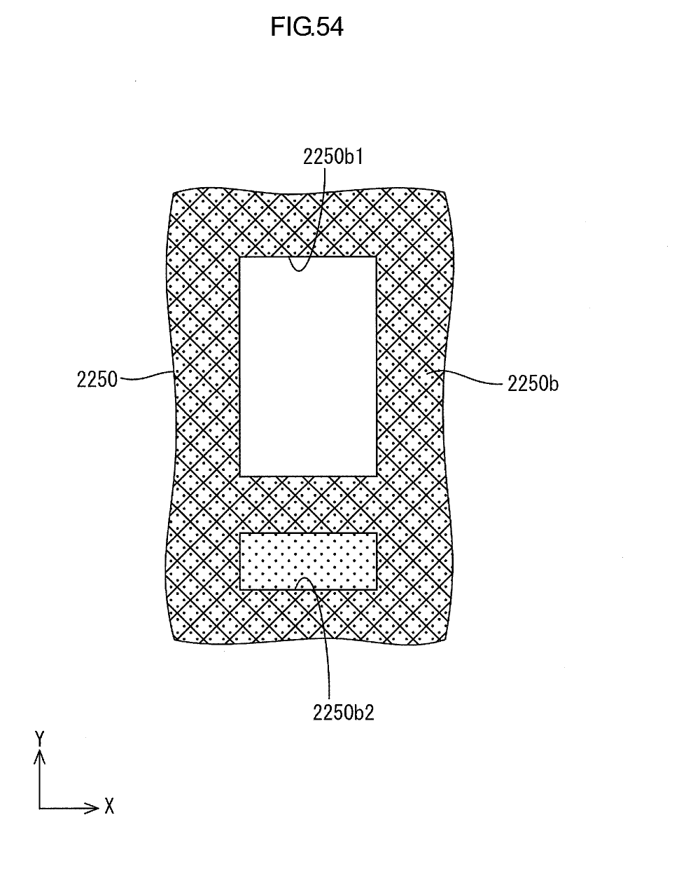

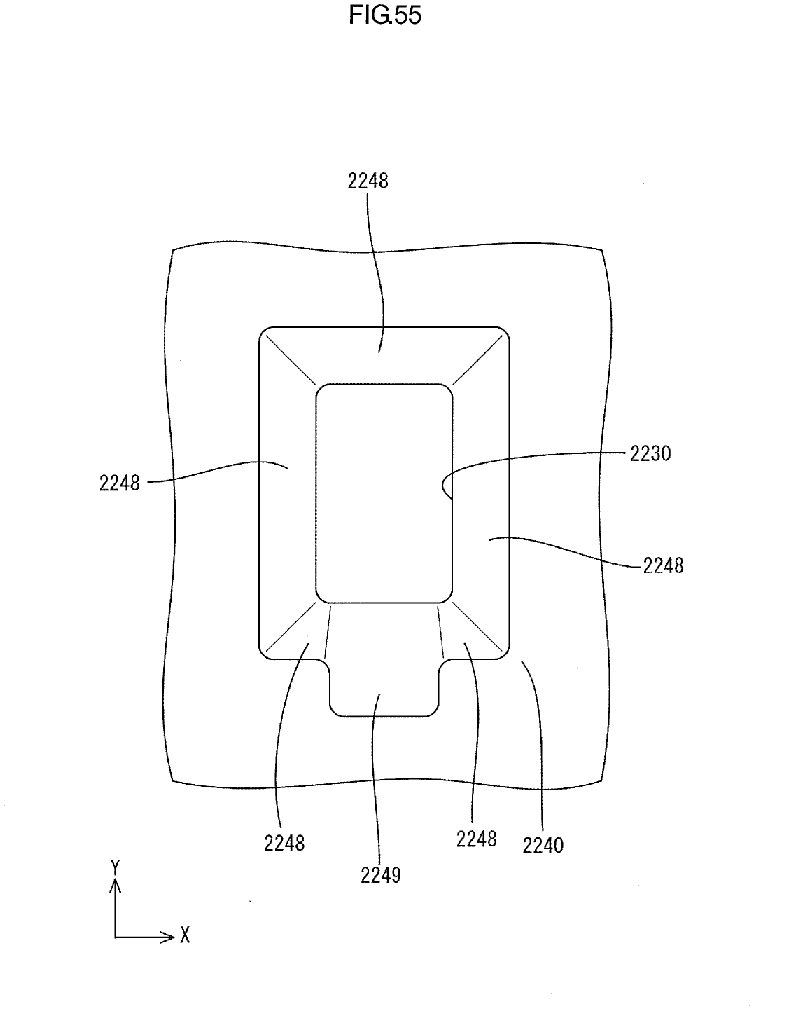

A twenty-third embodiment of the present invention will be described with reference to FIGS. 54 and 55. In the twenty-third embodiment, a light blocking film 2250b in a halftone mask 2250 includes the number of second holes 2250b2 different from the sixteenth embodiment. Structures, functions, and effects similar to those of the sixteenth embodiment will not be described.

As illustrated in FIG. 54, the halftone mask 2250 according to this embodiment includes a single second hole 2250b2 for each first hole 2250b1 in the light blocking film 2250b. The second hole 2250b2 is at a distance from an edge of the first hole 2250b1 in the Y-axis direction. When the organic insulator 2240 is developed after exposed using the halftone mask 2250 having the above configuration, as illustrated in FIG. 55, a second inclined portion 2249 is formed at a middle portion of a short edge of the lower contact hole 2230 and first inclined portions 2248 are formed at sides of the short edge.

### Twenty-Fourth Embodiment

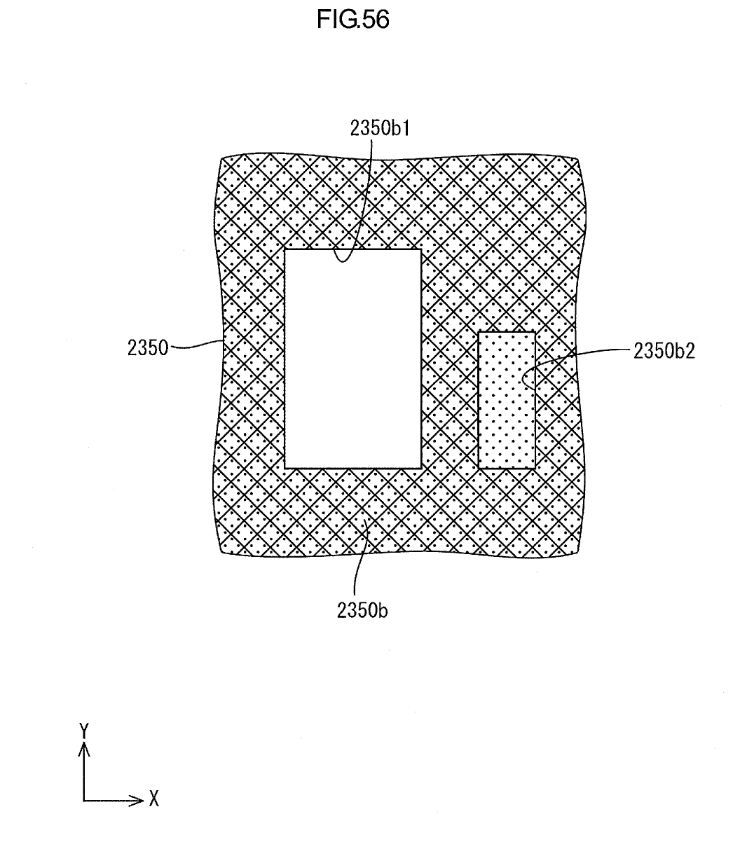

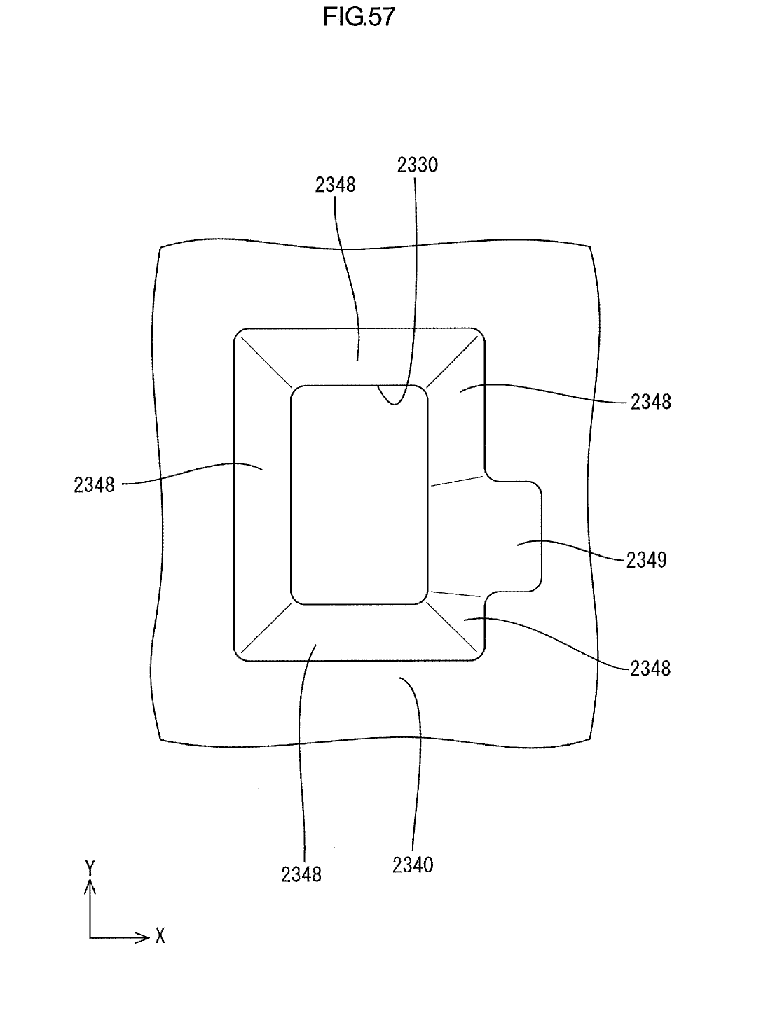

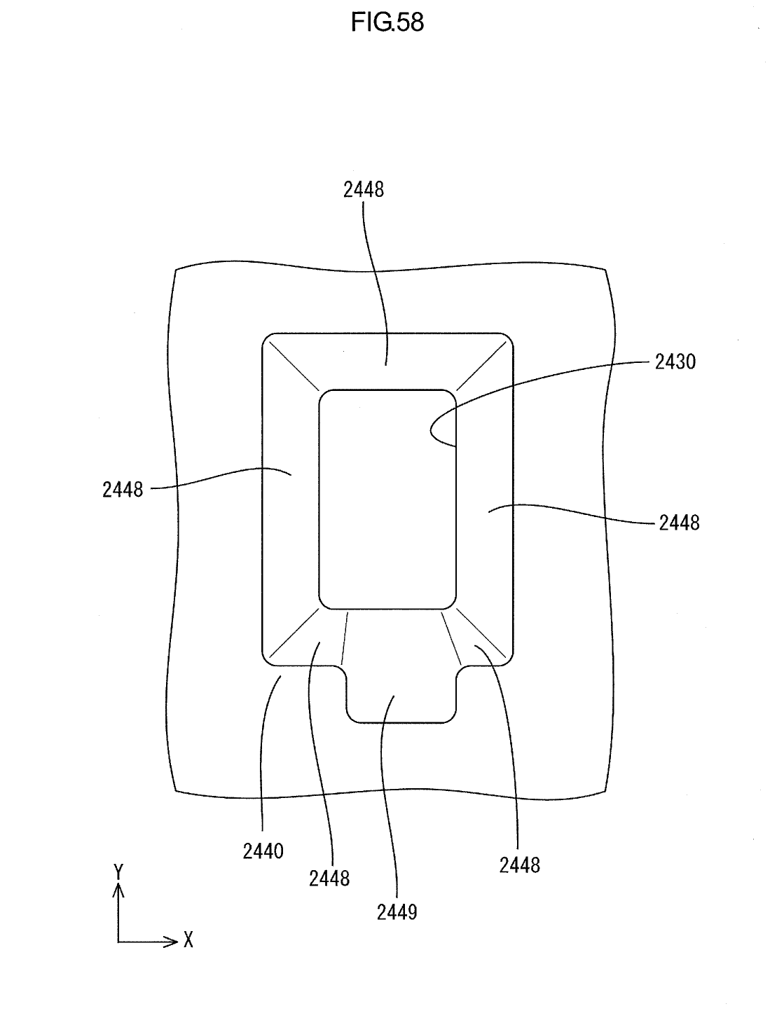

A twenty-fourth embodiment of the present invention will be described with reference to FIGS. 56 and 57. In the twenty-fourth embodiment, a light blocking film 2350b in a halftone mask 2350 includes second holes 2250b2 arranged differently from the nineteenth embodiment. Structure, functions, and effects similar to those of the nineteenth embodiment will not be described.

As illustrated in FIG. 56, the halftone mask 2350 according to this embodiment includes a single second hole 2350b2 for each first hole 2350b1 in the light blocking film 2350b. The second hole 2350b2 is at a distance from an edge of the first hole 2350b1 in the X-axis direction. An edge of the second hole 2350b2 is substantially flush with an edge of the first hole 2350b1 in the Y-axis direction. When an organic insulator 2340 is developed after exposed using the halftone mask 2350 having the above configuration, as illustrated in FIG. 57, a second inclined portion 2349 is formed at a portion of a long edge of a lower contact hole 2330 closer to an end of the long edge and first inclined portions 2348 are formed at the rest of the portions of the edges.

### Twenty-Fifth Embodiment

A twenty-fifth embodiment of the present invention will be described with reference to FIG. 58. In the twenty-fifth embodiment, each of second inclined portions 2449 is formed at a portion of a lower contact hole 2430 different from the twenty-fourth embodiment. Structures, functions, and effects similar to those of the twenty-fourth embodiment will not be described.

As illustrated in FIG. 58, the second inclined portion 2449 is formed at a portion of a short edge of a lower contact hole 2430 closer to an end of the short edge. First inclined portions 2448 are formed at the rest of the portions of edges. In the halftone mask for exposing an organic insulator 2440 that includes the lower contact holes 2430 having the above configuration, a single second hole is formed at a distance from an edge of a first hole in the Y-axis direction. Furthermore, an edge of the second hole is substantially flush with an edge of the first hole in the X-axis direction.

### Twenty-Sixth Embodiment

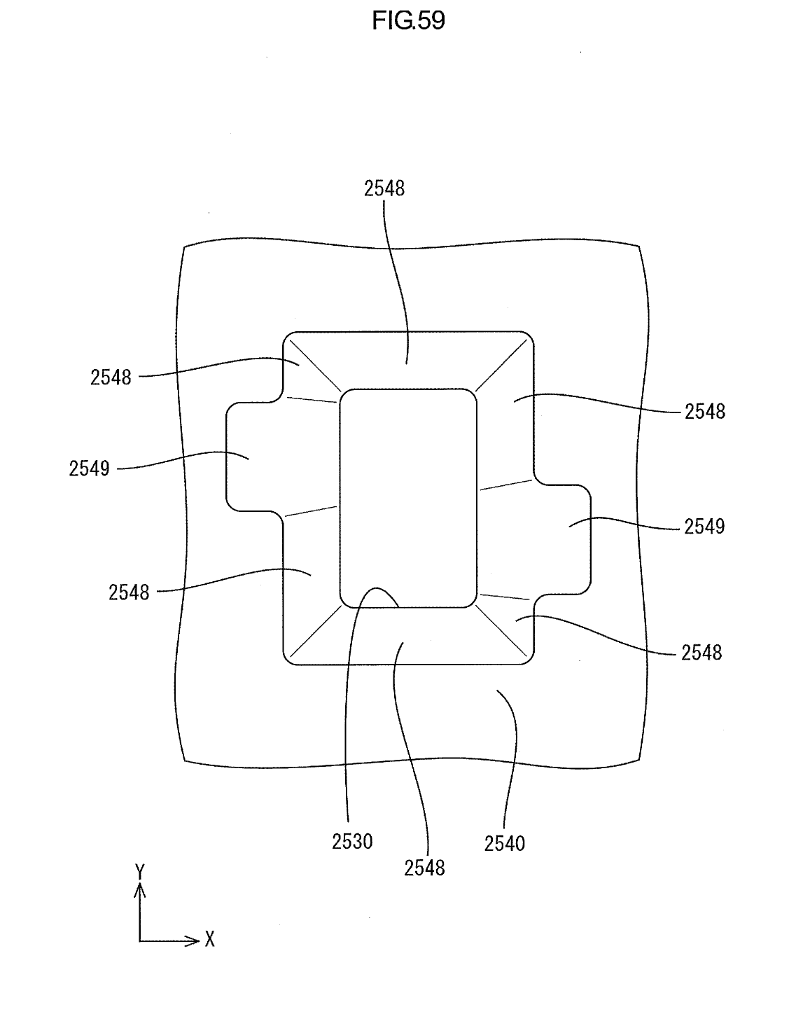

A twenty-sixth embodiment of the present invention will be described with reference to FIG. 59. In the twenty-sixth embodiment, the number of second inclined portions 2549 at edges of each lower contact hole 2530 is different from the twenty-fourth embodiment. Structures, functions, and effects similar to those of the twenty-fourth embodiment will not be described.

As illustrated in FIG. 59, the second inclined portions 2549 are formed at long edges of each lower contact hole 2530, respectively. The second inclined portions 2549 are located closer to ends of the respective long edges. The second inclined portion 2549 formed at one of the long edges of the lower contact hole 2530 and the second inclined portion 2549 formed at the other long edge are located closer to ends of the long edges opposite to each other in the Y-axis direction. First inclined portions 2548 are formed at the rest of the portions of the long edges, at other portions of which the second inclined portions 2549 are formed. In the halftone mask for exposing an organic insulator 2540 that includes the lower contact holes 2530 having the above configuration, two second holes are formed at a distance from edges of a first hole in the X-axis direction, respectively. Furthermore, edges of the second holes are substantially flush with edges of the first hole in the Y-axis direction, respectively.

### Twenty-Seventh Embodiment

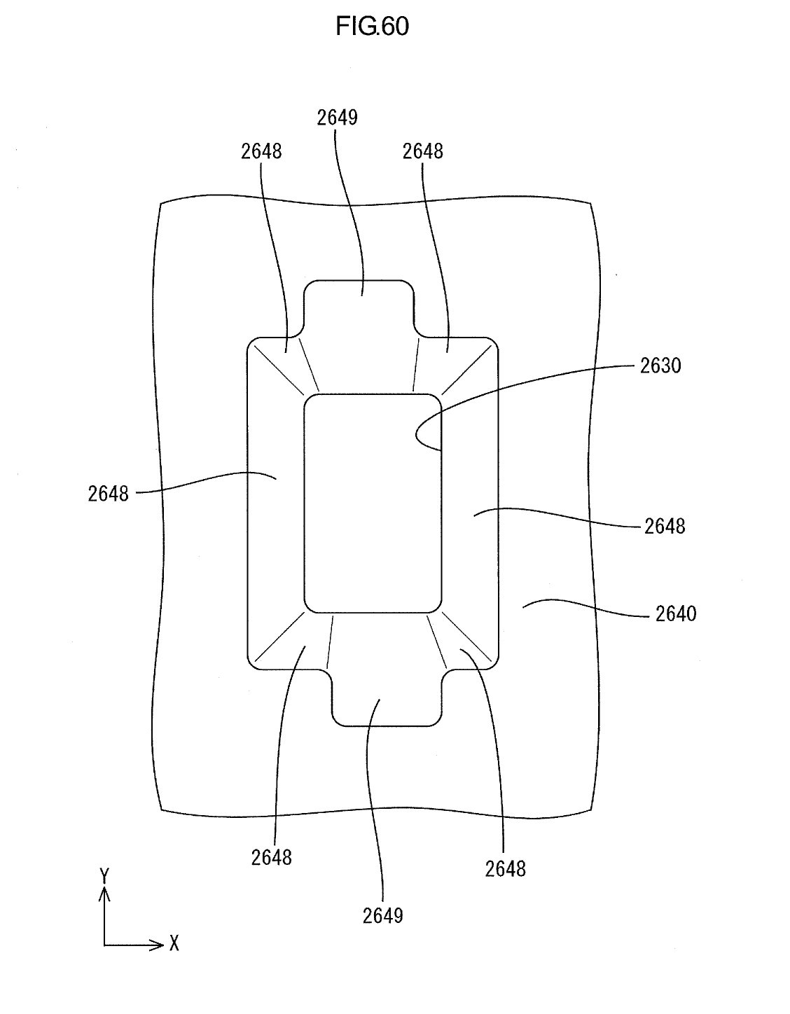

A twenty-seventh embodiment of the present invention will be described with reference to FIG. 60. In the twenty-seventh embodiment, second inclined portions 2649 are formed at portions of edges of each lower contact hole 2630 different from the twenty-sixth embodiment. Structures, functions, and effects similar to those of the twentieth embodiment will not be described.

As illustrated in FIG. 60, the second inclined portions 2649 according to this embodiment are formed at short edges of the lower contact hole 2630, respectively. The second inclined portions 2649 are located closer to ends of the respective short edges. The second inclined portion 2649 formed at one of the short edges of the lower contact hole 2630 and the second inclined portion 2649 formed at the other short edge are located closer to ends of the short edges opposite to each other in the X-axis direction. First inclined portions 2648 are formed at the rest of the portions of the short edges, at other portions of which the second inclined portions 2649 are formed. In the halftone mask for exposing an organic insulator 2640 that includes the lower contact holes 2630 having the above configuration, two second holes are formed at a distance from edges of a first hole in the Y-axis direction, respectively. Furthermore, edges of the second holes are substantially flush with edges of the first hole in the X-axis direction, respectively.

### Twenty-Eighth Embodiment

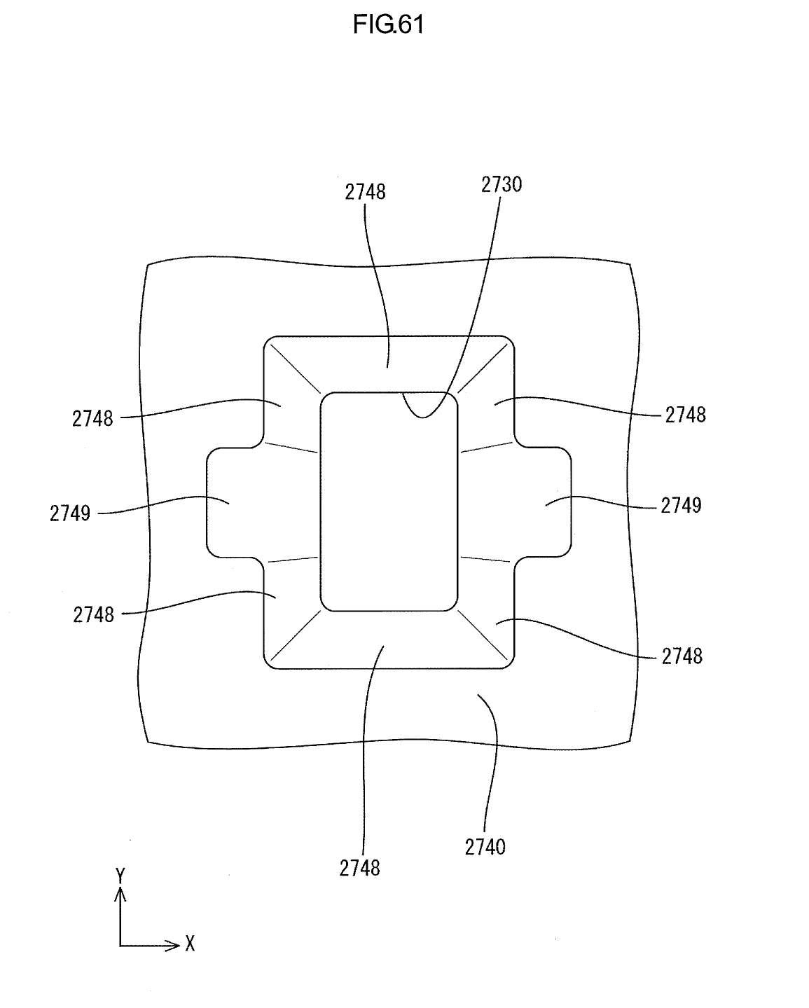

A twenty-eighth embodiment of the present invention will be described with reference to FIG. 61. In the twenty-eighth embodiment, second inclined portions 2749 are formed at portions of edges of each lower contact hole 2730 different from the sixteenth embodiment. Structures, functions, and effects similar to those of the sixteenth embodiment will not be described.

As illustrated in FIG. 61, the second inclined portions 2749 are formed at portions of edges of each lower contact hole 2730, respectively. The second inclined portions 2749 are located at middle portions of the respective long edges and first inclined portions 2748 are formed at sides of the ends of the long edges. In the halftone mask for exposing an organic insulator 2740 that includes the lower contact holes 2730 having the above configuration, two second holes are formed at a distance from edges of a first hole in the X-axis direction, respectively. Furthermore, the middle of the second hole in the Y-axis direction corresponds with the middle of the first hole in the Y-axis direction.

### Twenty-Ninth Embodiment

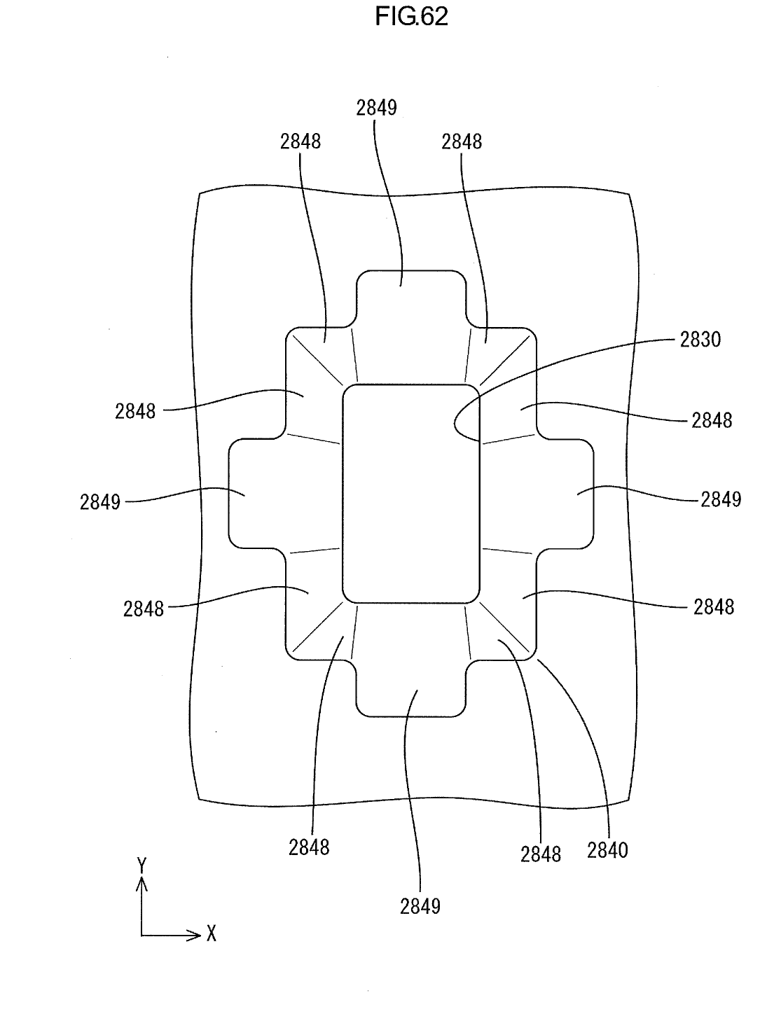

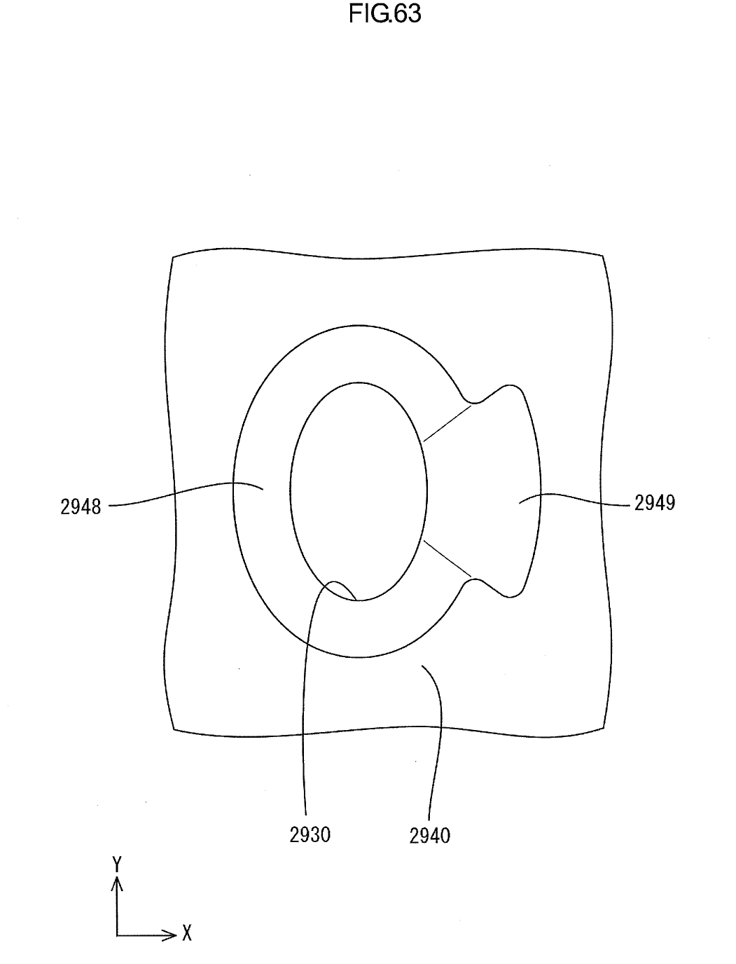

A twenty-ninth embodiment of the present invention will be described with reference to FIG. 62. In the twenty-ninth embodiment, the number of second inclined portions 2849 formed at edges of each lower contact hole 2830 are different from the sixteenth embodiment. Structures, functions, and effects similar to those of the sixteenth embodiment will not be described.

As illustrated in FIG. 62, the second inclined portions 2849 according to this embodiment are formed at four edges of the lower contact hole 2830, respectively. The second inclined portions 2849 are located at the middle of the respective edges and first inclined portions 2848 are formed at sides of the second inclined portions 2849. In the halftone mask for exposing an organic insulator 2840 that includes the lower contact holes 2830 having the above configuration, two second holes are formed at a distance from edges of a first hole in the X-axis direction, respectively, and two second holes are formed at a distance from edges of the first hole in the Y-axis direction, respectively. Furthermore, the middle of the second hole in the length direction corresponds with the middle of the first hole in the length direction or the width direction.

### Thirtieth Embodiment

A thirtieth embodiment of the present invention will be described with reference to FIG. 63. In the thirtieth embodiment, a position and the number of the second inclined portions 2949 at edges of the lower contact holes 2930 are different from the twenty-first embodiment. Structures, functions, and effects similar to those of the twenty-first embodiment will not be described.

As illustrated in FIG. 63, a single second inclined portions 2949 according to this embodiment is formed at an end of short dimension of each lower contact hole 2930 having an oval shape in a plan view. A first inclined portion 2948 is formed at the rest portion of the edge. In the halftone mask for exposing an organic insulator 2940 that includes the lower contact holes 2930 having the above configuration, one second hole is formed in a light blocking film at a distance from a first hole in the X-axis direction. Furthermore, the middle of the second hole in the Y-axis direction corresponds with the middle of the first hole in the Y-axis direction.

### Thirty-First Embodiment

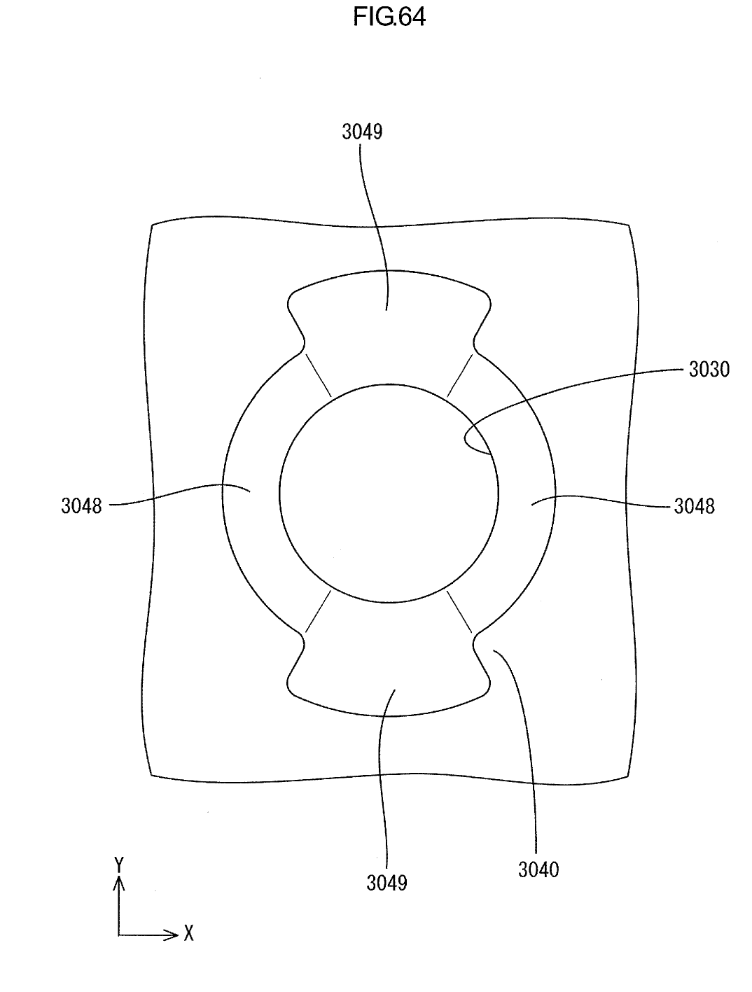

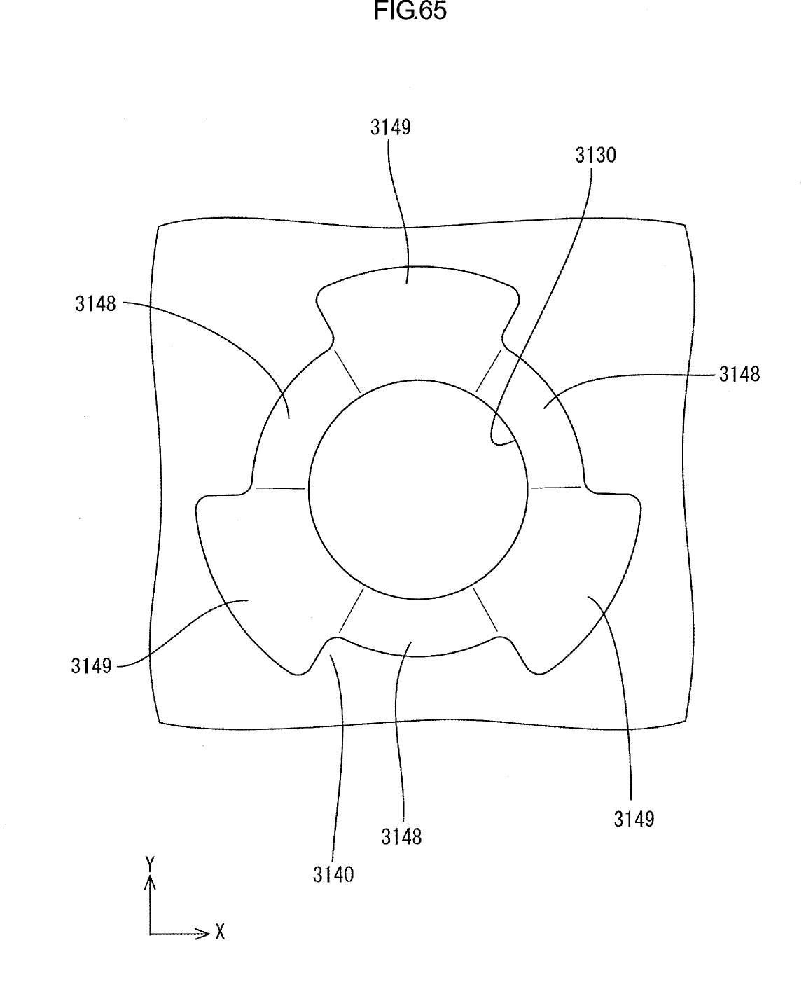

A thirty-first embodiment of the present invention will be described with reference to FIG. 64. In the thirty-first embodiment, positions and the number of second inclined portions 3049 formed at an edge of each lower contact hole 3030 are different from the twenty-second embodiment. Structures, functions, and effects similar to those of the twenty-second embodiment will not be described.

As illustrated in FIG. 64, the second inclined portions 3049 according to this embodiment are formed at an edge of each lower contact hole 3030 that has a round shape in a plan view. Two second inclined portions 3049 are about 180° apart from each other along a circumferential direction of the lower contact hole 3030. First inclined portions 3048 are formed at the rest of the portions of the edge. The edge of the lower contact hole 3030 has a line symmetric and point symmetric shape in a plan view. In the halftone mask for exposing an organic insulator 3040 that includes the lower contact holes 3030 having the above configuration, two second holes are formed at a distance from edges of a first hole in the Y-axis direction, respectively. Furthermore, the second holes are about 180° apart from each other along a circumferential direction of the first hole.

### Thirty-Second Embodiment

A thirty-second embodiment of the present invention will be described with reference to FIG. 65. In the thirty-second embodiment, the number of second inclined portions 3149 formed at an edge of each lower contact hole 3130 is different from the thirty-first embodiment. Structures, functions, and effects similar to those of the thirty-first embodiment will not be described.

As illustrated in FIG. 65, the second inclined portions 3149 according to this embodiment are formed at an edge of each lower contact hole 3130 that has a round shape in a plan view. Three second inclined portions 3149 are about 120° apart from one another along a circumferential direction of the lower contact hole 3130. First inclined portions 3148 are formed at the rest of portions of the edge. In the halftone mask for exposing an organic insulator 3140 that includes the lower contact holes 3130 having the above configuration, three second holes are formed at a distance from a center of a first hole in the radial direction, respectively. Furthermore, the second holes are about 120° apart from each other along a circumferential Y-axis direction of the first hole.

### Other Embodiment

The present invention is not limited to the above embodiments described with reference to the drawings. The following embodiments may be included in the technical scope of the present invention.

(1) The angle between the first edge and the second edge inside the contact hole in the bending portion may be defined as appropriate other than the angles defined in the above embodiments illustrated in the drawings.

(2) Each of the first edge and the second edge of each bending portion in each of the above embodiments is a straight edge in a plan view. However, each of the first edge and the second edge of the bending portion may a curved edge.

(3) The shapes of each contact hole main portion and each expanded hole portion in a plan view may be defined as appropriate other than those in the above embodiments. For example, the shapes of the contact hole main portion and the expanded hole portion in a plan view may be square shapes, triangular shapes, polygonal shapes with five or more sides, diamond-like shapes, parallelogram shapes, round shapes, or elliptical shapes.

(4) The arrangement of each expanded hole portion relative to the corresponding contact hole main portion may be defined as appropriate other than the arrangements in the above embodiments. The number and the size of the expanded hole portions in a plan view may also be altered as appropriate.

(5) The arrangement of the expanded hole portion of the upper contact hole relative to the pixel components (gate electrode, drain electrode, channel, hole of the insulator, gate line, pixel electrode, common electrode, drain line, or upper contact hole) may be defined as appropriate other than the arrangements in the above embodiments.

(6) The arrangement and the shape of each upper contact hole in a plan view and the area in which the upper contact hole is formed may be defined as appropriate other than those of the above embodiments. For example, the arrangement may be altered such that the upper contact hole overlaps the expanded hole portion of the lower contact hole in a plan view, or the upper contact hole overlaps the lower contact hole in a plan view. In this configuration, the shape of the upper contact hole in a plan view may be the same as that of the lower contact hole. According to the configuration, the upper contact hole can be used as a mask for patterning the lower contact holes.

(7) In the second and fourteenth embodiments, the patterning is performed on the organic insulator using the gray tone mask. However, the patterning may be performed on the organic insulator using a halftone mask including a semitransmissive film.

(8) The alignment film is applied to the array board using the inkjet device or the screen printing device in the above embodiments, the alignment film may be applied to the array board using an offset printing device, a relief printing device, an intaglio printing device, or a lithographic printing device. It is preferable to use the same device for applying the alignment film to the CF board as that used for the array board.

(9) The alignment film is made of polyimide in the above embodiments. However, liquid crystal alignment materials other than polyimide may be used for the alignment film.

(10) The alignment film is the light alignment film made of light alignment material to exert the alignment function when subjected to the ultraviolet light. However, an alignment film configured to exert alignment function through rubbing may be included in the scope of the present invention.

(11) The display area side contact hole overlaps the drain electrode of the TFT in a plan view and the pixel electrode is directly connected to the drain electrode in the above embodiments. However, the display area side contact hole may not overlap the drain electrode in a plan view but overlap the drain line (including capacitance formation portion) in a plan view and the pixel electrode may be connected to the drain line.

(12) In each of the above embodiments, the TFTs are disposed over the respective gate lines. However, a configuration in which the TFTs that do not overlap the gate lines in a plan view may be included in the scope of the present invention. In the configuration, the gate electrodes may be formed branched off the gate lines.

(13) In each of the above embodiments, a portion of each TFT is disposed over the corresponding source line. However, a configuration in which each TFT does not overlap the source line in a plan view may be included in the scope of the present invention. In the configuration, the source electrodes may be formed branched off the source lines.

(14) In each of the above embodiments, each gate line and each auxiliary capacitor line are disposed such that the middle portion of the pixel electrode is sandwiched therebetween in a plan view, or the auxiliary capacitor line may be disposed so as to cross the middle portion of the pixel electrode in the length direction.

(15) In the above embodiments, each bending portion (at least two inclined portions) is formed at the edge of the corresponding non-display area side contact hole for connecting the corresponding gate line to the row control circuit. However, in a configuration in which the non-display area side contact holes are formed at a portion where the column control circuit and the source line are connected, the bending portion (at least two inclined portions) may be formed at an edge of the non-display area side contact hole. Furthermore, in a configuration that includes the non-display area side contact holes for connecting the lines formed from the first metal film to the lines formed from the second metal film in the non-display area, the bending portion (at least two inclined portions) may be formed at an edge of the non-display area side contact hole.

(16) The arrangement and the number of row control circuits on the array board may be defined as appropriate other than those of the above embodiments. For example, a configuration in which the row control circuit is disposed on the right side of the display area on the array board in FIG. 4 or including a pair of row control circuits disposed on the right side and the left side of the display area on the array board may be included in the scope of the present invention.

(17) The materials of the gate insulator, the protection film, the first interlayer insulator, the organic insulator, and the second interlayer insulator may be defined as appropriate other than those of the above embodiments.

(18) In the above embodiments, the oxide semiconductor film is the oxide thin film containing indium (In), gallium (Ga), and zinc (Zn). However, another kind of oxide semiconductor material may be used. Specifically, an oxide containing indium (In), silicon (Si), and zinc (Zn), an oxide containing indium (In), aluminum (Al), and zinc (Zn), an oxide containing tin (Sn), silicon (Si), and zinc (Zn), an oxide containing tin (Sn), aluminum (Al), and zinc (Zn), an oxide containing tin (Sn), gallium (Ga), and zinc (Zn), an oxide containing gallium (Ga), silicon (Si), and zinc (Zn), an oxide containing gallium (Ga), aluminum (Al), and zinc (Zn), an oxide containing indium (In), copper (Cu), and zinc (Zn), an oxide containing tin (Sn), copper (Cu), and zinc (Zn) may be used.

(19) The first metal film and the second metal film are formed from a multilayer film of titanium (Ti) and copper (Cu) in the above embodiments. However, titanium may be replaced by molybdenum (Mo), molybdenum nitride (MoN), titanium nitride (TiN), tungsten (W), niobium (Nb), molybdenum-titanium alloy (MoTi), or molybdenum-tungsten alloy (MoW). Alternatively, a single-layer metal film of titanium, copper, or aluminum may be used.

(20) In each of the above embodiments, the liquid crystal panel includes the FFS mode as an operation mode. However, a liquid crystal panel including the IPS (In-Plane Switching) mode or the VA (Vertical Alignment) mode as an operation mode may be included in the scope of the present invention.

(21) In each of the above embodiments, the display area on the liquid crystal panel is in the middle of the short dimension and off to one end of the long dimension. However, a liquid crystal panel including a display area in the middle of the long dimension and off to one end of the short dimension may be included in the scope of the present invention. Furthermore, a liquid crystal panel including a display area off to one end of the long dimension and to one end of the short dimension may be included in the scope of the present invention. Furthermore, a liquid crystal panel including a display area in the middle of the long dimension and in the middle of the short dimension may be included in the scope of the present invention.

(22) The driver is mounted directly on the array board by the COG method in the above embodiments. However, the driver mounted on the flexible board connected to the array board through ACF may be included in the scope of the present invention.

(23) The row control circuit and column control circuit are disposed in the non-display area of the array board in the above embodiments. However, a configuration that does not include one of or both the row control circuit and the column control circuit and includes a driver configure to perform the functions of those circuit may be included in the scope of the present invention. The configuration that does not include the row control circuit does not include the non-display area side contact holes.

(24) Each of the embodiments includes the liquid crystal panel having a vertically-long rectangular shape. However, a liquid crystal panel having a horizontally-long rectangular shape or a square shape may be included in the scope of the present invention.

(25) A configuration including the liquid crystal panel in each of the above embodiments and a functional panel such as a touch panel or a parallax barrier panel (switch liquid crystal panel) attached to the liquid crystal panel may be included in the scope of the present invention. Furthermore, a configuration including a touch panel pattern directly formed on a liquid crystal panel may be included in the scope of the present invention.

(26) The backlight device in the liquid crystal display device is the edge-light type in the above embodiments. However, a liquid crystal display device including a direct backlight device may be included in the scope of the present invention.

(27) Each of the above embodiments includes the transmissive type liquid crystal display device including the backlight device as an external light source. However, a reflective liquid crystal display device configured to display images using external light may be included in the scope of the present invention. Such a display device does not require a backlight device.

(28) Each of the above embodiments includes the TFTs as switching components of the liquid crystal display device. However, switching components other than the TFTs (such as thin film diodes (TFDs)) may be included in the scope of the present invention. Furthermore, a liquid crystal display device configured to display black and white images other than o the liquid crystal display device configured to display color images.

(29) Each of the above embodiments includes the liquid crystal panel including the liquid crystals held between the substrates and the alignment film for controlling the alignment of the liquid crystals. However, a display panel including an alignment film for controlling alignment of functional organic molecules other than the liquid crystals may be included in the scope of the present invention.

(30) The above embodiments include the liquid crystal panels that are classified as small sized or small to middle sized panels. Such liquid crystal panels are used in electronic devices including PDAs, mobile phones, laptop computers, digital photo frames, portable video games, and electronic ink papers. However, liquid crystal panels that are classified as middle sized or large sized (or supersized) panels having screen sizes from 20 inches to 90 inches are also included in the scope of the present invention. Such display panels may be used in electronic devices including television devices, electronic signboards (digital signage), and electronic blackboard.

(31) The bending portions, or the first inclined portions and the second inclined portions are formed at the edges of the lower contact holes of the display area side contact holes in the second and sixth to fourteenth embodiments. However, the bending portions, or the first inclined portions and the second inclined portions similar to those of the second and sixth to fourteenth embodiments may be formed at the edges of the non-display area side contact holes.

(32) In the fourteenth embodiment, the number of the first inclined portions and the number of the second inclined portions are the same (in pairs). However, the first inclined portions and the second inclined portions may be formed in the different numbers. Specifically, the first inclined portion(s) or the second inclined portion(s) may be formed at three edges out of four edges of each lower contact hole (non-display area side contact hole), and the second inclined portion or the first inclined portion may be formed at the rest of the edges. Even if the shape of each lower contact hole in a plan view is altered to a shape other than the rectangular shape, the first inclined portions and the second inclined portions may be formed in the different numbers similarly to the above. The arrangement of the first inclined portions and the second inclined portions at the edges of the lower contact hole in a plan view may be altered as appropriate.

(33) In the fourteenth embodiment, two inclined portions (first inclined portion and second inclined portion) with the different inclination angles are formed at the edge of the lower contact hole. However, three or more inclined portions with different inclination angles (specifically, at least the first inclined portion, the second inclined portion, and a third inclined portion with an inclination angle different from both the first inclined portion and the second inclined portion) may be formed at the edge of the lower contact hole (non-display area side contact hole).

(34) The configuration according to the fourteenth embodiment may be combined with the configuration according to any of the first to thirteenth embodiments. In this case, the bending portion, and the first inclined portion and the second inclined portion are provided for the edge of the lower contact hole (non-display area side contact hole).

(35) In the fifteenth embodiment, the difference between the inclination angles of the inclined portions are altered by adjusting the inclination angle of the second inclined portion while the inclination angle of the first inclined portion is maintained constant in the comparative experiment. The difference between the inclination angles of the inclined portions may be altered by adjusting the inclination angle of the first inclined portion while the inclination angle of the second inclined portion is maintained constant. Furthermore, the difference between the inclination angles of the inclined portions may be altered by adjusting the inclination angle of the second inclined portion and the inclination angle of the first inclined portion, respectively.

(36) In each of the fifteenth to the thirty-second embodiment (except for the eighteenth embodiment), the organic insulator is exposed to light using the halftone mask. However, the organic insulator in each of those embodiments may be exposed to light using a gray-tone mask.

(37) In each of the fifteenth to the thirty-second embodiment (except for the eighteenth embodiment), the positive photosensitive organic resin material is used for the organic insulator exposed to light using the halftone mask. However, a negative photosensitive organic resin material may be used for the organic insulator exposed to light using the halftone mask in each of those embodiments.

(38) In the eighteenth embodiment, the positive photosensitive organic resin material is used for the organic insulator exposed to light using the gray-tone mask. However, a negative photosensitive organic resin material may be used for the organic insulator exposed to light using the gray-tone mask.

(39) The width of the semitransmissive area, the distance between the transmissive area and the semitransmissive area, and a distance between the light blocking area and the semitransmissive area of the halftone mask may be altered from those in the sixteenth embodiment or the seventeenth embodiment as appropriate. It is preferable to define those in a range from 0.5 μm to 5 μm.

(40) The width of the semitransmissive area of the halftone mask may be altered from that in the eighteenth embodiment as appropriate. It is preferable to define the width in a range from 0.5 μm to 5 μm.

(41) The difference between the inclination angles of the first inclined portion and the second inclined portion may be altered from that in the fifteenth embodiment as appropriate. It is preferable to define the difference in angle in a range from 10° to 50°. The inclination angle of the first inclined portion and the inclination angle of the second inclined portion may be altered as appropriate.

(42) The length of the second inclined portion formed at the short edge of the lower contact hole may be altered from that in the fifteenth embodiment as appropriate. It is preferable to define the length equal to 8 μm or smaller.

(43) The area of each lower contact hole may be altered from that in the fifteenth embodiment as appropriate. It is preferable to define the area in a range from 10 μm² to 150 μm².

(44) In the twentieth embodiment, the second inclined portion is formed at the short edge of the lower contact hole for the entire length of the short edge. However, the second inclined portion may be formed at the long edge of the lower contact hole for the entire length of the long edge.

(45) A modification of the twenty-first embodiment or the thirtieth embodiment may include a second inclined portion formed at an end of a long dimension of a contact hole having an oval shape in a plan view. Alternatively, a second inclined portion may be formed off the long axis or the short axis of the contact hole. Furthermore, the number and the arrangement of the second inclined portions and the area in which the second inclined portion is formed may be altered as appropriate.

(46) The number and the arrangement of the second inclined portions and the area in which the second inclined portion is formed at the edge of the lower contact hole having the round shape in a plan view may be altered as appropriate from those in the twenty-second, the thirty-first, or the thirty-second embodiment. For example, four or more second inclined portions may be formed or the second inclined portions may be arranged at irregular intervals along a circumferential direction of the lower contact hole.

(47) The number and the arrangement of the second inclined portions and the areas in which the second inclined portions are formed at the edges of the lower contact hole having a rectangular shape in a plan view may be altered from those in the fifteenth embodiment to the thirty-second embodiment. For example, three second inclined portions or five or more second inclined portions may be formed. Alternatively, two second inclined portions may be formed at the long edge of the lower contact hole and two second inclined portions may be formed at the short edge of the lower contact hole. Furthermore, the configuration of any of the fifteenth embodiment to the thirty-two embodiment and the configuration of any of the first embodiment to the fourteenth embodiment may be combined.

### EXPLANATION OF SYMBOLS

11: Liquid crystal panel (display device)
11a: CF board (opposite board)
11b, 211b, 1311b, 1411b, 1611b, 1711b: Array board (display component)
11c: Liquid crystal layer (liquid crystals)
11e, 111e, 1311e, 1411e: Alignment film
17a, 317a, 417a: Gate electrode
17b: Source electrode
17c, 317c, 417c: Drain electrode
17d: Channel
18, 118, 318, 418, 1318: Pixel electrode
24, 1324, 1424: Second transparent electrode film (second conductive film)
25: Auxiliary capacitor line
30, 130, 330, 430, 530, 630, 730, 830, 930, 1030, 1130, 1230, 1330, 1430, 1530, 1630, 1730, 1830, 1930, 2030, 2130, 2230, 2330, 2430, 2530, 2630, 2730, 2830, 2930, 3030, 3130: Lower contact hole (contact hole)
30a, 530a, 630a, 730a, 830a, 930a, 1030a, 1130a, 1230a: Contact hole main portion
30b, 330b, 430b, 530b, 630b, 730b, 830b, 930b, 1030b, 1130b, 1230b: Expanded hole portion
33: Non-display area side contact hole (contact hole)
33a: Contact hole main portion
33b: Expanded hole portion
34: First metal film (first conductive film, third conductive film)
35: Gate insulator (insulator)
36: Semiconductor film
37: Protection film (insulator)
38, 1338, 1438: Second metal film (First metal film, second metal film)
39, 1339, 1439: First interlayer insulator (insulator)
40, 140, 1340, 1440, 1540, 1640, 1740, 1840, 1940, 2040, 2140, 2240, 2340, 2440, 2540, 2640, 2740, 2840, 2940, 3040, 3140: Organic insulator (insulator)
42: Inkjet device
42d: Nozzle
43, 143, 743, 843, 943, 1143, 1243: Bending portion
43a, 743a, 843a, 943a: First edge (edge)
43b, 743b, 843b, 943b: Second edge (edge)
44: First inclined portion
45: Second inclined portion
46, 1346, 1746: Gray tone mask
46b, 1346b, 1746b: Light blocking film
46b1, 1346b1, 1746b1: Slit
47: Screen printing device (stencil printing device)
47a: Screen (stencil)
47a1: Hole
47c, 47d: Squeegee
48, 1448, 1548, 1848, 1948, 2048, 2148, 2248, 2348, 2448, 2548, 2648, 2748, 2848, 2948, 3048, 3148: First inclined portion (inclined portion)
49, 1449, 1549, 1649, 1749, 1849, 1948, 2049, 2149, 2249, 2349, 2449, 2549, 2649, 2749, 2849, 2949, 3049, 3149: Second inclined portion (inclined portion)
50, 1650, 1850, 1950, 2050, 2150, 2250, 2350: Halftone mask
50b, 1650b, 1850b, 1950b, 2050b, 2150b, 2250b, 2350b: Light blocking film
50b1, 1650b1, 1850b1, 1950b1, 2050b1, 2150b1, 2250b1, 2350b1: First hole (hole)
50b2, 1650b2, 1850b2, 1950b2, 2050b2, 2150b2, 2250b2, 2350b2: Second hole (hole)
50c, 1650c: Semitransmissive film
50c1: Hole (hole)
GS: Glass substrate (substrate)
HTA: Semitransmissive area
TA: Transmissive area
SA: Light blocking area
θ1, θ2: Inclination angle

1-14. (canceled)

15. A display component comprising:
a first conductive film;
a second conductive film disposed above the first conductive film and including a portion overlapping the first conductive film in a plan view;
an insulator held between the first conductive film and the second conductive film and including a contact hole for connecting the second conductive film to the first conductive film, the contact hole being at a position overlapping the first conductive film and the second conductive film in a plan view;
an alignment film disposed above the second conductive film and including a portion overlapping the contact hole in a plan view and a portion not overlapping the contact hole in a plan view; and
at least two inclined portions formed at an edge of the contact hole in the insulator and having inclined shapes in a cross-sectional view with inclination angles different from each other.

16. The display component according to claim 15, wherein the at least two inclined portions are formed such that a difference between the inclination angles thereof is in a range from 10° to 50°.

17. The display component according to claim 15, wherein
the insulator is formed such that the contact hole includes a long edge and a short edge in a plan view, and
one of the at least two inclined portions having a smaller inclination angle is formed at the short edge of the contact hole.

18. The display component according to claim 17, wherein the inclined portion having the smaller inclination angle has a dimension along the short edge equal to 8 μm or smaller.

19. The display component according to claim 15, wherein
the insulator is formed such that the contact hole has a polygonal shape in a plan view, and
the inclined portion having the smaller inclination angle and the inclined portion having a larger inclination angle of the at least two inclined portions are formed at portions of at least one edge of the contact hole.

20. The display component according to claim 19, wherein
the insulator is formed such that the contact hole has a rectangular shape in a plan view, and
the inclined portion having the smaller inclination angle and the inclined portion having a larger inclination angle of the at least two inclined portions are formed at portions of at least a long edge of the contact hole.

21. The display component according to claim 15, wherein the insulator is formed such that the contact hole has a round shape or an oval shape in a plan view.

22. The display component according to claim 15, wherein the insulator is formed such that the contact hole has an opening area in a range from 10 μm² to 150 μm².

23. The display component according to claim 15, further comprising:
a third conductive film provided below the first conductive film, at least a portion of the third conductive film overlapping the first conductive film in a plan view; and
a semiconductor film interposed between the third conductive film and the first conductive film, wherein
the first conductive film forms at least a source electrode and a drain electrode,
the third conductive film forms a gate electrode that overlaps at least the source electrode and the drain electrode in a plan view, and
the semiconductor film includes an oxide semiconductor and forma a channel that is connected to the source electrode and the drain electrode.

24. The display component according to claim 23, wherein the oxide semiconductor contains indium (In), gallium (Ga), zinc (Zn), and oxygen (O).

25. The display component according to claim 24, wherein the oxide semiconductor is crystalline.

26. A display device comprising:
the display component according to claim 15;
an opposite board disposed opposite the display component; and
liquid crystals disposed between the display component and the opposite board.

27. A method of producing a display component comprising:
a first film forming process for forming a first conductive film, an insulator, and a second conductive film in this sequence on a substrate, the first film forming process including:
forming a contact hole at a position overlapping the first conductive film and the second conductive film in a plan view for connecting the second conductive film to the first conductive film; and
forming at least two inclined portions at an edge of the contact hole such that the at least two inclined portions have inclined shapes in a cross-sectional view and inclination angles different from each other; and
a second film forming process for forming an alignment film including a portion overlapping the contact hole and a portion not overlapping the contact hole.

28. The method according to claim 27, wherein the first film forming process further includes:
forming at least an organic insulator from photosensitive organic resin material as the insulator;
exposing the organic insulator using a halftone mask including a semitransmissive film or a gray-tone mask including a semitransmissive area with a slit as a photomask; and
forming one of the at least two inclined portions having a smaller inclination angle at the edge of the contact hole with light transmitted through the semitransmissive film of the halftone mask or the semitransmissive area of the gray-tone mask.

29. The method according to claim 27, wherein the first film forming process further includes:
forming at least an organic insulator from photosensitive organic resin material as the insulator;
exposing the organic insulator using a halftone mask including a light blocking film and a semitransmissive film including holes, respectively, as a photomask, the halftone mask including a semitransmissive area in which the hole in the light blocking film overlaps the semitransmissive film in a plan view, the semitransmissive area having a width in a range from 0.5 μm to 5 μm; and
forming one of the at least two inclined portions having a smaller inclination angle at the edge of the contact hole with light transmitted through the semitransmissive area.

30. The method according to claim 29, wherein
the halftone mask used in the first film forming process is configured according to photosensitivity of the photosensitive organic resin material of the organic insulator,
when the photosensitive organic resin material of the organic insulator is a positive type, the organic insulator is exposed to light using the halftone mask including a transmissive area in which the hole in the light blocking film and the hole in the semitransmissive film overlap each other in a plan view and a distance between the transmissive area and the semitransmissive area is in a range from 0.5 μm to 5 μm, and
when the photosensitive organic resin material of the organic insulator is a negative type, the organic insulator is exposed to light using the halftone mask including a light blocking area that overlaps the light blocking film in a plan view and a distance between the light blocking area and the semitransmissive area is in a range from 0.5 μm to 5 μm.

31. The method according to claim 27, wherein the first film forming process includes:
forming at least an organic film from photosensitive organic resin material as the insulator;
exposing the organic insulator using a gray-tone mask as a photomask, the gray-tone mask including a light blocking film and a width of the semitransmissive area including the slit being in a range from 0.5 μm to 5 μm; and
forming one of the at least two inclined portions having a smaller inclination angle at the edge of the contact hole with light transmitted through the semitransmissive area.

32. The method according to claim 27, further comprising:
forming a third conductive film prior to formation of the first conductive film such that at least a portion of the third conductive film overlaps the first conductive film in a plan view; and
forming a semiconductor film from an oxide semiconductor between the third conductive film and the first conductive film.

33. The method according to claim 32, wherein the oxide semiconductor contains indium (In), gallium (Ga), zinc (Zn), and oxygen (O).

34. The method according to claim 33, wherein the oxide semiconductor is crystalline.
